(19) United States
(12) Patent Application Publication
(10) Pub. No.: US 2025/0366360 A1
(43) Pub. Date: Nov. 27, 2025

(54) ORGANIC RANDOM POLYMER AND ORGANIC OPTOELECTRONIC DEVICE USING THE SAME

(71) Applicant: Raynergy Tek Incorporation, HSINCHU (TW)

(72) Inventors: Min-Hsien Chen, HSINCHU (TW); Tsz Chung Timothy Yiu, HSINCHU (TW); Chuang-Yi Liao, HSINCHU (TW)

(21) Appl. No.: 19/203,457

(22) Filed: May 9, 2025

Related U.S. Application Data
(60) Provisional application No. 63/651,413, filed on May 24, 2024.
(60) Provisional application No. 63/651,410, filed on May 24, 2024.
(60) Provisional application No. 63/730,474, filed on Dec. 11, 2024.

(51) Int. Cl. H10K 85/10; C08G 61/12; H10K 30/40; H10K 50/11

(52) U.S. Cl. CPC H10K 85/113; C08G 61/126; H10K 85/151; C08G 2261/122; C08G 2261/124; C08G 2261/1412; C08G 2261/148; C08G 2261/149; C08G 2261/314; C08G 2261/3223; C08G 2261/3241; C08G 2261/3243; C08G 2261/3246; C08G 2261/414; C08G 2261/94; H10K 30/40; H10K 50/11

(57) ABSTRACT

An organic random polymer comprises a structure of Formula I:

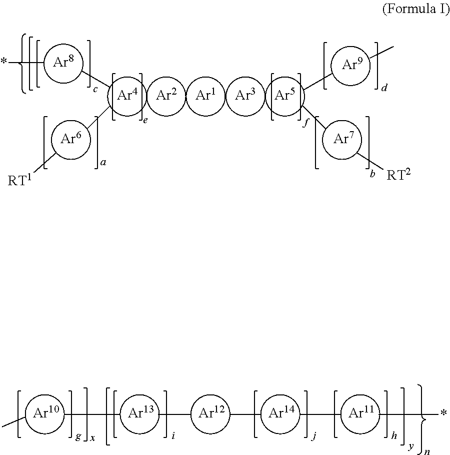

The organic random polymer utilizes the 3-position of a sulfur-containing five-membered heterocycle as the polymerization site rather than the end of 2-(3-oxo-2,3-dihydro-1H-inden-1-ylidene) malononitrile, and thus there are no isomers. The organic random polymer can be tailored by adjusting the y-block to absorb light in the shortwave infrared region and exhibit good thermal stability. The present invention also provides an organic optoelectronic device comprising a first electrode, an active layer, and a second electrode. The active layer contains the organic random polymer. This organic optoelectronic device demonstrates good external quantum efficiency in the near-infrared region and possesses excellent thermal stability.

The present application is based on, and claims priority from, America provisional patent application number U.S. 63/651,413 filed on 2024 May 24, U.S. 63/651,410 filed on 2024 May 24 and U.S. 63/730,474 filed on 2024 Dec. 11, and the disclosure of which is hereby incorporated by reference herein in its entirety.

### BACKGROUND OF THE INVENTION

### Field of the Invention

The present invention relates to an organic polymer applied in an organic optoelectronic device, and in particular to an organic random polymer and an organic optoelectronic device comprising the same.

### Description of the Prior Art

Compared to traditional inorganic optoelectronic devices, organic optoelectronic devices have wide absorption wavelength ranges, high absorption coefficients, and adjustable structures, and their light absorption ranges, energy levels and solubility can be adjusted according to the target requirements. In addition, organic materials have the advantages of low cost, flexibility, low toxicity and large-area production of devices, so that organic optoelectronic devices have good competitiveness in various fields, such as organic field effect transistors (OFETs), organic light emitting diodes (OLEDs), organic photovoltaics (OPVs) and organic photodetectors (OPDs).

Existing fullerene materials have drawbacks such as difficulty in synthesis and purification, as well as weak absorption in the wavelength region above 700 nm. In recent years, the development of non-fullerene acceptor (NFA) materials has not only overcome the aforementioned disadvantages of fullerene materials but also demonstrated significant advantages in organic semiconductor (OSC) devices due to their good processability, easy adjustment of solubility, material energy level position, and film-forming properties. In order to achieve commercialization and good lifespan, the importance of thermal stability of materials is also increasing. Due to their small molecular weight, small molecules are prone to crystallization when devices are heat treated and cause defective devices. In contrast, polymers have excellent film-forming properties, easy processability, and high solubility in organic solvents. In particular, high molecular weight polymers tend to have lower crystallinity, resulting in better thermal stability than small molecules. Therefore, subsequent application of polymeric materials in organic semiconductor devices is expected to improve their thermal stability.

The existing skill mainly modified the terminal electron-withdrawing groups (2-(3-oxo-2,3-dihydro-1H-inden-1-ylidene) malononitrile, IC) of non-fullerene as the polymerization reaction position. However, during modification of the IC terminal group, isomers may be formed, and these isomers are difficult to separate, resulting in polymers containing different isomeric forms. These different isomeric forms may have negative effects on the performance of devices or lead to reproducibility issues. For example, a study published by Feng He et al. in 2024 shows that two dimeric isomers with δ- and γ-linkage positions on IC group respectively have significantly different power conversion efficiencies 13.15% and 17.14% in organic photovoltaic (OPV) devices. The efficiency difference between the two isomers is substantial, with one isomer demonstrating inferior performance. Moreover, attempts to isolate individual IC isomeric monomers are hindered by their highly similar physical and chemical properties, which makes separation difficult and cost-prohibitive for commercial applications.

As mentioned above, developing an organic random polymer with advantages in synthesis and purification, a tunable absorption wavelength, an extended absorption spectrum reaching the near-infrared region, and excellent thermal stability, is a very important issue at present.

### SUMMARY OF THE INVENTION

In view of this, one category of the present invention is to provide an organic random polymer comprises a structure such as Formula I:

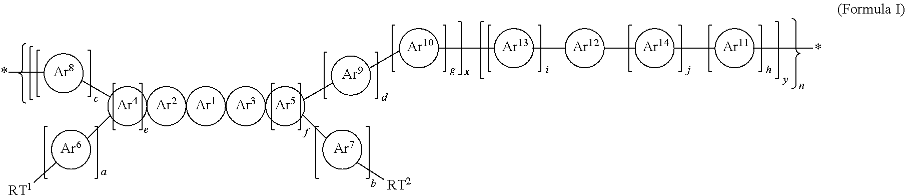

Wherein, Ar¹, Ar⁴, Ar⁵, Ar¹³, and Ar¹⁴ are each independently selected from arylene or heteroarylene having 5 to 20 ring atoms, Ar¹, Ar⁴, Ar⁵, Ar¹³, and Ar¹⁴ comprise monocyclic, polycyclic, or fused ring structure, and optionally unsubstituted or substituted with one or more identical or different R¹ or L¹, Ar² and Ar³ are each independently selected from the group consisting of

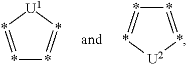

Wherein, U¹ and U² are each independently selected from the group consisting of NR¹, C═O, O, S, Se, SiR¹R², and CR¹R². Ar⁶, Ar⁷, Ar⁸, and Ar⁹ are each independently selected from the group consisting of a structure having —CY¹=CY²— or —C≡C—, arylene having 5 to 20 ring atoms and heteroarylene having 5 to 20 ring atoms, Ar⁶, Ar⁷, Ar⁸, and Ar⁹ comprise monocyclic, polycyclic, or fused ring structure, and optionally unsubstituted or substituted with one or more identical or different R¹ or L¹. Ar¹⁰, Ar¹¹, and Ar¹² are each independently selected from arylene or heteroarylene having 5 to 30 ring atoms, Ar¹⁰, Ar¹¹, and Ar¹² comprise monocyclic, polycyclic, or fused ring structure, and optionally unsubstituted or substituted with one or more identical or different R¹ or L¹. Wherein, R¹ and R₂ are each independently selected from the group consisting of H, F, Cl, CN, C1-C30 straight-chain alkyl, C1-C30 branched alkyl, and C1-C30 cyclic alkyl. Wherein, one or more CH₂ of alkyl are optionally replaced by at least one group selected from the group consisting of —O—, —S—, —C(═O)—, —C(═S)—, —C(═O)—O—, —O—C(═O)—, —NR⁰—, —SiR⁰R⁰⁰—, —CF₂—, —CR⁰=CR⁰⁰—, —CY¹=CY²—, and —C≡C—. Wherein, O and S are not directly bonded to each other, and one or more atoms are optionally substituted with F, Cl, Br, I, or CN. Wherein, one or more CH₂ or CH₃ are optionally substituted with at least one of cation, anion, aryl, heteroaryl, aralkyl, heteroaralkyl, aryloxy, and heteroaryloxy. Wherein, the aryl and the heteroaryl are each independently selected from monocyclic, polycyclic, or fused ring structures having 5 to 20 ring atoms, and the alkyl is optionally unsubstituted or substituted with one or more identical or different L¹. L¹ is selected from the group consisting of F, Cl, —NO₂, —CN, —NC, —NCO, —NCS, —OCN, —SCN, R⁰, OR⁰, SR⁰, —C(═O)X⁰, —C(═O)R⁰, —C(═O)—OR⁰, —O—C(═O)—R⁰, —NH₂, —NHR⁰, —NR⁰R⁰⁰, —C(═O)NHR⁰, —C(, O)NR⁰R⁰⁰, —SO₃R⁰, —SO₂R⁰, —OH, —NO₂, —CF₃, —SF₅, and C1-C30 silane, C1-C30 carbonyl and C1-C30 hydrocarbon optionally substituted or unsubstituted with one or more heteroatoms, wherein the heteroatom comprises N, O, S, and Se. Wherein, R⁰ and R⁰⁰ are each independently selected from the group consisting of H and C1-C20 straight-chain alkyl and C1-C20 branched alkyl, and optionally fluorinated. X⁰ is halogen. Y¹ and Y² are each independently selected from the group consisting of H, F, Cl, and CN. a, b, c, d, e, f, g, h, i, and j are integers, each independently selected from 0 or 1 to 10. x and y are mole ratio, and x+y=1. n is the number of repeating units and is an integer selected from 1 to 1000. RT¹ and RT² are electron-withdrawing groups. * is a bonding position.

Wherein, Ar¹ is further selected from the group consisting of the following structures:

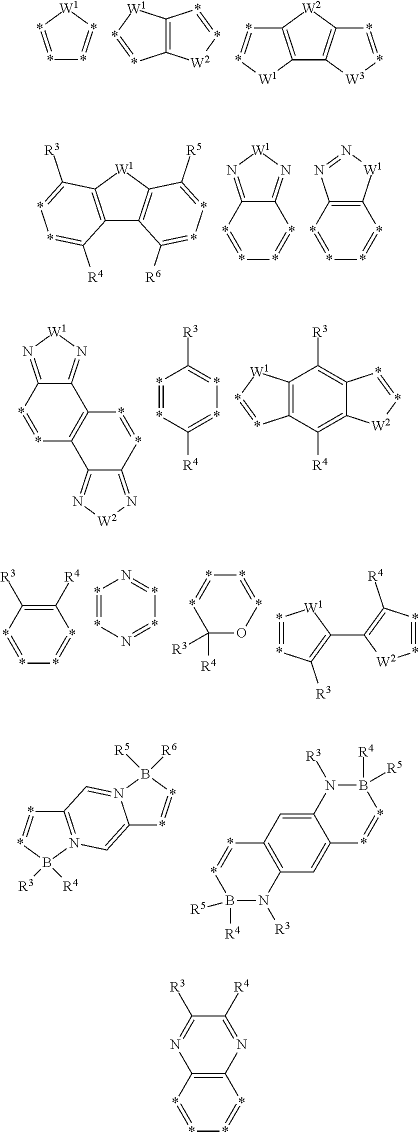

Wherein, W¹, W², and W³ are each independently selected from the group consisting of S, O, Se, CR³R⁴, SiR³R⁴, C═O, and NR³. R³, R⁴, R⁵ and R⁶ are each independently defined as R¹ as defined previously, and are optionally covalently bonded to at least one of the others, or each is a separate group.

Wherein, Ar² and Ar³ are further each independently selected from the group consisting of the following structures:

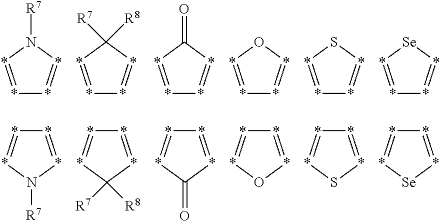

Wherein, R⁷ and R⁸ are each independently defined as R¹ as defined previously.

Wherein, Ar⁴ and Ar⁵ are further each independently selected from the group consisting of the following structures and their enantiomeric forms:

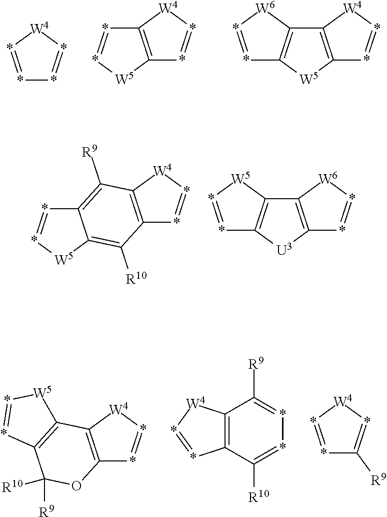

Wherein, W⁴, W⁵, and W⁶ are each independently selected from the group consisting of S, O, Se, CR⁹R¹⁰, SiR⁹R¹⁰, C—O, and NR⁹. R⁹ and R¹⁰ are each independently defined as R¹ as defined previously. U³ is defined as U¹ as defined previously.

Wherein, Ar⁶, Ar⁷, Ar⁸ and Ar⁹ are further each independently selected from the group consisting of the following structures and their enantiomeric forms:

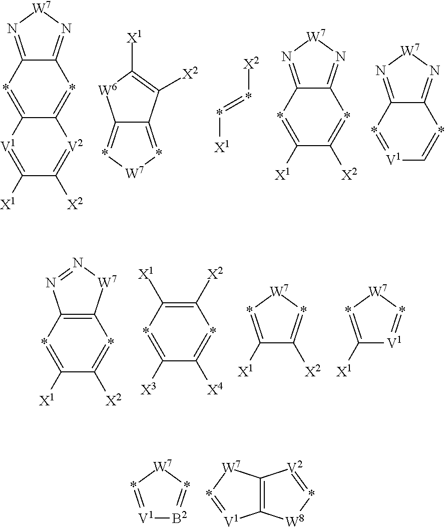

Wherein, W⁷ and W⁸ are further each independently selected from the group consisting of S, O, Se, CR¹¹R¹², SiR¹¹R¹², C—O, and NR¹¹. V¹ and V² are further each independently selected from CR¹¹ and N, wherein R¹¹ and R¹² are each independently defined as R¹ as defined previously. X¹, X², X³ and X⁴ are each independently defined as R¹ as defined previously.

Wherein, Ar¹⁰ and Ar¹¹ are further each independently selected from the group consisting of the following structures and their enantiomeric forms:

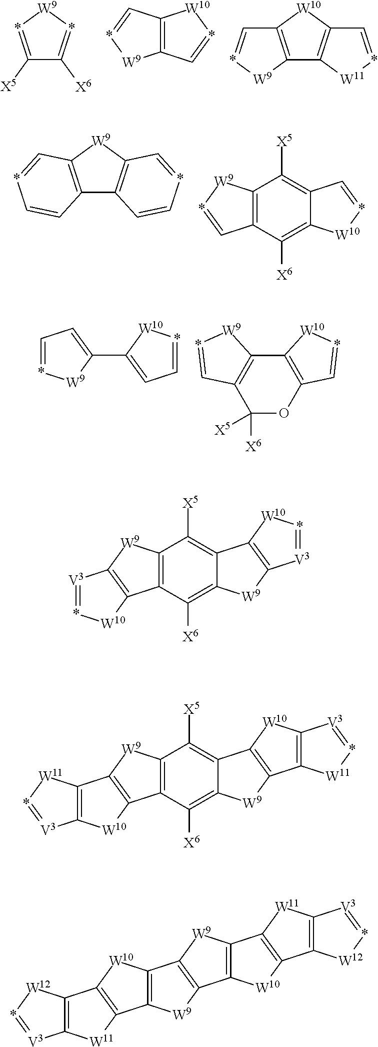

Wherein W⁹, W¹⁰, W¹¹ and W¹² are further each independently selected from the group consisting of S, O, Se, CR¹³R¹⁴, SiR¹³R¹⁴, C—O, and NR¹³. Each V³ is further each independently selected from CR¹³ and N. Wherein, R¹³ and R¹⁴ are each independently defined as R¹ as defined previously. X⁵ and X⁶ are each independently defined as R¹ as defined previously.

Wherein, Ar¹² is further selected from the group consisting of the following structures and their enantiomeric forms:

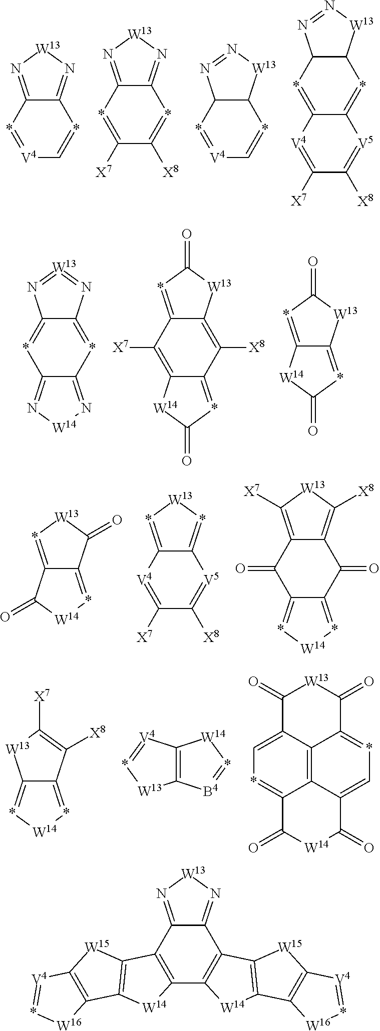

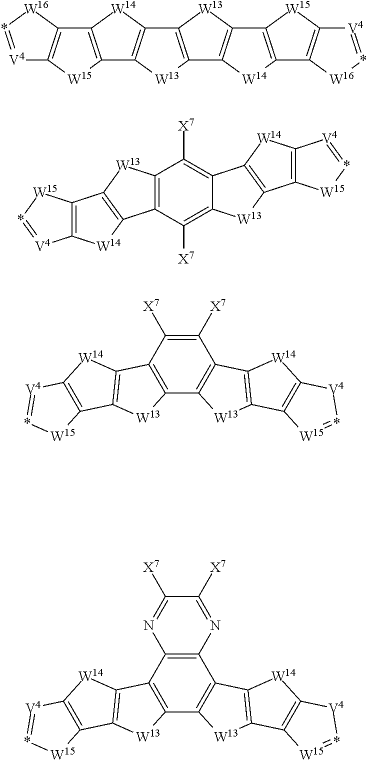

Wherein, W¹³, W¹⁴, W¹⁵ and W¹⁶ are further each independently selected from the group consisting of S, O, Se, CR¹⁵R¹⁶, SiR¹⁵R¹⁶, C═O, and NR¹⁵. V⁴ and V⁵ are further each independently selected from CR¹⁵ and N. R¹⁵, R¹⁶, X⁷ and X⁸ are each independently defined as R¹ as defined previously, and are optionally covalently bonded to at least one of the others, or each is a separate group.

Wherein, Ar¹³ and Ar¹⁴ are further each independently selected from the group consisting of the following structures and their enantiomeric forms:

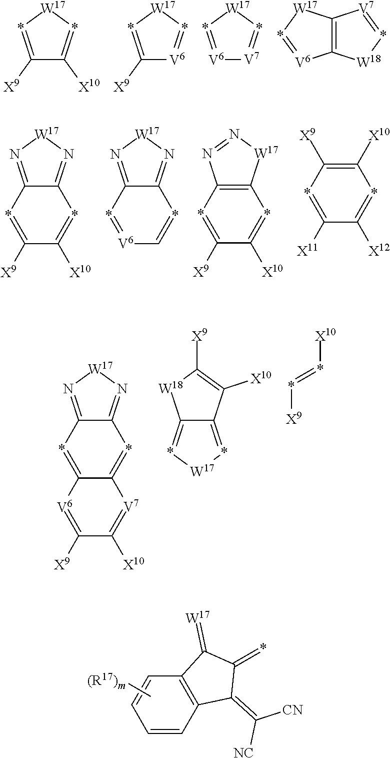

Wherein, W¹⁷ and W¹⁸ are further each independently selected from the group consisting of S, O, Se, CR¹⁷R¹⁸, SiR¹⁷R¹⁸, C═O, and NR¹⁷. V⁶ and V⁷ are further each independently selected from CR¹⁷ and N. R¹⁷, R¹⁸, X⁹, X¹⁰, X¹¹ and X¹² are each independently defined as R¹ as defined previously, and are optionally covalently bonded to at least one of the others, or each is a separate group. m is selected from the group consisting of 0, 1, 2, 3, and 4.

Wherein, RT¹ and RT² are further each independently selected from the group consisting of the following structures:

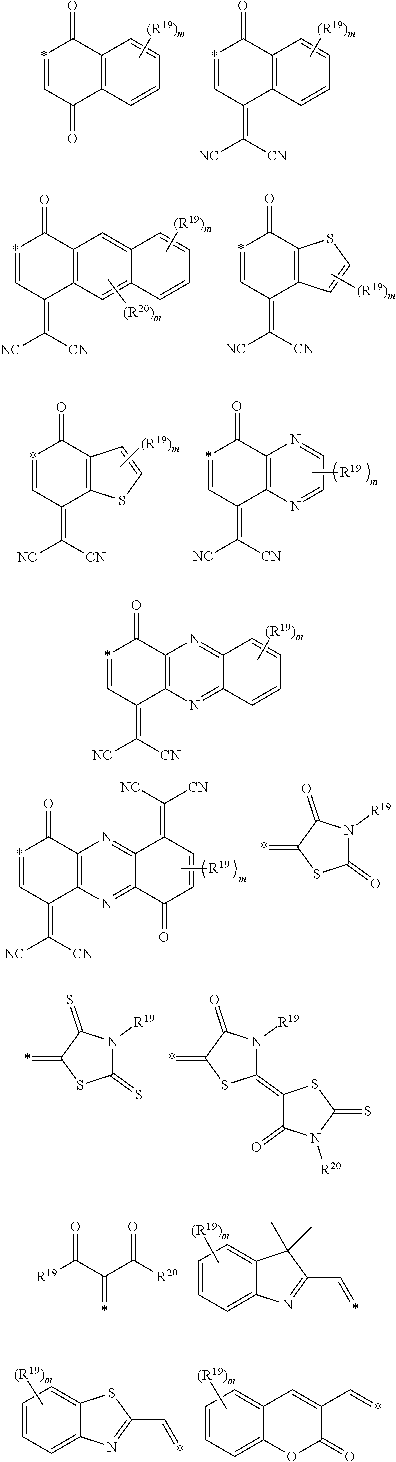

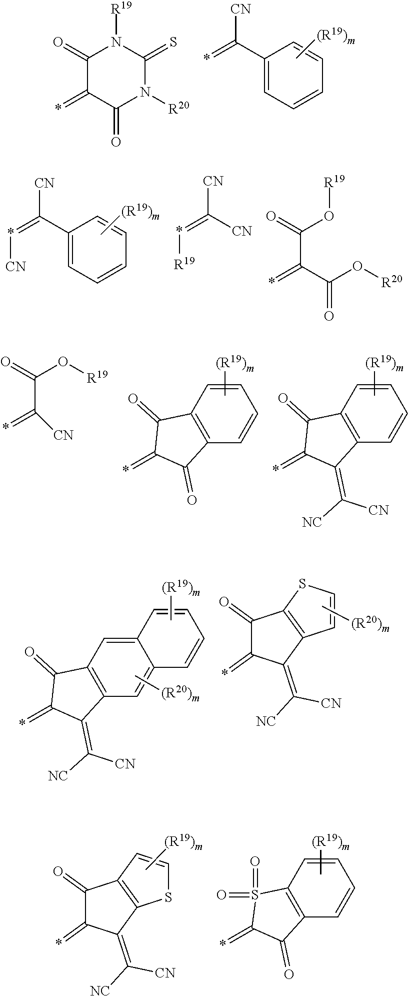

Wherein, R¹⁹ and R²⁰ are each independently defined as R¹ as defined previously. m is selected from the group consisting of 0, 1, 2, 3, and 4.

The second category of the present invention is to provide an organic composition comprising the organic random polymer described previously and at least one of a P-type organic semiconductor material and an N-type organic semiconductor material. Wherein, the P-type organic semiconductor material comprises at least one organic conjugated polymer or one organic conjugated small molecule, and the energy band gap of the N-type organic semiconductor material is from 0.5 to 2.0 eV.

The third category of the present invention is to provide an organic optoelectronic device comprising the organic random polymer described previously.

The fourth category of the present invention is to provide an organic optoelectronic device comprising a first electrode, an active layer and a second electrode. The active layer at least comprises an organic random polymer described previously. Wherein, the active layer is disposed between the first electrode and the second electrode, and at least one of the first electrode and the second electrode is a transparent or semi-transparent electrode.

The fifth category of the present invention is to provide an organic optoelectronic device comprising a first electrode, an active layer and a second electrode. The active layer at least comprises an organic composition described previously. Wherein, the active layer is disposed between the first electrode and the second electrode, and at least one of the first electrode and the second electrode is a transparent or semi-transparent electrode.

Compared with the prior art, the organic random polymer of the present invention exhibits the following advantages: (1) the organic random polymer of the present invention employs the 3-position of thiophene, rather than the 2-(3-oxo-2,3-dihydro-1H-inden-1-ylidene) malononitrile (IC) terminal group, as the polymerization site. As a result, no isomeric forms are generated. This structural design reduces the synthetic complexity, lowers production cost, and improves the synthetic yield, thereby providing advantages in large-scale production and commercial viability; (2) the organic random polymer of the present invention exhibits excellent thermal stability; (3) the organic random polymer of the present invention has a tunable absorption wavelength range and can be used as a single-component active layer; (4) the organic random polymer of the present invention has tunable energy levels and solubility, allowing it to be polymerized with different functional groups to prepare polymers with customized specifications for various application requirements; and (5) compared to commonly used halogenated solvents such as chloroform or chlorobenzene reported in the literature, the organic random polymer of the present invention can use non-halogenated solvents to process, which is more environmentally friendly.

### BRIEF DESCRIPTION OF THE APPENDED DRAWINGS

Some of the embodiments will be described in detail, with reference to the following figures, wherein like designations denote like members, wherein:

FIG. 1 shows a schematic structural diagram of one embodiment of an organic optoelectronic device of the present invention.

FIG. 2 shows absorption spectra in solution state of Comparative Example 1.

FIG. 3 shows absorption spectra in solution state of Polymer 1, Polymer 2, Polymer 4, Polymer 5, Polymer 8, and Polymer 9 of the organic random polymer of the present invention.

### DETAILED DESCRIPTION OF THE INVENTION

In order to make the advantages, spirit and features of the present invention easier and clearer, it will be detailed and discussed in the following with reference to the embodiments and the accompanying drawings. It is worth noting that the specific embodiments are merely representatives of the embodiments of the present invention, but it can be implemented in many different forms and is not limited to the embodiments described in this specification. Rather, these embodiments are provided so that this disclosure will be thorough and complete.

The terminology used in the various embodiments disclosed in the present invention is only for the purpose of describing specific embodiments, and is not intended to limit the various embodiments disclosed in the present invention. As used herein, singular forms also include plural forms unless the context clearly indicates otherwise. Unless otherwise defined, all terms (including technical and scientific terms) used in this specification have the same meanings as commonly understood by one of ordinary skill in the art to which the various embodiments disclosed herein belong. The above terms (such as those defined in commonly used dictionaries) will be interpreted as having the same meaning as the contextual meaning in the same technical field, and will not be interpreted as having an idealized or overly formal meaning, unless explicitly defined in the various embodiments disclosed herein.

In the description of this specification, the description of the reference terms “an embodiment”, “a specific embodiment” and the like means that specific features, structures, materials, or characteristics described in connection with the embodiment are included in at least one embodiment of the present invention. In this specification, the schematic expressions of the above terms do not necessarily refer to the same embodiment. Furthermore, the particular features, structures, materials, or characteristics described may be combined in any suitable manner in any one or more embodiments.

### Definition

As used herein, “donor” material and “p-type” (“P-type”) material refer to a semiconductor material, such as an organic semiconductor material, having holes as a primary current or charge carrier. In some embodiments, when a p-type semiconductor material is deposited on a substrate, it can provide the hole mobility greater than about 10⁻⁵ cm²/Vs.

As used herein, “acceptor” material and “n-type” (“N-type”) material refer to the semiconductor material, such as the organic semiconductor material, having electrons as the primary current or the charge carrier. In some embodiments, when an n-type semiconductor material is deposited on a substrate, it can provide the electron mobility of more than about 10⁻⁵ cm²/Vs.

“*” or “*” in the structures listed herein represents the available bonding positions of this structure, but not limited thereto.

As used herein, “solution process” refers to a process in which a compound (e.g., a polymer), material, or composition can be used in a solution state, such as spin coating, printing (e.g., inkjet printing, gravure printing, and lithography printing), spray coating, slit coating, drop casting, dip coating, and blade coating.

As used herein, “annealing” refers to a post-deposition thermal treatment to a semi-crystalline polymer film for certain duration in the environment or under decompressed or pressurized environment. “Annealing temperature” refers to the temperature at which the polymer film or the mixed film of the polymer and other molecules can perform small-scale molecular movement and rearrangement during the annealing process. Without being limited by any particular theory, it is believed that annealing can lead to an increase in crystallinity in the polymer film and enhance the carrier mobility of the polymer film or a mixed film formed by the polymer and other molecules, and the molecules are arranged alternately to achieve the effect of independent transporting paths of effective electrons and holes.

The external quantum efficiency (EQE) as used herein is the spectral response Amp/Watt unit, which Amp is converted to the number of electrons per unit time (electron/sec) and Watt is converted to the number of photons per unit time (Photons/sec), and insert the quantum efficiency obtained by the above formula. Generally speaking, quantum efficiency (QE) refers to external quantum efficiency (EQE), also known as incident photon-electron conversion efficiency (IPCE).

In an embodiment, an organic random polymer comprises a structure such as

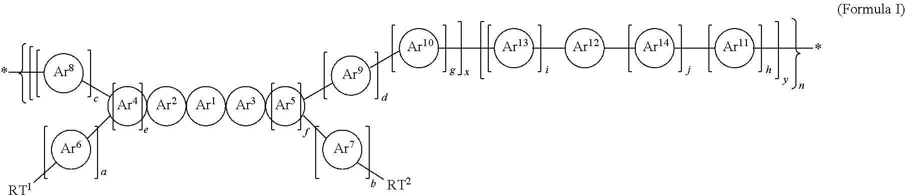

Wherein, Ar¹, Ar⁴, Ar⁵, Ar¹³, and Ar¹⁴ are each independently selected from arylene or heteroarylene having 5 to 20 ring atoms, Ar¹, Ar⁴, Ar⁵, Ar¹³, and Ar¹⁴ comprise monocyclic, polycyclic, or fused ring structure, and optionally unsubstituted or substituted with one or more identical or different R¹ or L¹, Ar² and Ar³ are each independently selected from the group consisting of

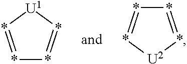

Wherein, U¹ and U² are each independently selected from the group consisting of NR¹, C═O, O, S, Se, SiR¹R², and CR¹R². Ar⁶, Ar⁷, Ar⁸, and Ar⁹ are each independently selected from the group consisting of a structure having —CY¹=CY²— or —C≡C—, arylene having 5 to 20 ring atoms and heteroarylene having 5 to 20 ring atoms, Ar⁶, Ar⁷, Ar⁸, and Ar⁹ comprise monocyclic, polycyclic, or fused ring structure, and optionally unsubstituted or substituted with one or more identical or different R¹ or L¹. Ar¹⁰, Ar¹¹, and Ar¹² are each independently selected from arylene or heteroarylene having 5 to 30 ring atoms, Ar¹⁰, Ar¹¹, and Ar¹² comprise monocyclic, polycyclic, or fused ring structure, and optionally unsubstituted or substituted with one or more identical or different R¹ or L¹. Wherein, R¹ and R² are each independently selected from the group consisting of H, F, Cl, CN, C1-C30 straight-chain alkyl, C1-C30 branched alkyl, and C1-C30 cyclic alkyl. Wherein, one or more CH₂ of alkyl are optionally replaced by at least one group selected from the group consisting of —O—, —S—, —C(═O)—, —C(═S)—, —C(═O)—O—, —O—C(═O)—, —NR⁰—, —SiR⁰R⁰⁰—, —CF₂—, —CR⁰=CR⁰⁰—, —CY¹=CY²—, and —C≡C—. Wherein, O and S are not directly bonded to each other, and one or more atoms are optionally substituted with F, Cl, Br, I, or CN. Wherein, one or more CH₂ or CH₃ are optionally substituted with at least one of cation, anion, aryl, heteroaryl, aralkyl, heteroaralkyl, aryloxy, and heteroaryloxy. Wherein, the aryl and the heteroaryl are each independently selected from monocyclic, polycyclic, or fused ring structures having 5 to 20 ring atoms, and the alkyl is optionally unsubstituted or substituted with one or more identical or different L¹. L′ is selected from the group consisting of F, Cl, —NO₂, —CN, —NC, —NCO, —NCS, —OCN, —SCN, R⁰, OR⁰, SR⁰, —C(═O)X⁰, —C(═O)R⁰, —C(═O)—OR⁰, —O—C(═O)—R⁰, —NH₂, —NHR⁰, —NR⁰R⁰⁰, —C(═O)NHR⁰, —C(, O)NR⁰R⁰⁰, —SO₃R⁰, —SO₂R⁰, —OH, —NO₂, —CF₃, —SF₅, and C1-C30 silane, C1-C30 carbonyl and C1-C30 hydrocarbon optionally substituted or unsubstituted with one or more heteroatoms, wherein the heteroatom comprises N, O, S, and Se. In practice, L′ is preferably selected from the group consisting of C1-C20 silane, C1-C20 carbonyl and C1-C20 hydrocarbon optionally substituted or unsubstituted with one or more heteroatoms. Wherein, R⁰ and R⁰⁰ are each independently selected from the group consisting of H and C1-C20 straight-chain alkyl and C1-C20 branched alkyl, and optionally fluorinated. X⁰ is halogen. Y¹ and Y² are each independently selected from the group consisting of H, F, Cl, and CN. In practice, X⁰ is preferably selected from F or Cl. a, b, c, d, e, f, g, h, i, and j are integers, each independently selected from 0 or 1 to 10. x and y are mole ratio, and x+y=1. n is the number of repeating units and is an integer selected from 1 to 1000. RT¹ and RT² are electron-withdrawing groups. Wherein, * is a bonding position.

Wherein, Ar¹ is further selected from the group consisting of the following structures:

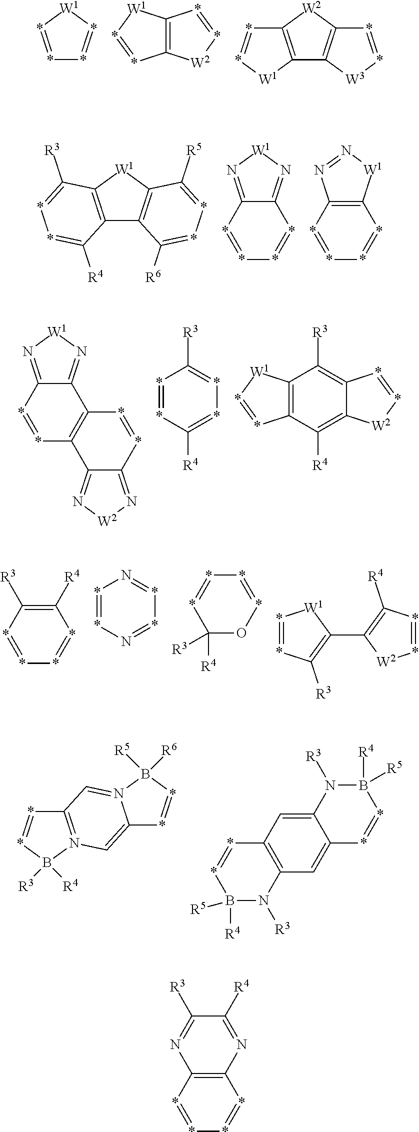

Wherein, W¹, W², and W³ are each independently selected from the group consisting of S, O, Se, CR³R⁴, SiR³R⁴, C—O, and NR³. R³, R⁴, R⁵ and R⁶ are each independently defined as R¹ as defined previously and are optionally covalently bonded to at least one of the others, or each is a separate group.

In practice, Ar¹ is preferably selected from the group consisting of the following

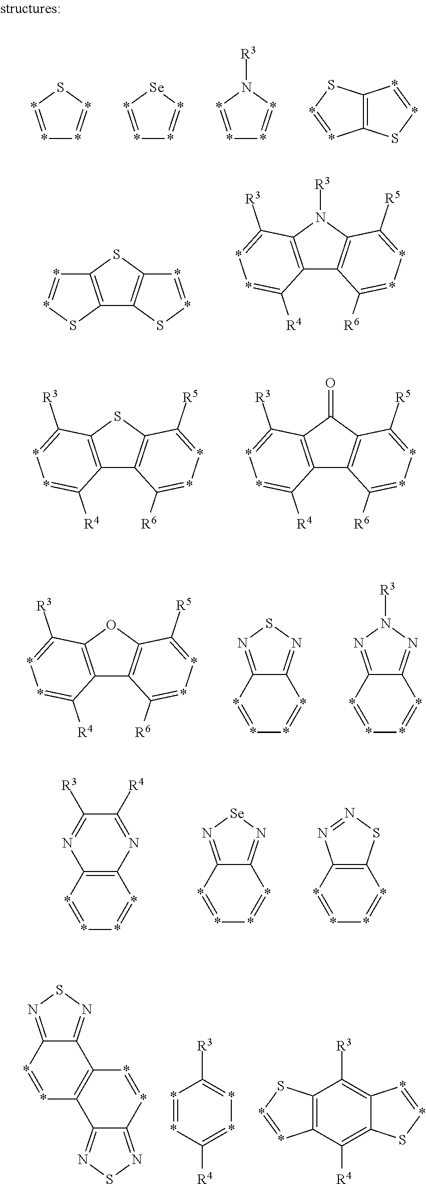

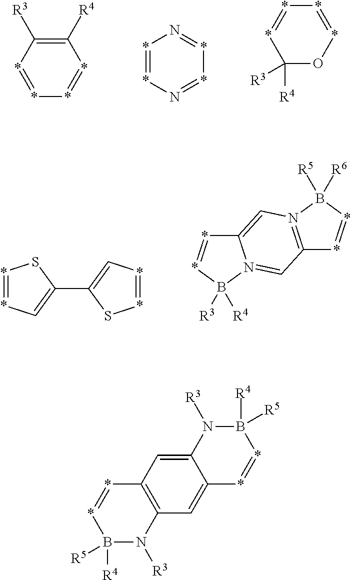

Wherein, Ar² and Ar³ are further each independently selected from the group consisting of the following structures:

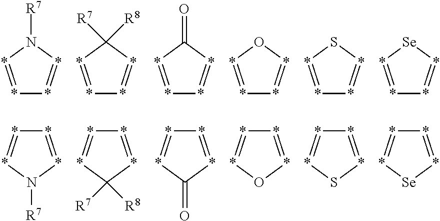

Wherein, R⁷ and R⁸ are each independently defined as R¹ as defined previously.

Wherein, Ar⁴ and Ar⁵ are further each independently selected from the group consisting of the following structures and their enantiomeric forms:

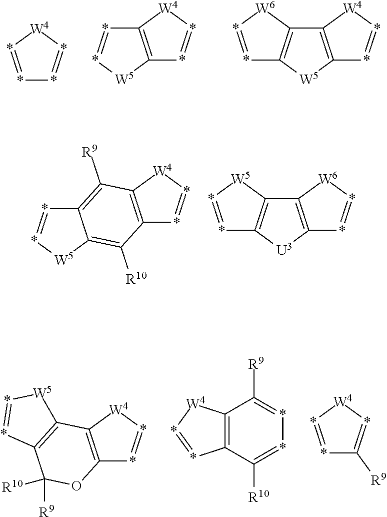

Wherein, W⁴, W⁵, and We are each independently selected from the group consisting of S, O, Se, CR⁹R¹⁰, SiR⁹R¹⁰, C—O, and NR⁹. R⁹ and R¹⁰ are each independently defined as R¹ as defined previously. U³ is selected from the group consisting of NR¹, C═O, O, S, Se, SiR¹R², and CR¹R².

In practice, Ar⁴ is preferably selected from the group consisting of the following structures:

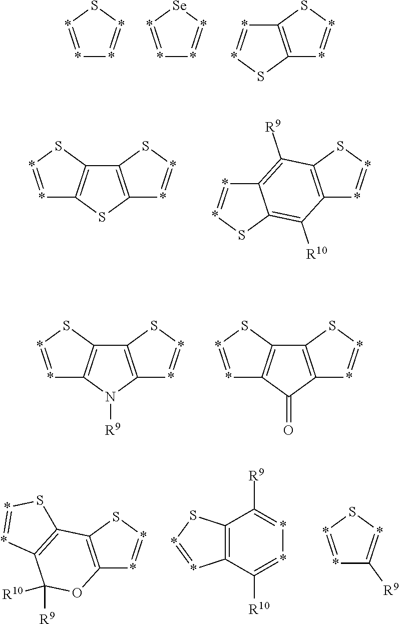

In practice, Ar⁵ is preferably selected from the group consisting of the following structures:

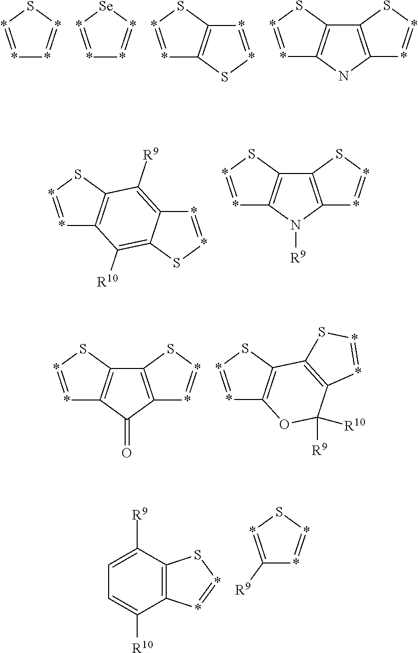

Wherein, Ar⁶, Ar⁷, Ar⁸ and Ar⁹ are further each independently selected from the group consisting of the following structures and their enantiomeric forms:

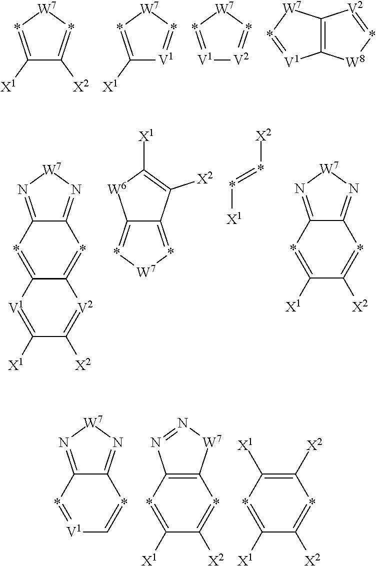

Wherein, W⁷ and W⁸ are further each independently selected from the group consisting of S, O, Se, CR¹¹R¹², SiR¹R¹², C—O, and NR¹¹. V¹ and V² are further each independently selected from CR¹¹ and N, wherein R¹¹ and R¹² are each independently defined as R¹ as defined previously. X¹, X², X³ and X⁴ are each independently defined as R¹ as defined previously.

In practice, Ar⁶, Ar⁷, Ar⁸ and Ar⁹ are preferably each independently selected from the group consisting of the following structures:

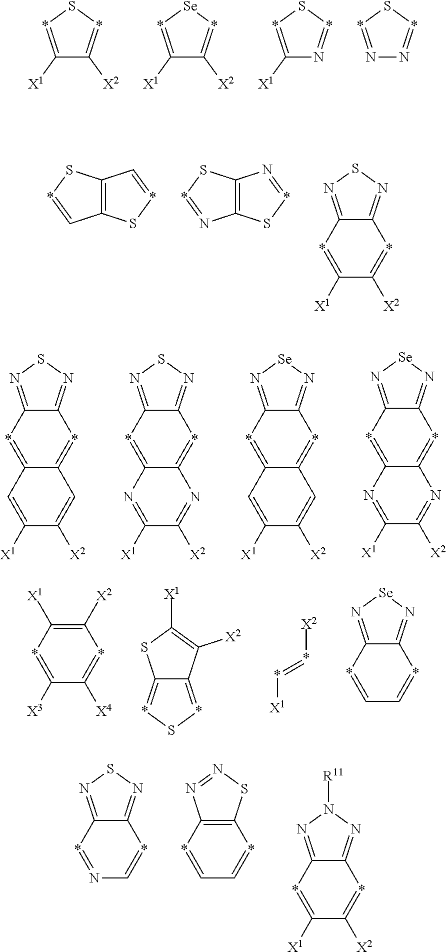

Wherein, Ar¹⁰ and Ar¹¹ are further each independently selected from the group consisting of the following structures and their enantiomeric forms:

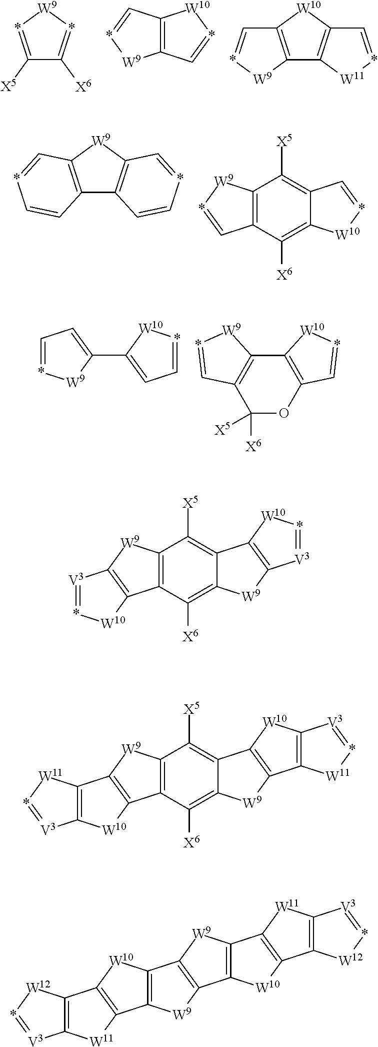

Wherein W⁹, W¹⁰, W¹¹ and W¹² are further each independently selected from the group consisting of S, O, Se, CR¹³R¹⁴, SiR¹³R¹⁴, C—O, and NR¹³. Each V³ is further each independently selected from CR¹³ and N. Wherein, R¹³ and R¹⁴ are each independently defined as R¹ as defined previously. X⁵ and X⁶ are each independently defined as R¹ as defined previously.

In practice, Ar¹⁰ and Ar¹¹ are preferably each independently selected from the group consisting of the following structures and their enantiomeric forms:

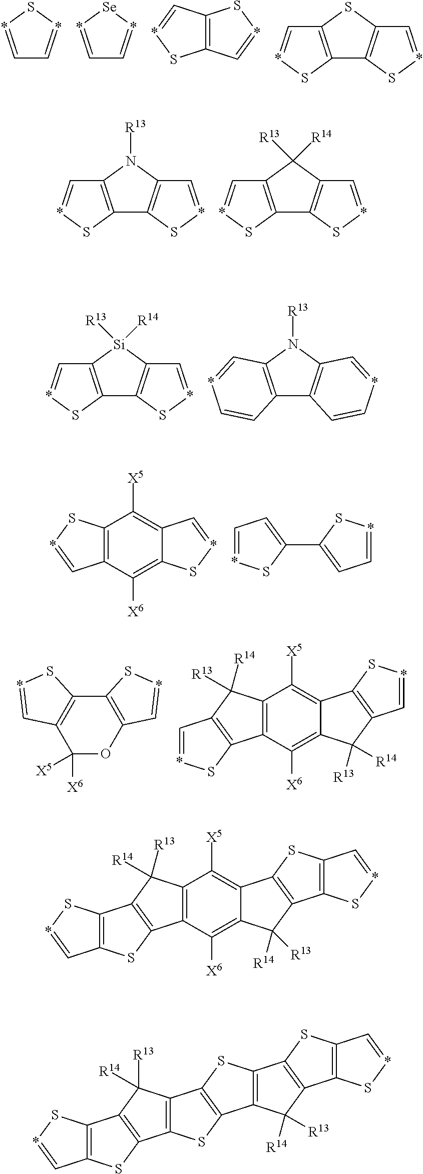

Wherein, Ar¹² is further selected from the group consisting of the following structures and their enantiomeric forms:

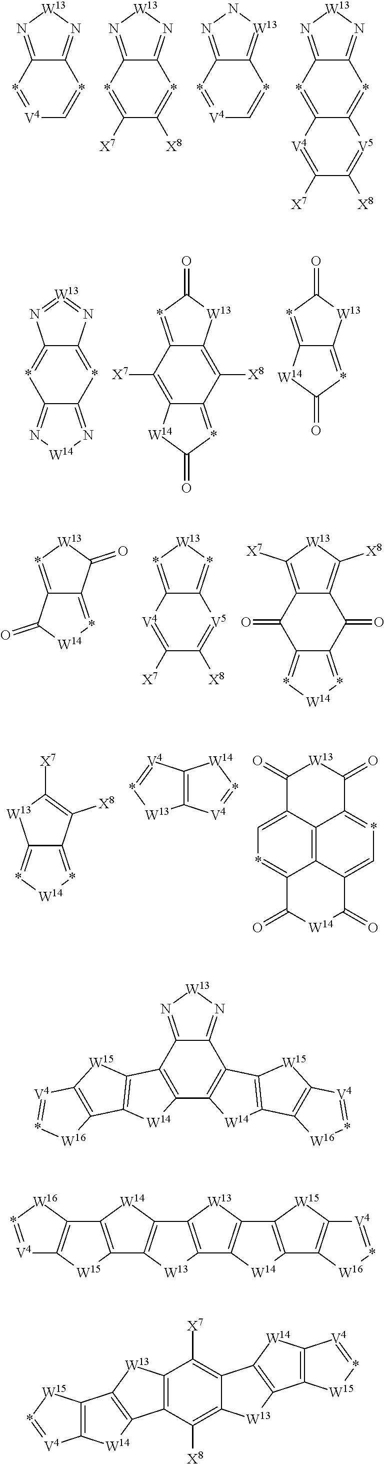

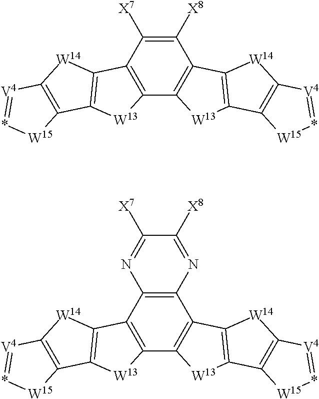

Wherein, W¹³, W¹⁴, W¹⁵ and W¹⁶ are further each independently selected from the group consisting of S, O, Se, CR¹⁵R¹⁶, SiR¹⁵R¹⁶, C—O, and NR¹⁵. V⁴ and V⁵ are further each independently selected from CR¹⁵ and N. R¹⁵, R¹⁶, X⁷ and X⁸ are each independently defined as R¹ as defined previously, and are optionally covalently bonded to at least one of the others, or each is a separate group.

In practice, Ar¹² is preferably selected from the group consisting of the following structures and their enantiomeric forms:

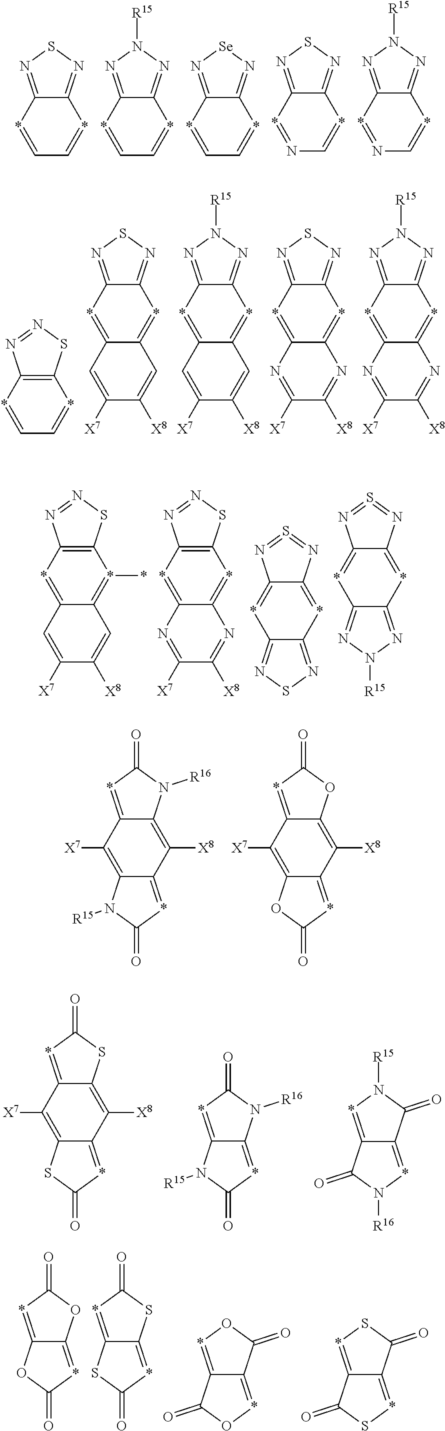

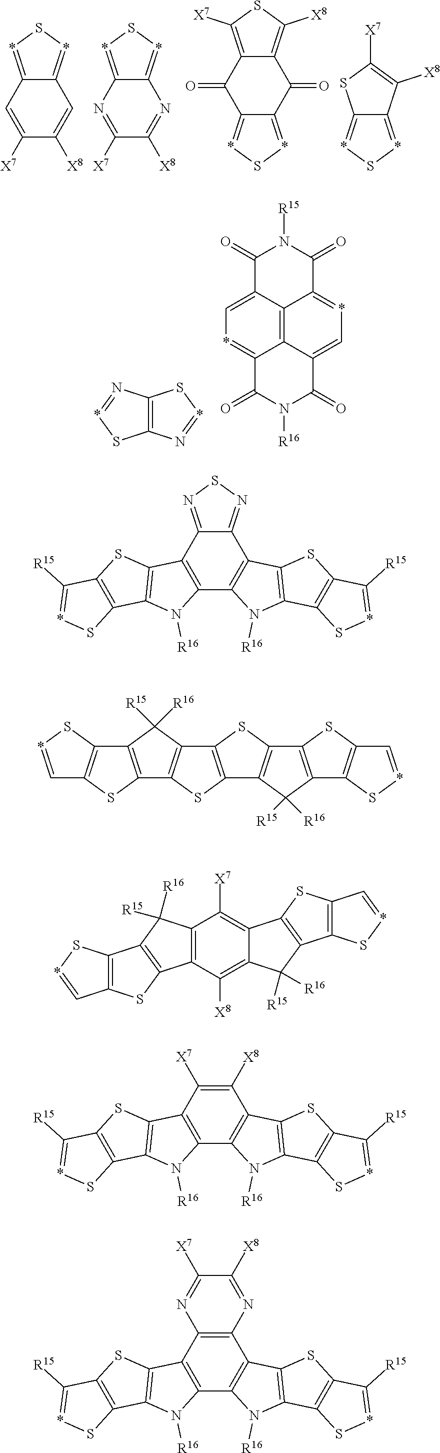

Wherein, R¹⁵, R¹⁶, X⁷ and X⁸ are each independently defined as R¹ as defined previously, and are optionally covalently bonded to at least one of the others, or each is a separate group.

Wherein, Ar¹³ and Ar¹⁴ are further each independently selected from the group consisting of the following structures and their enantiomeric forms:

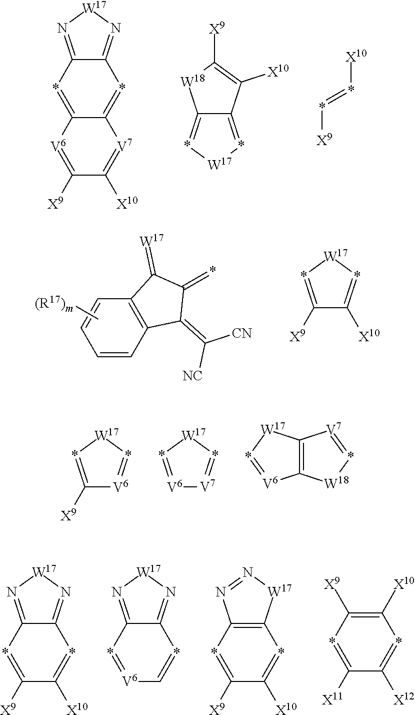

Wherein, W¹⁷ and W¹⁸ are further each independently selected from the group consisting of S, O, Se, CR¹⁷R¹⁸, SiR¹⁷R¹⁸, C═O, and NR¹⁷. V⁶ and V⁷ are further each independently selected from CR¹⁷ and N. R¹⁷, R¹⁸, X⁹, X¹⁰, X¹¹ and X¹² are each independently defined as R¹ as defined previously, and are optionally covalently bonded to at least one of the others, or each is a separate group. m is selected from the group consisting of 0, 1, 2, 3, and 4.

In practice, Ar¹³ and Ar¹⁴ are preferably each independently selected from the group consisting of the following structures and their enantiomeric forms:

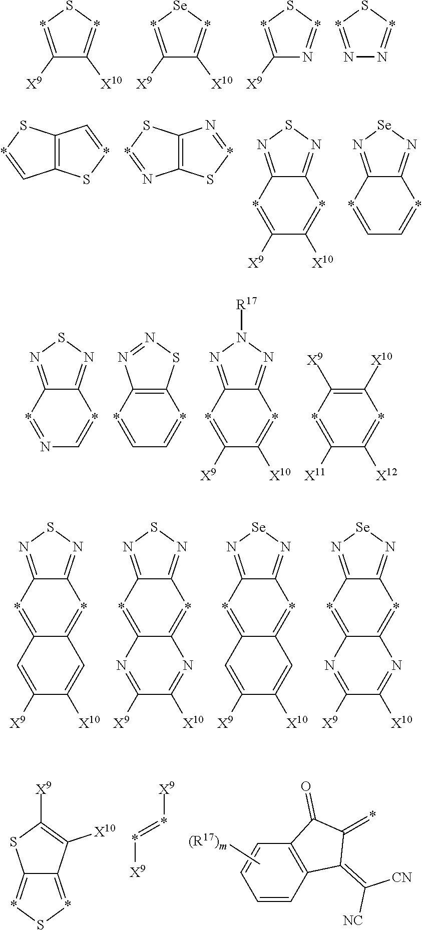

Wherein, RT¹ and RT² are further each independently selected from the group consisting of the following structures:

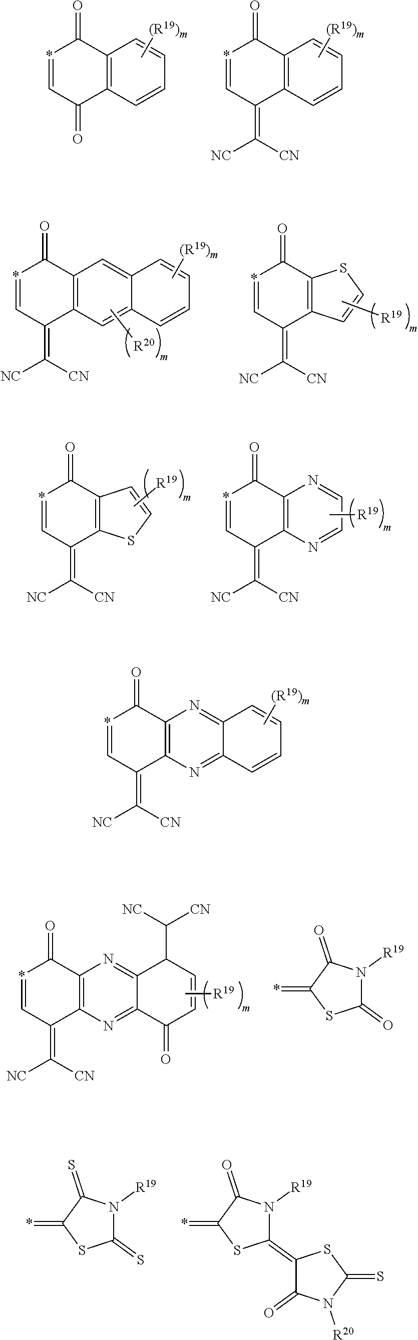

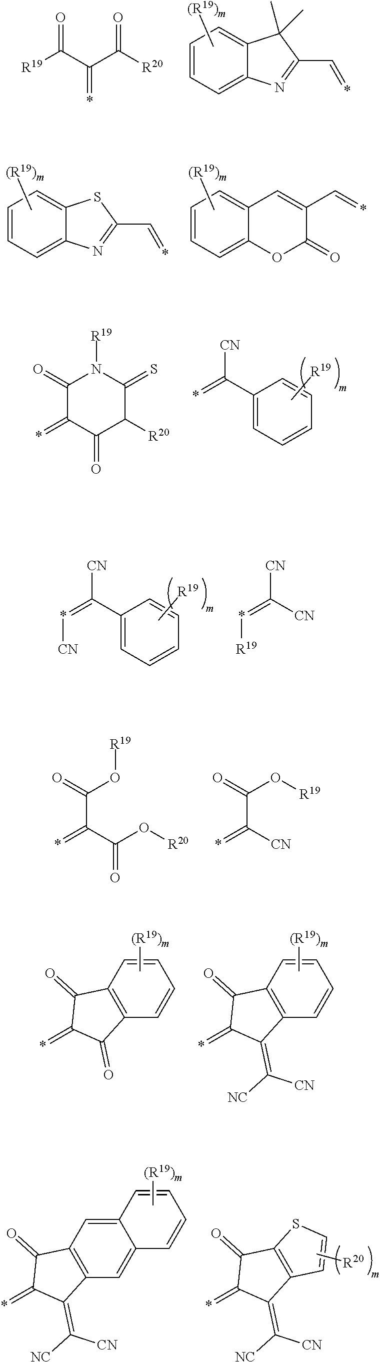

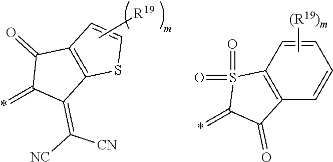

Wherein, R¹⁹ and R²⁰ are each independently defined as R¹ as defined previously. m is selected from the group consisting of 0, 1, 2, 3, and 4.

It should be noted that, in the foregoing description, the expression “as defined as R¹ defined previously” is used to define the following substituents for the purpose of avoiding redundant and lengthy repetition. However, this does not imply that each substituent must be limited by the definition of R′ and each substituent may include different substituents as required. In practice, R¹, R², R³, R⁴, R⁵, R⁶, R⁷, R⁸, R⁹, R¹⁰, R¹, R¹², R¹³, R¹⁴, R¹⁵, R¹⁶, R^{16a}, R¹⁷, R¹⁸, R¹⁹, R²⁰, X¹, X², X³, X⁴, X⁵, X⁶, X⁷, X⁸, X⁹, X¹⁰, X¹¹ and X¹² are each independently selected from the group consisting of H, F, Cl, CN, C1-C30 straight-chain alkyl, C1-C30 branched alkyl, and C1-C30 cyclic alkyl. Wherein, one or more CH₂ of alkyl are optionally replaced by at least one group selected from the group consisting of —O—, —S—, —C(═O)—, —C(═S)—, —C(═O)—O—, —O—C(═O)—, —NR⁰—, —SiR⁰R⁰⁰—, —CF₂—, —CR⁰=CR⁰⁰—, —CY¹=CY²—, and —C≡C—. Wherein, O and S are not directly bonded to each other, and one or more atoms are optionally substituted with F, Cl, Br, I, or CN. Wherein, one or more CH₂ or CH₃ are optionally substituted with at least one of cation, anion, aryl, heteroaryl, aralkyl, heteroaralkyl, aryloxy, and heteroaryloxy. Wherein, the aryl and the heteroaryl are each independently selected from monocyclic, polycyclic, or fused ring structures having 5 to 20 ring atoms, and the alkyl is optionally unsubstituted or substituted with one or more identical or different L¹.

In details, the organic material could comprise the following embodiments A1 to

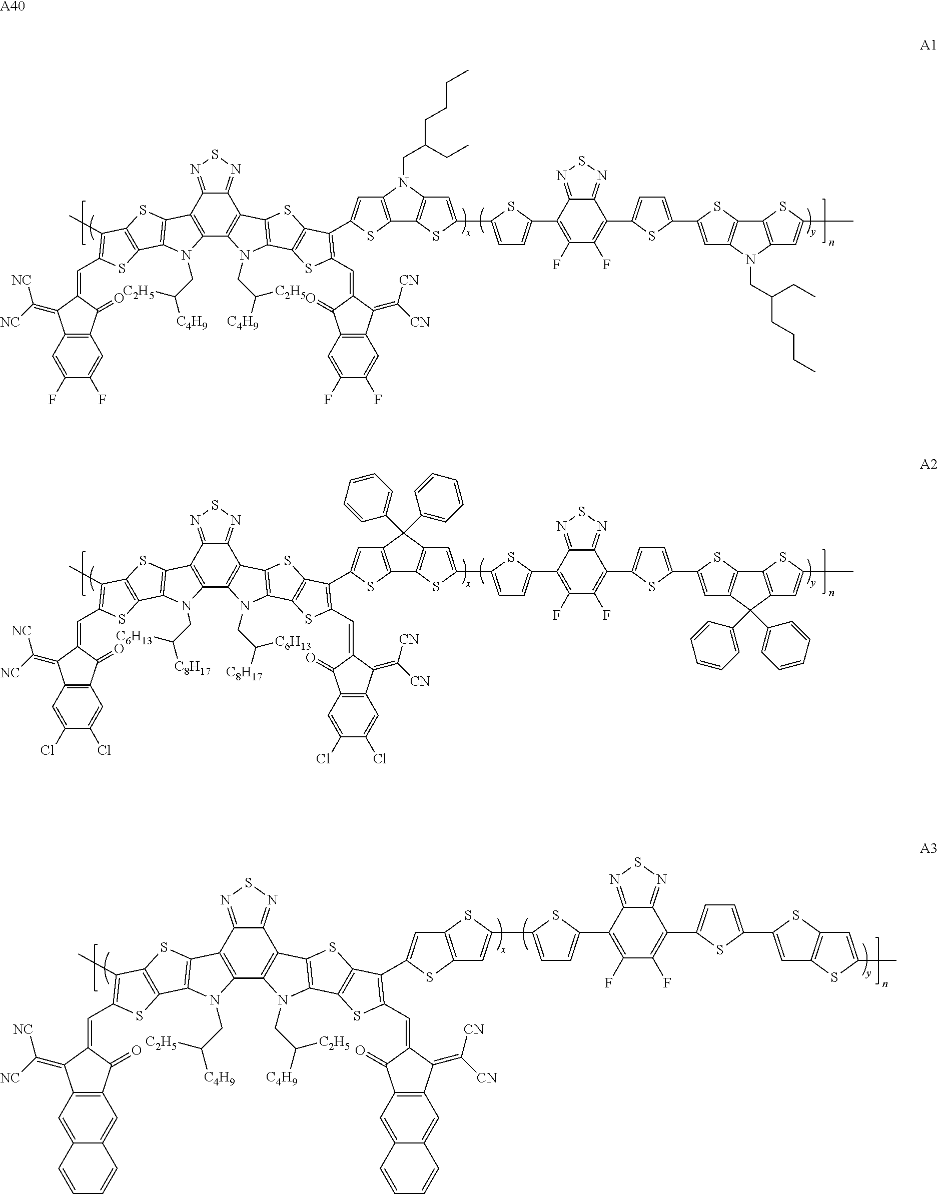

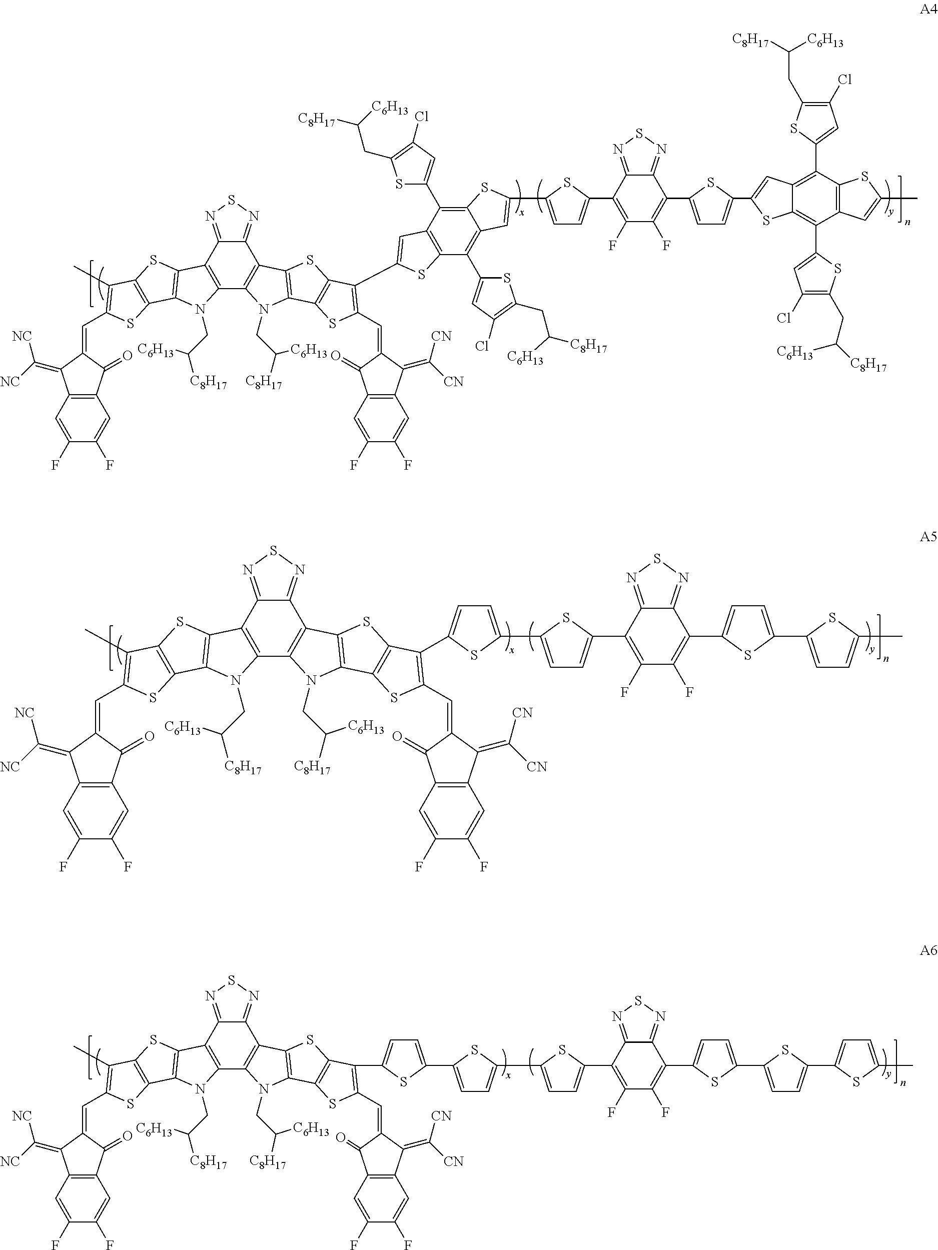

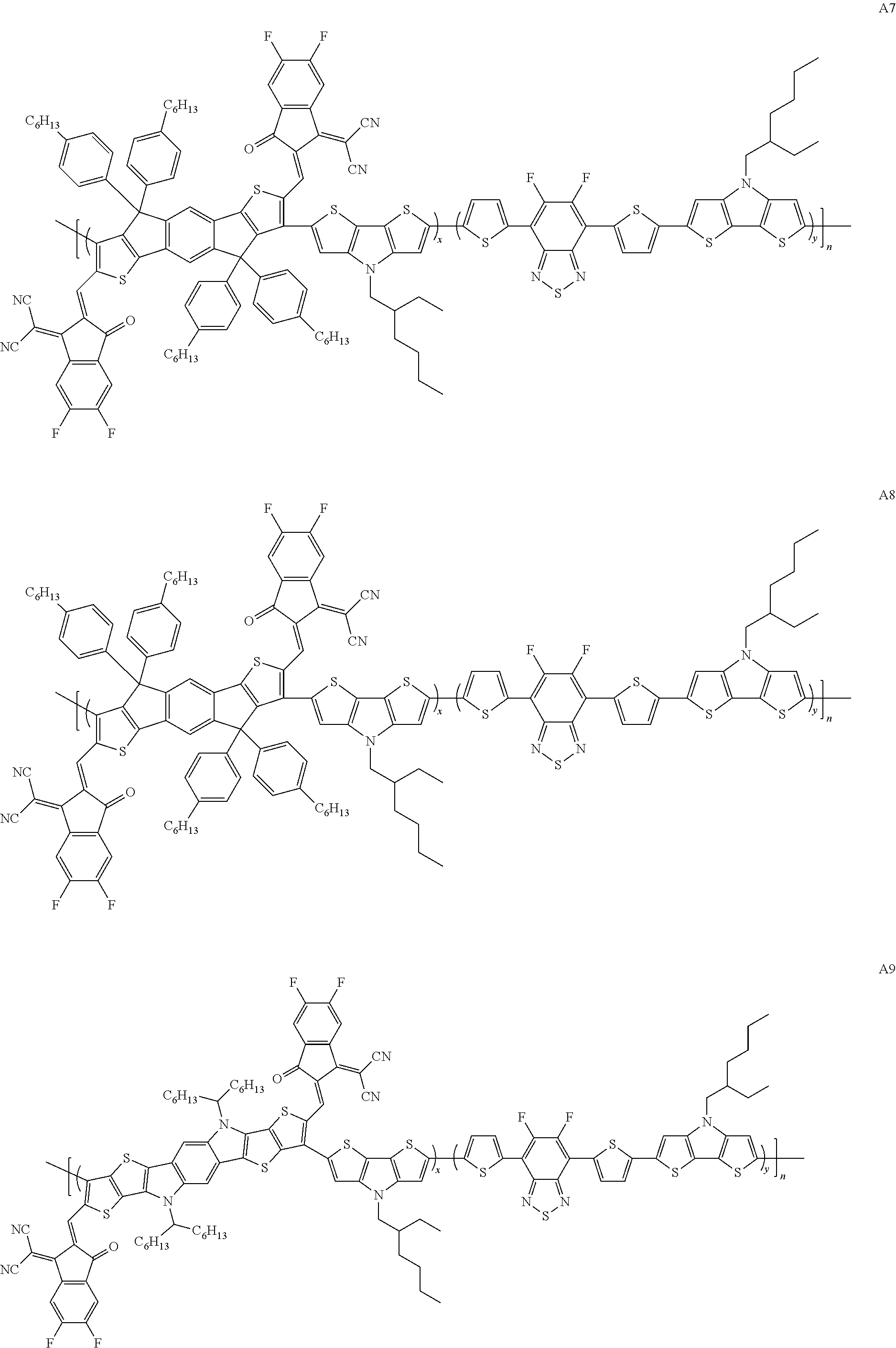

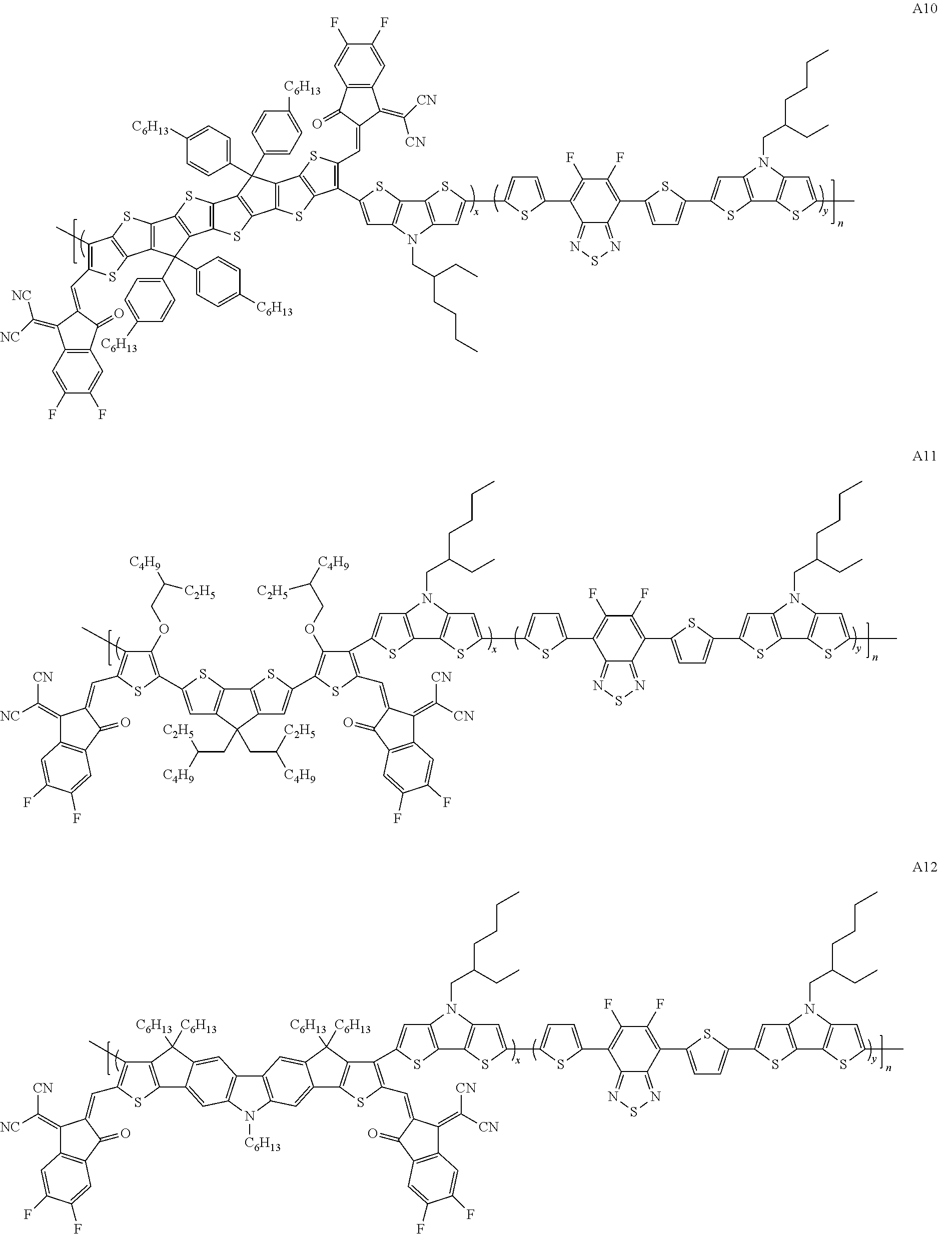

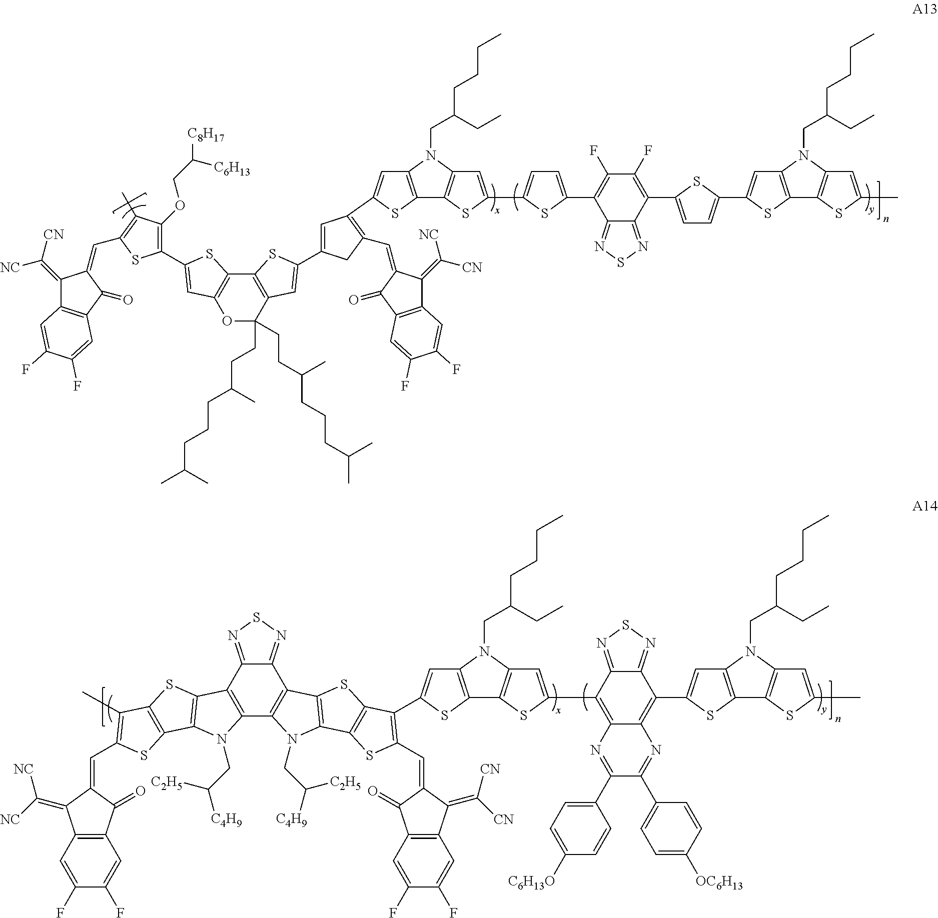

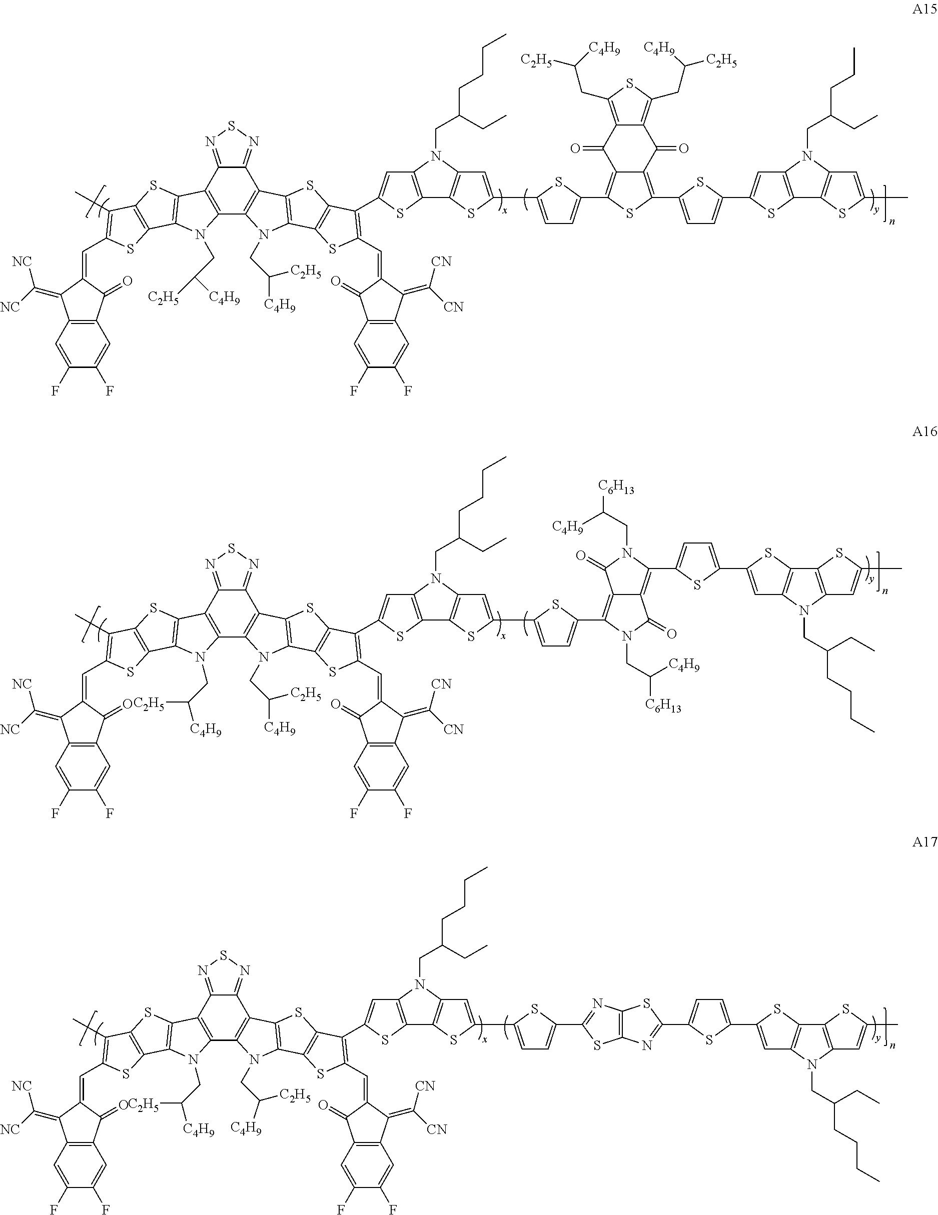

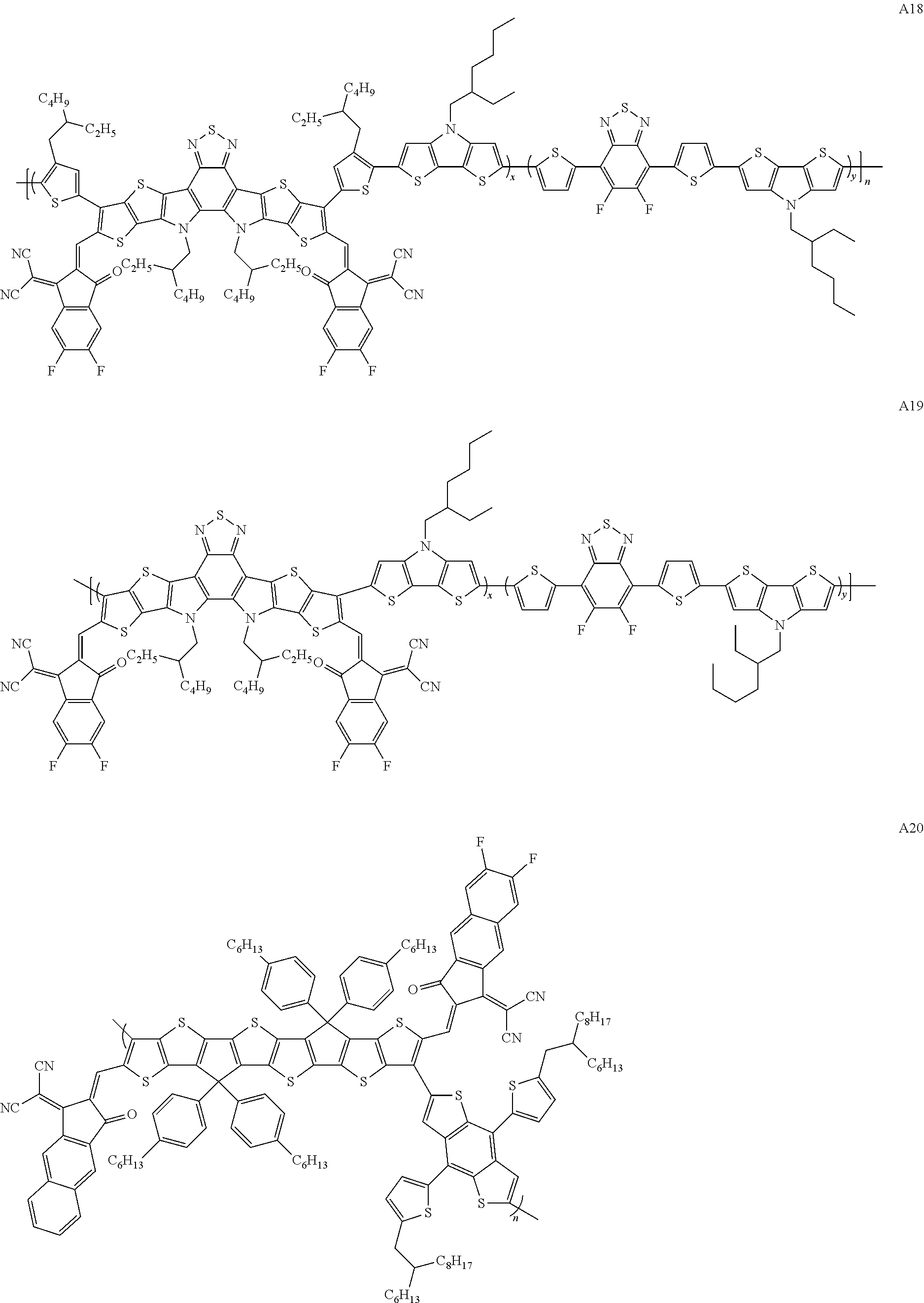

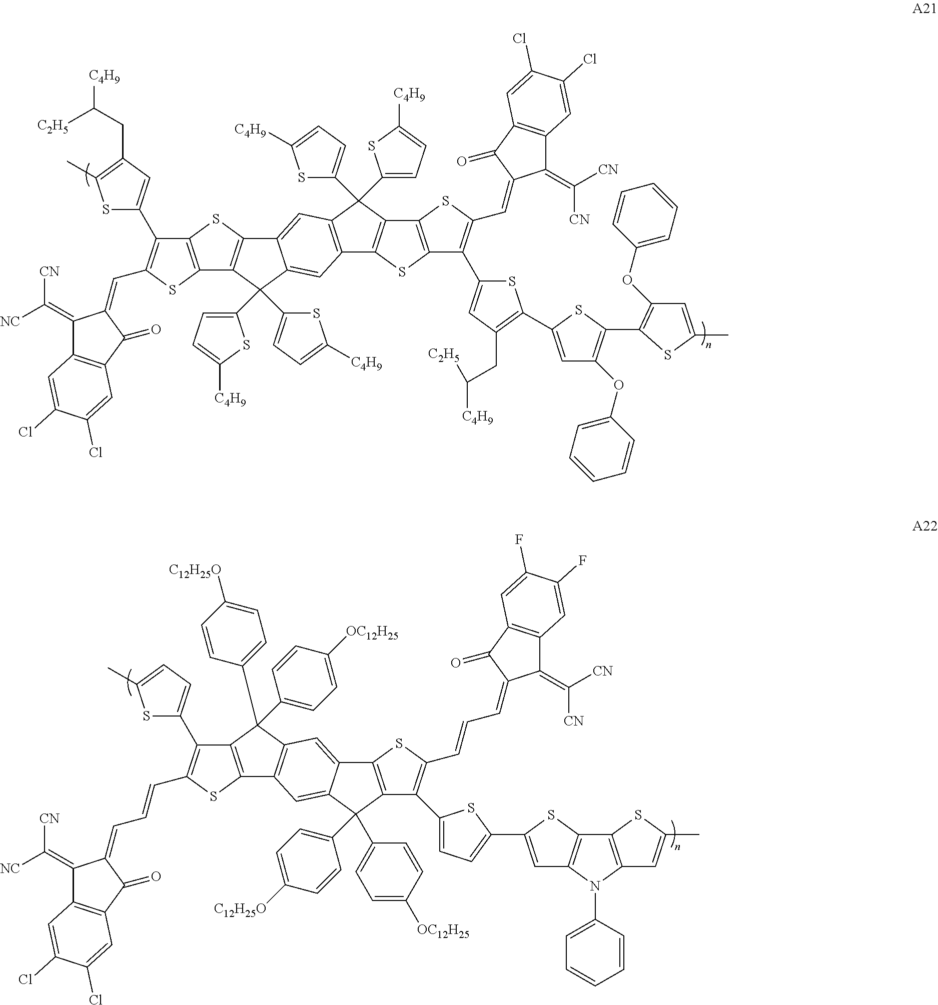

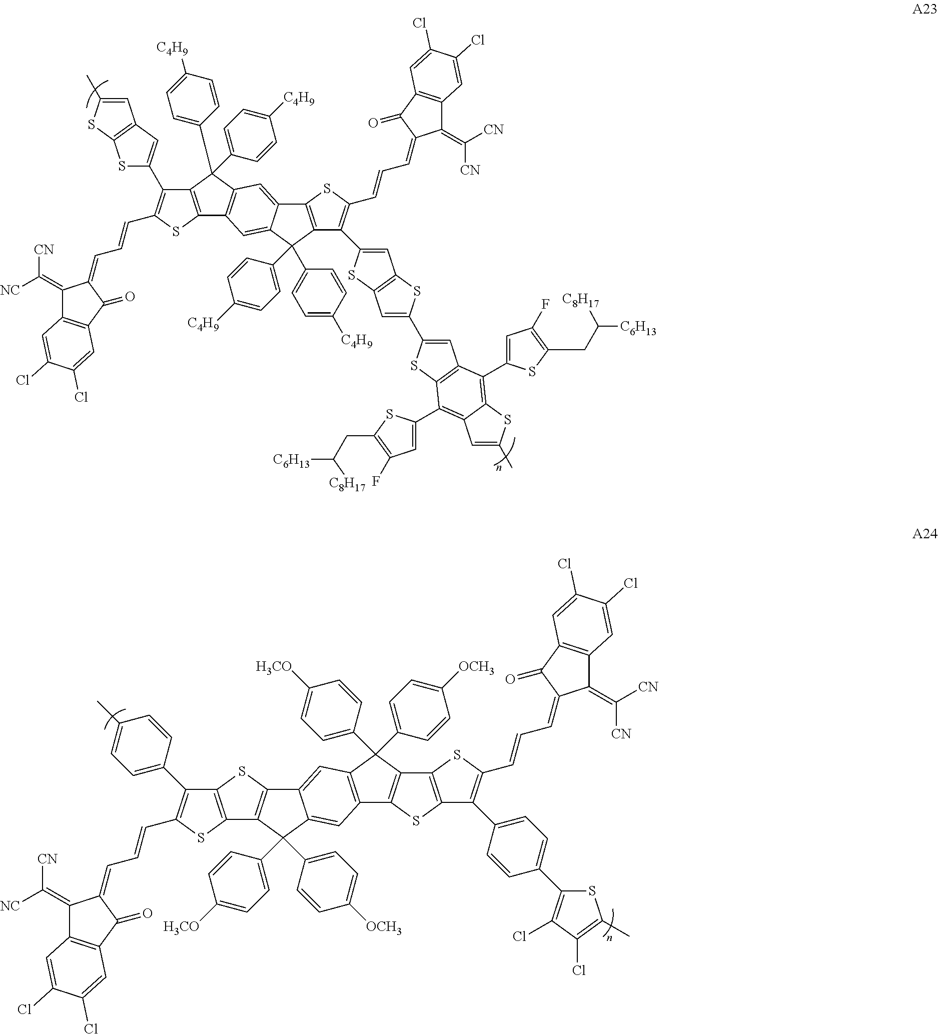

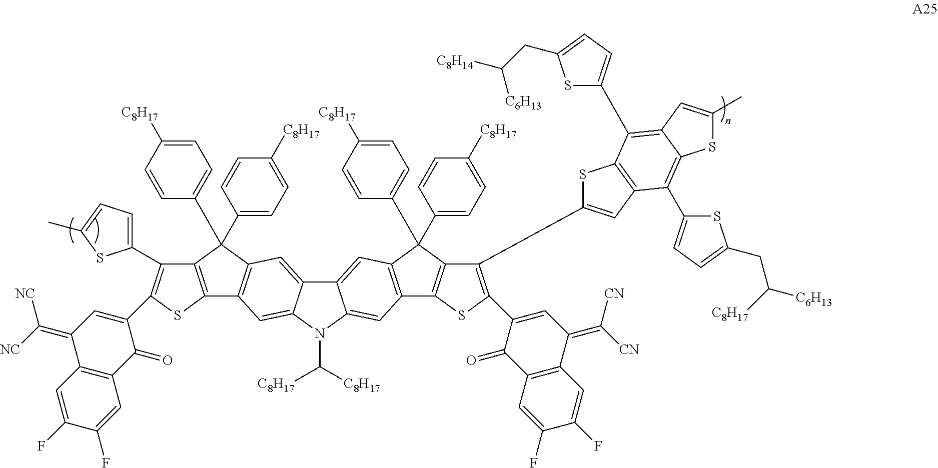

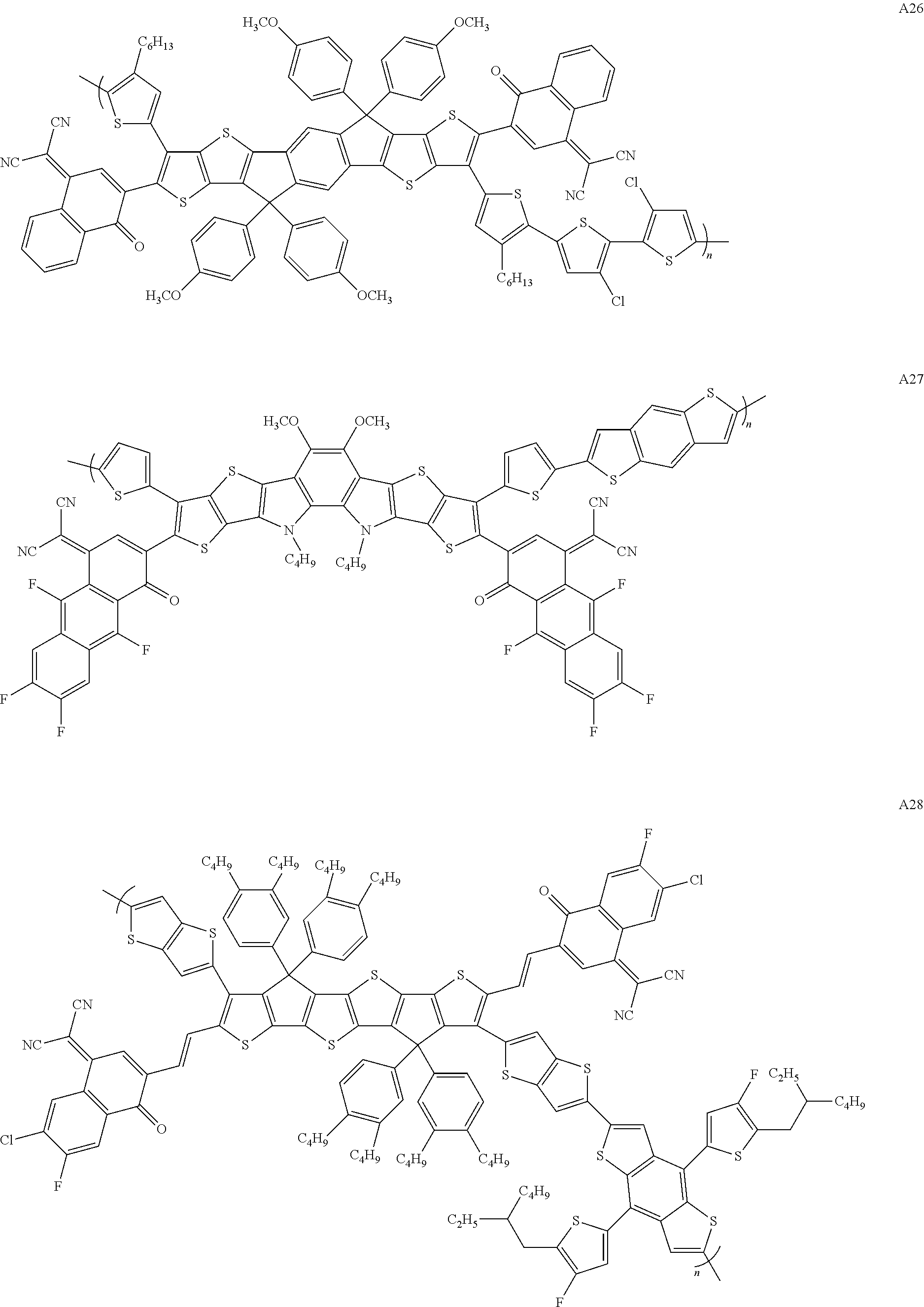

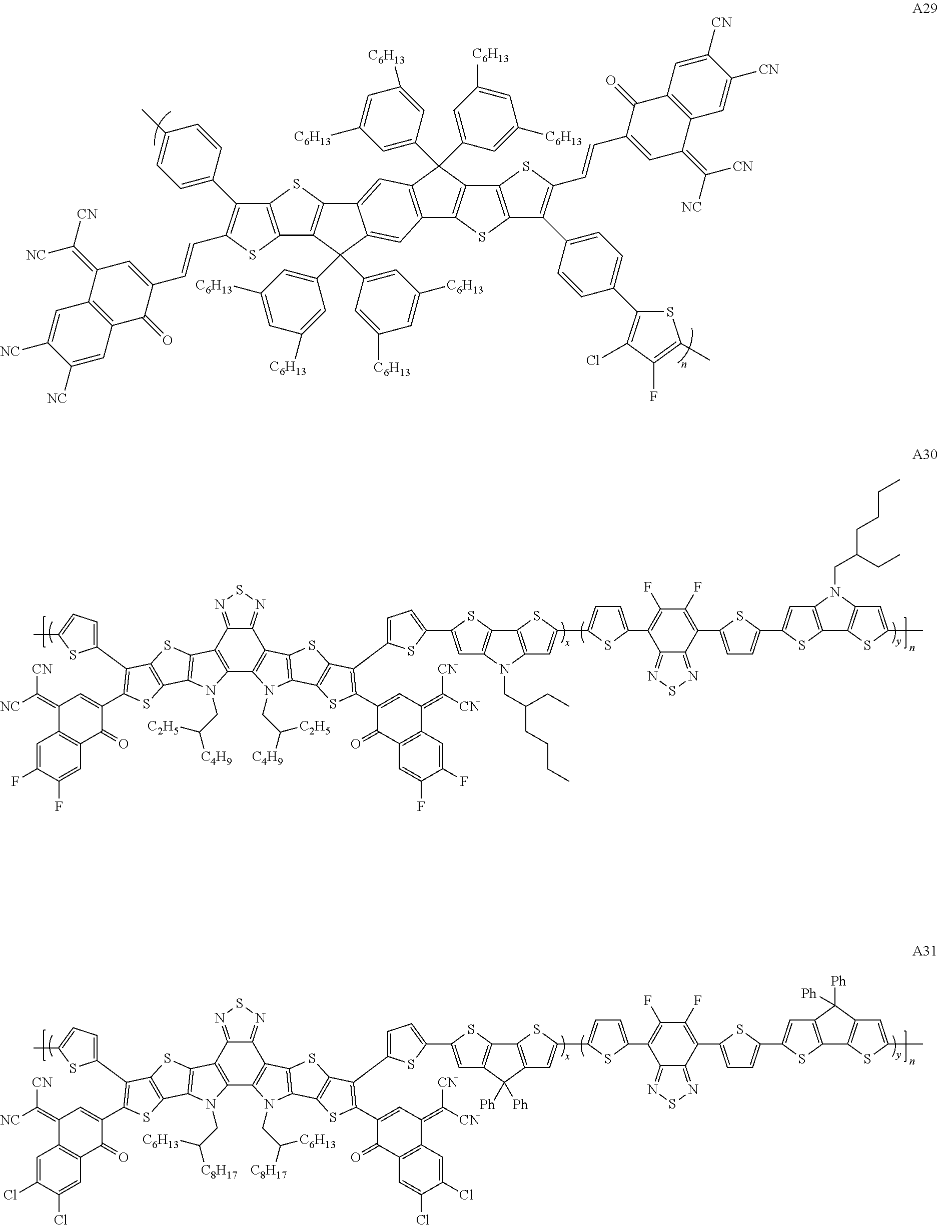

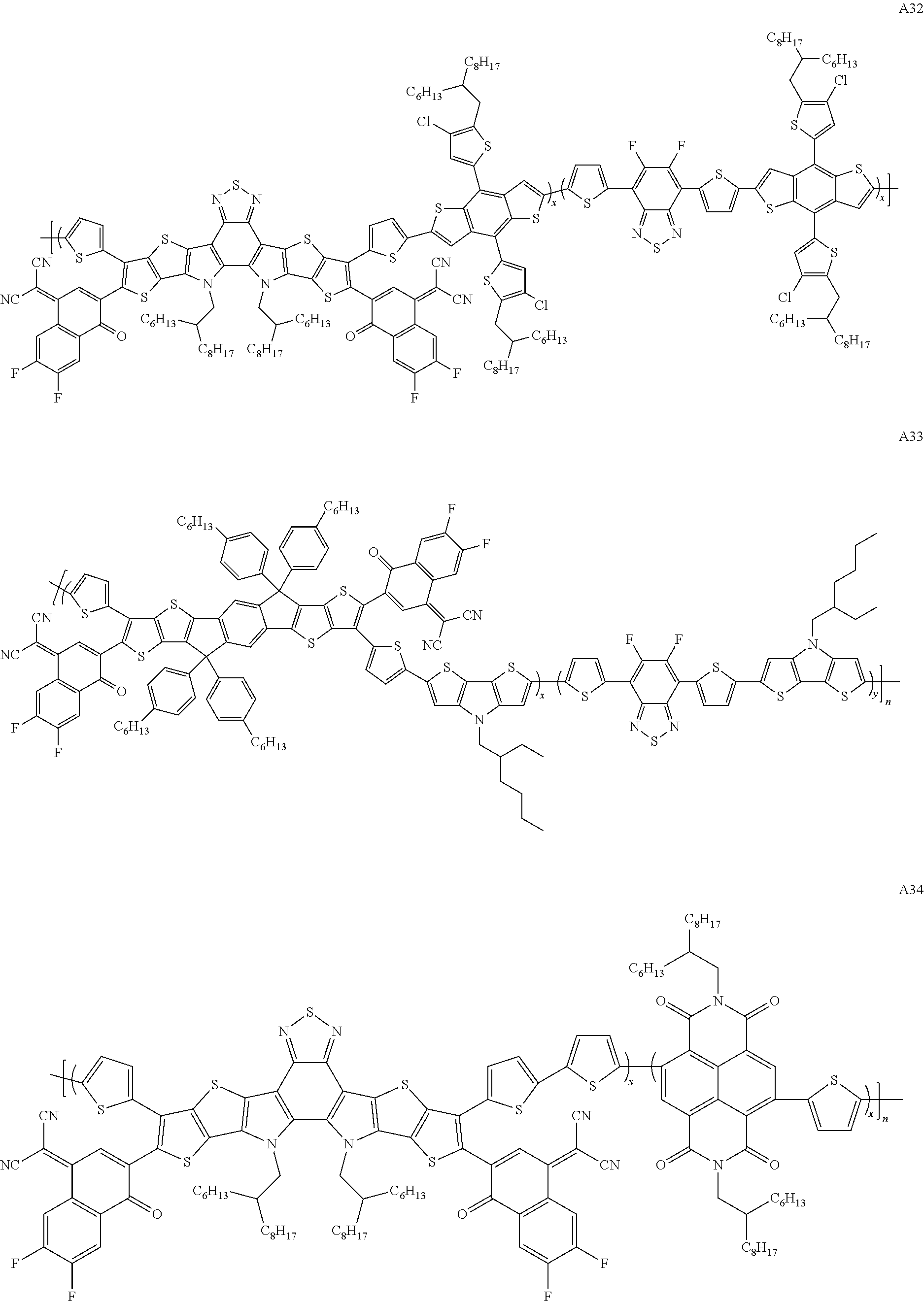

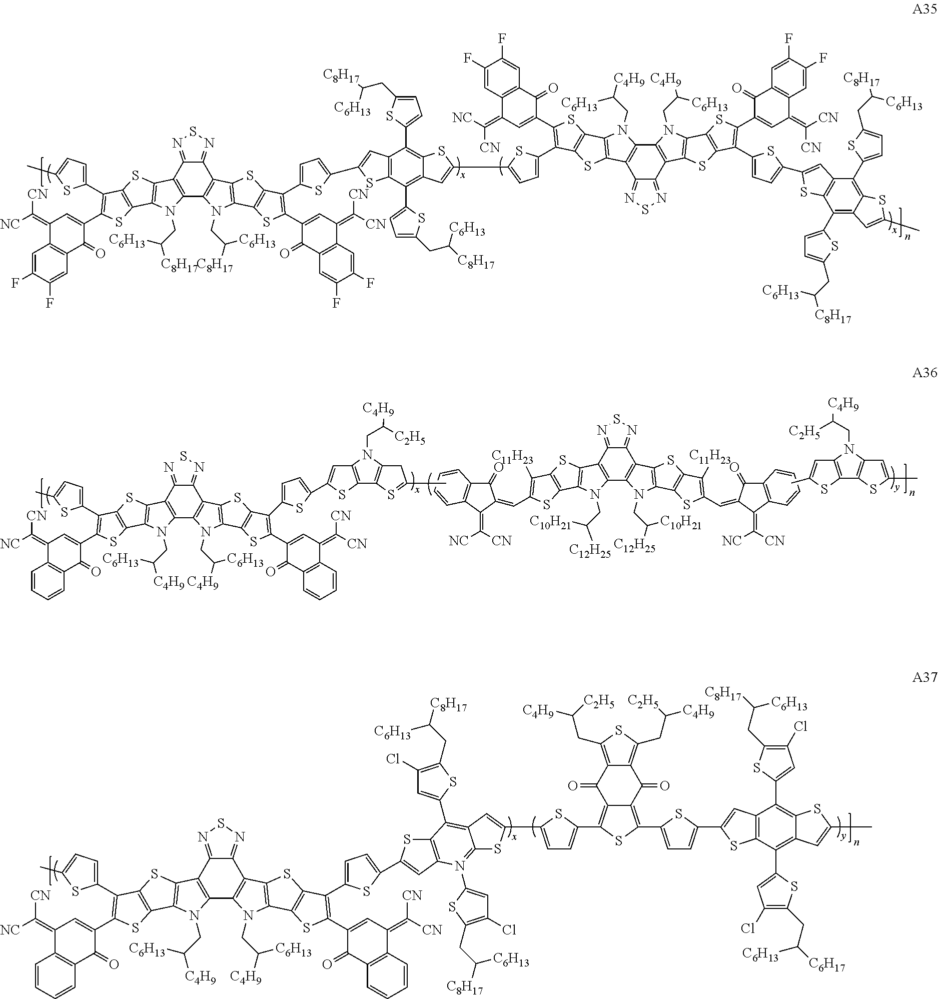

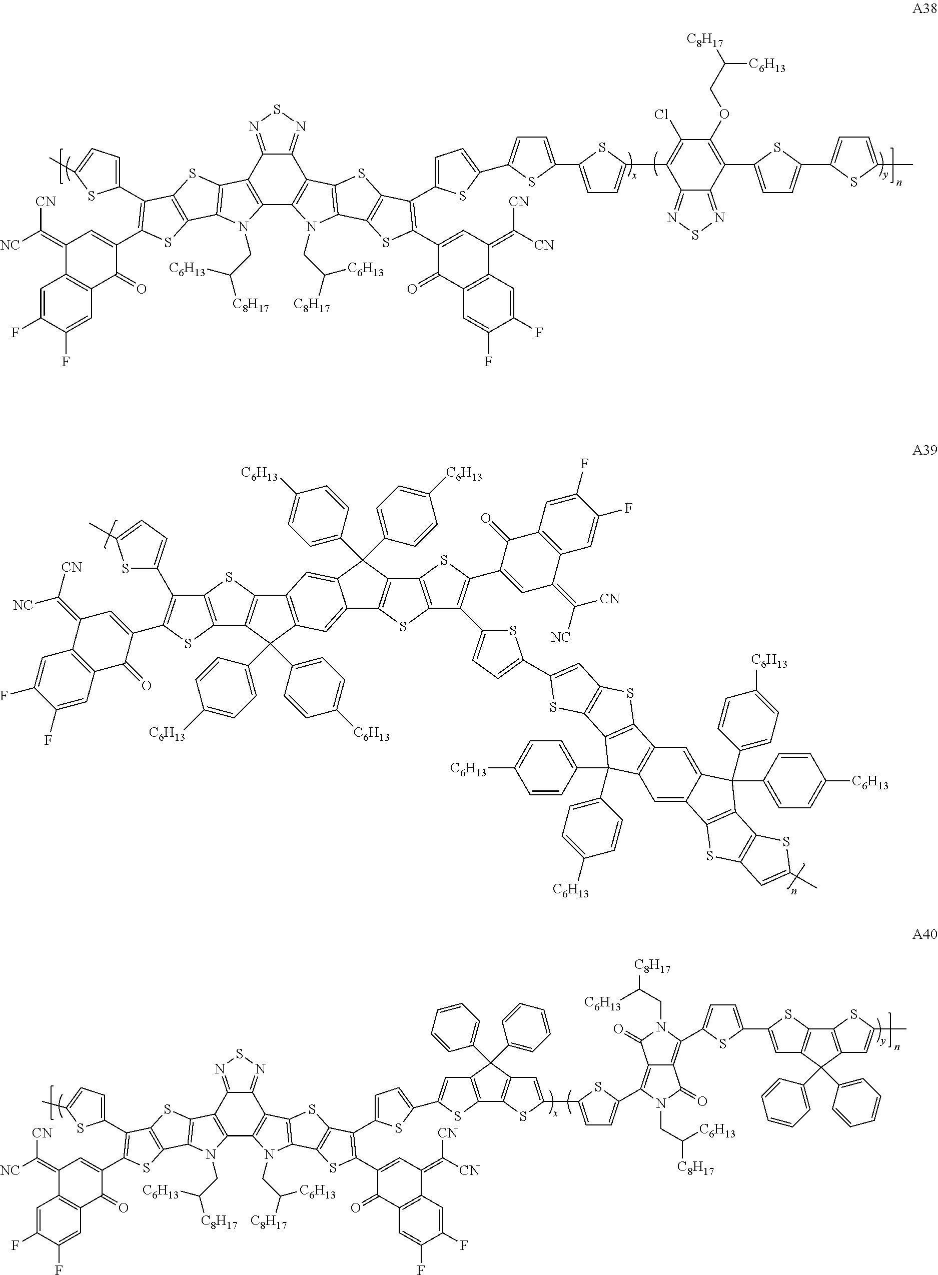

It should be understood that the above-listed embodiments are only intended to allow the person skilled in the art to understand the structure and composition of the present invention more clearly, and are not limited thereto.

As demonstrated in the above-described embodiments, the present invention utilizes the modifiable nature of the 3-position of a sulfur-containing five-membered heterocycle (i.e., thiophene) as a reactive site for polymerization. Two exemplary reaction schemes are shown below:

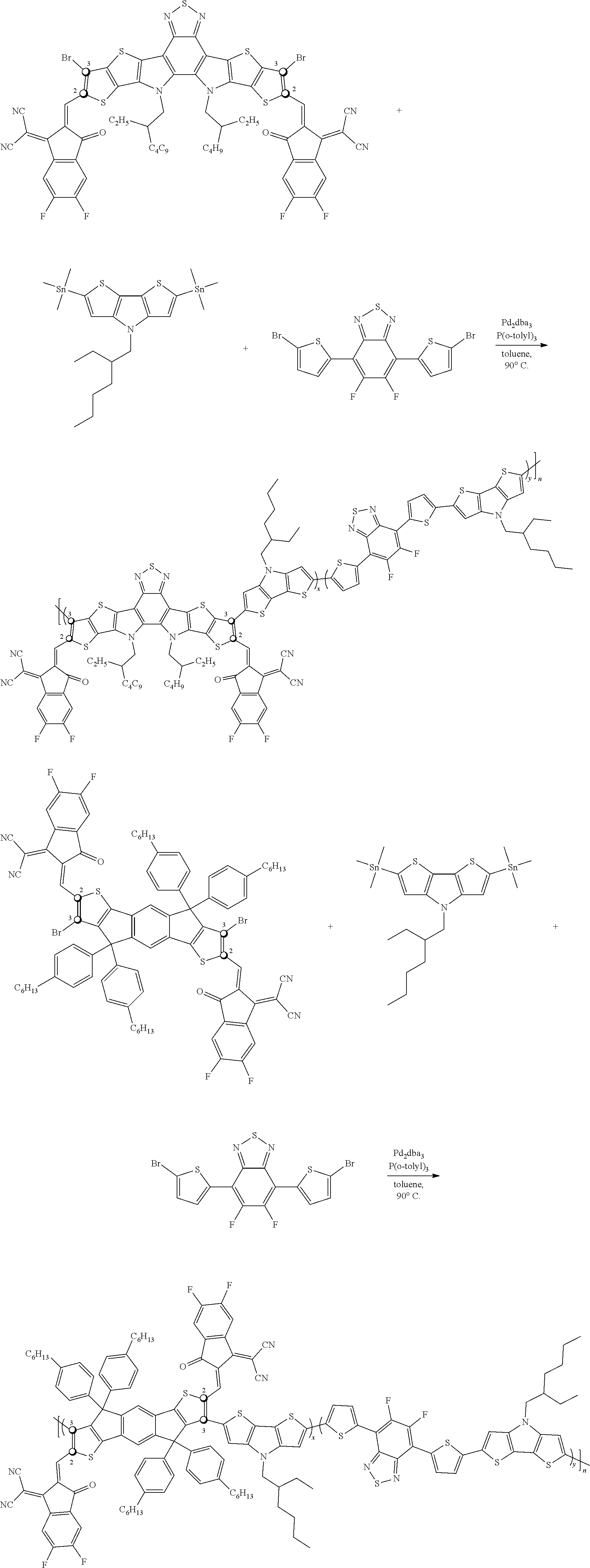

This synthetic design does not require the retention of bromine or iodine groups on the terminal electron-withdrawing group of the NFA for polymerization, thereby resulting in a symmetric molecular structure of the NFA without the formation of isomers. As a result, there is no need to address issues related to molecular asymmetry or to separate specific isomers, which simplifies the synthesis process, reduces cost, improves synthetic yield, and offers advantages in large-scale production and commercial viability. In addition, the present invention also enables the preparation of organic random polymers with customized specifications by utilizing the tunable energy levels and solubility characteristics of the organic random polymer.

In one embodiment, the present invention provides an organic composition comprising the organic random polymer as previously and at least one of a P-type organic semiconductor material and an N-type organic semiconductor material. The P-type organic semiconductor material comprises at least one organic conjugated polymer or one organic conjugated small molecule. The energy band gap of the N-type organic semiconductor material is from 0.5 to 2.0 eV. In practice, the energy band gap of the P-type organic semiconductor material is from 0.6 to 2.0 eV.

Wherein, the P-type organic semiconductor material is further selected from at least one organic conjugated polymer. The conjugated polymer is composed of a plurality of monomers, and the monomers include one selected from the following structures and combinations thereof:

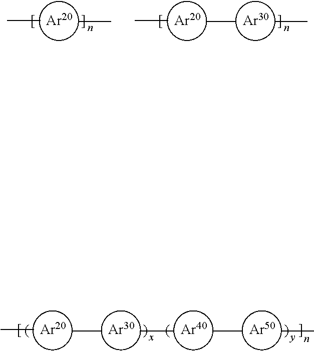

Wherein, Ar20, Ar30, Ar40 and Ar50 are monocyclic or polycyclic structures containing C4-C30 ring atoms respectively. n is the number of repeating units and is an integer selected from 1 to 1000. x and y are molar fractions, wherein 0<x<1, 0<y<1 and x+y=1. In a preferred embodiment, at least one of the ring atoms included in Ar20, Ar30, Ar40 and Ar50 is a heteroatom, wherein the heteroatom is independently selected from at least one of S, O, Se, N, F, Cl and Si.

Wherein, Ar20 and Ar40 are each independently selected from the group consisting of the following structures:

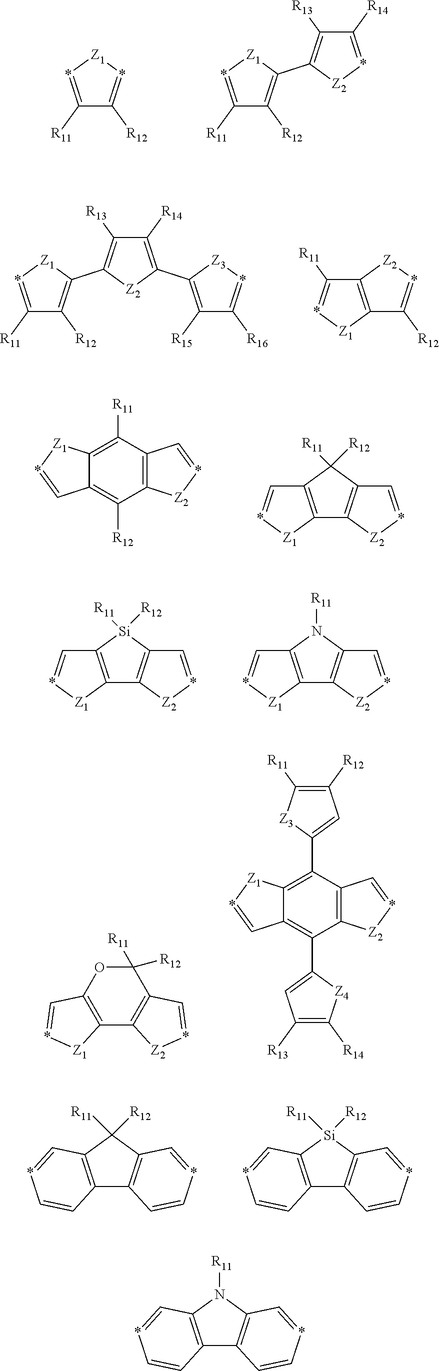

Wherein, each structure is connected by *. Z₁, Z₂, Z₃ and Z₄ are independently selected from O, S and Se. R₁₁, R₁₂, R₁₃, R₁₄, R₁₅ and R₁₆ are each independently selected from the following group consisting of hydrogen, halogen, cyano group, C1-C30 alkyl with or without substituents, C1-C30 alkoxy with or without substituents, C1-C30 alkylthio with or without substituents, C1-C30 haloalkyl with or without substituents, C2-C30 ester with or without substituents, C1-C30 alkylaryl with or without substituents, C1-C30 alkyl heteroaryl with or without substituents, C1-C30 silyl aryl with or without substituents, C1-C30 silyl heteroaryl with or without substituents, C1-C30 alkoxyaryl with or without substituents, C1-C30 alkyloxy heteroaryl with or without substituents, C1-C30 alkylthioaryl with or without substituents, C1-C30 alkylthio heteroaryl with or without substituents, C1-C30 haloalkyl aryl with or without substituents, C1-C30 haloalkyl heteroaryl with or without substituents, C2-C30 esteryl aryl with or without substituents and C2-C30 esteryl heteroaryl with or without substituents.

Wherein, Ar30 and Ar50 are each independently selected from the group consisting of the following structures:

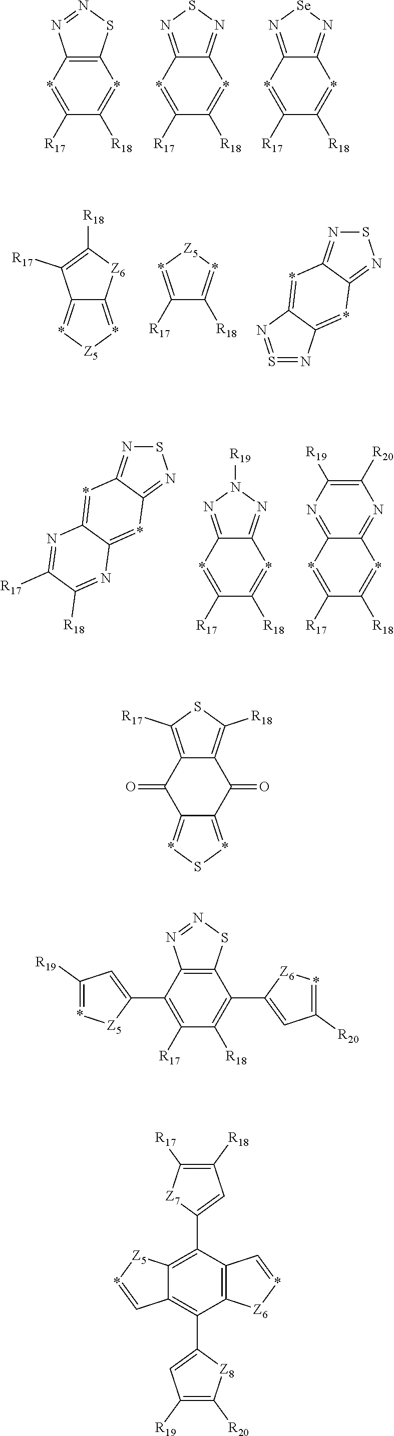

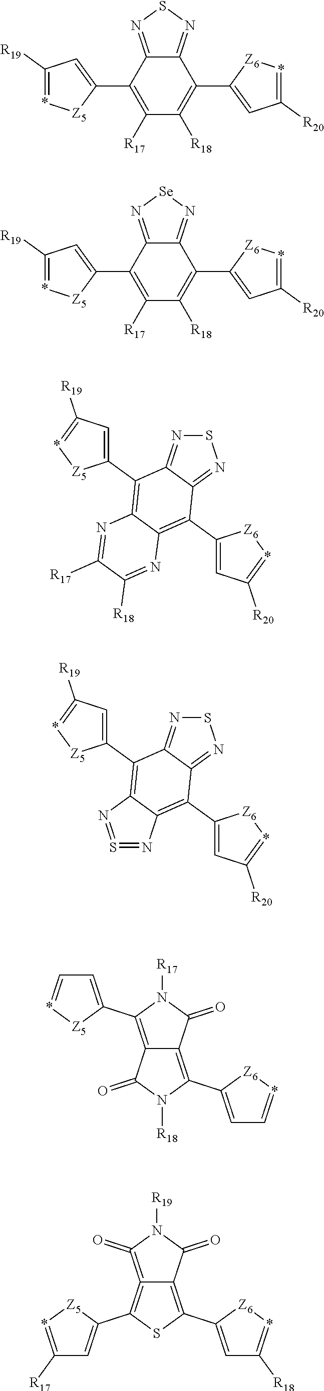

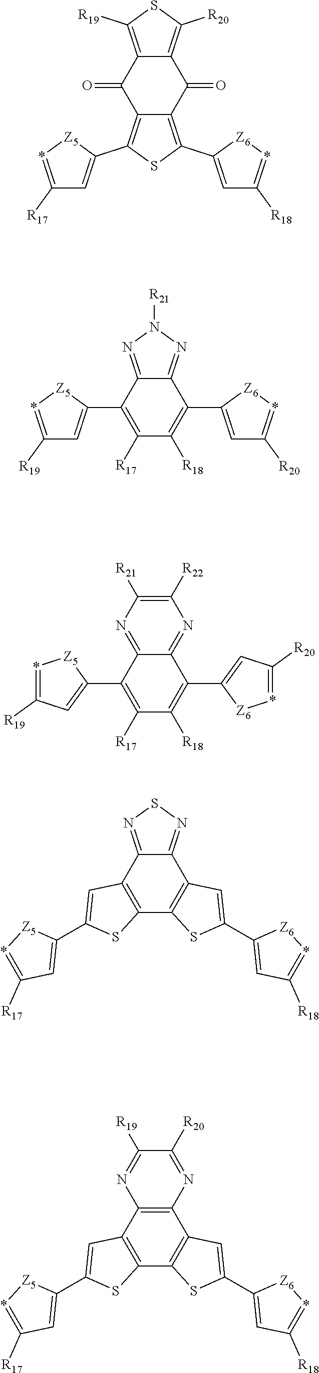

Wherein, each structure is connected by *. Z₅, Z₆, Z₇ and Z₈ are each independently selected from the group consisting of O, S and Se. R₁₇, R₁₈, R₁₉, R₂₀, R₂₁ and R₂₂ are each independently selected from the group consisting of hydrogen, halogen, cyano group, C1-C30 alkyl with or without substituents, C1-C30 alkoxy with or without substituents, C1-C30 alkylthio with or without substituents, C1-C30 haloalkyl with or without substituents, C2-C30 ester with or without substituents, C1-C30 alkylaryl with or without substituents, C1-C30 alkyl heteroaryl with or without substituents, C1-C30 silyl aryl with or without substituents, C1-C30 silyl heteroaryl with or without substituents, C1-C30 alkoxyaryl with or without substituents, C1-C30 alkyloxy heteroaryl with or without substituents, C1-C30 alkylthioaryl with or without substituents, C1-C30 alkylthio heteroaryl with or without substituents, C1-C30 haloalkyl aryl with or without substituents, C1-C30 haloalkyl heteroaryl with or without substituents, C2-C30 esteryl aryl with or without substituents and C2-C30 esteryl heteroaryl with or without substituents. Wherein, R₁₇, R₁₈, R₁₉, R₂₀, R₂₁ and R₂₂ are optionally covalently bonded to at least one of the others, or each is a separate group.

The substituents mentioned above can be independently selected from the following groups and their derivatives: C1-C30 alkyl, C3-C30 branched alkyl, C1-C30 silyl, C2-C30 ester, C1-C30 alkoxy, C1-C30 alkylthio, C1-C30 haloalkyl, C2-C30 olefin, C2-C30 alkyne, C2-C30 carbon chains containing cyano group, C1-C30 carbon chains containing nitro groups, C1-C30 carbon chains containing hydroxy groups, C3-C30 carbon chains containing keto groups, halogens, cyano groups, hydrogen, deuterium and tritium. The above-mentioned aryl group and heteroaryl group may have a monocyclic or polycyclic structure.

In practice, the conjugated polymer further comprises the following embodiments P-1˜P-37:

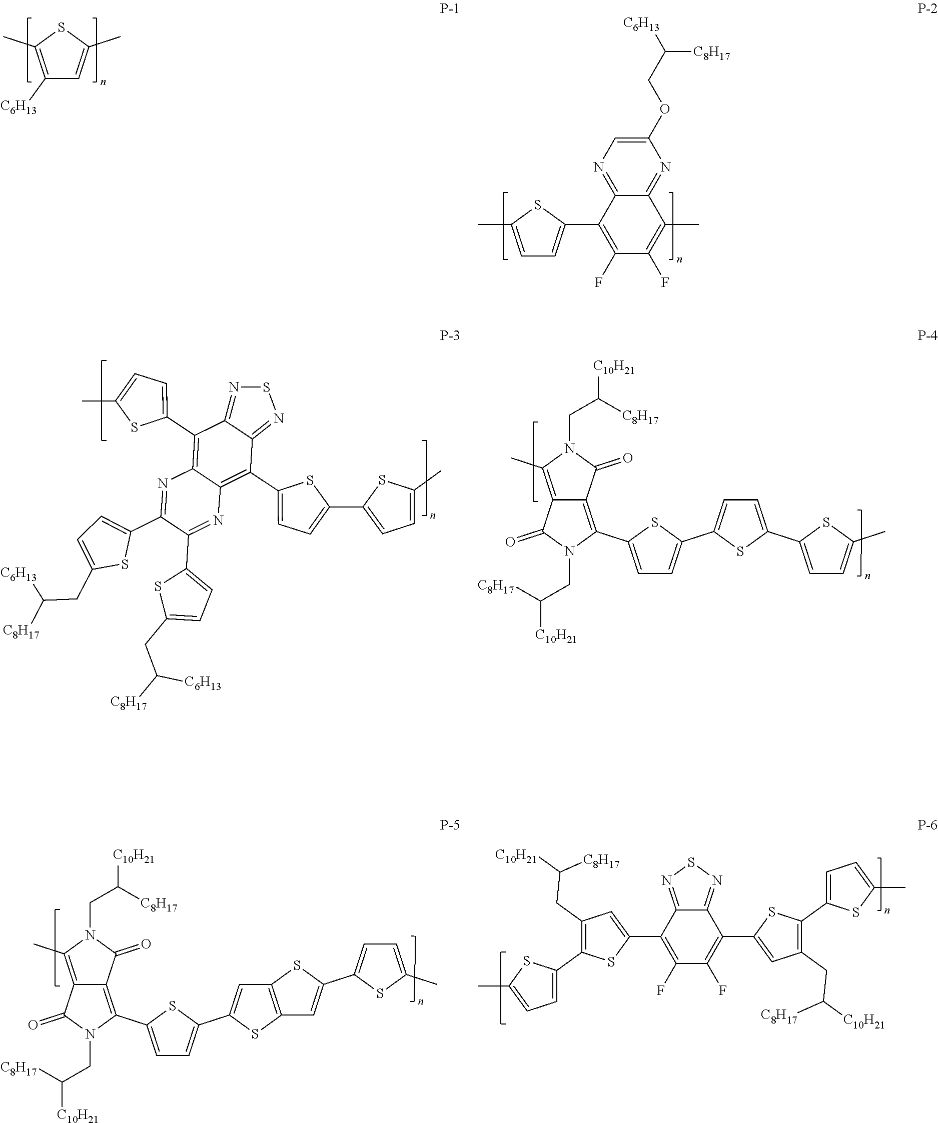

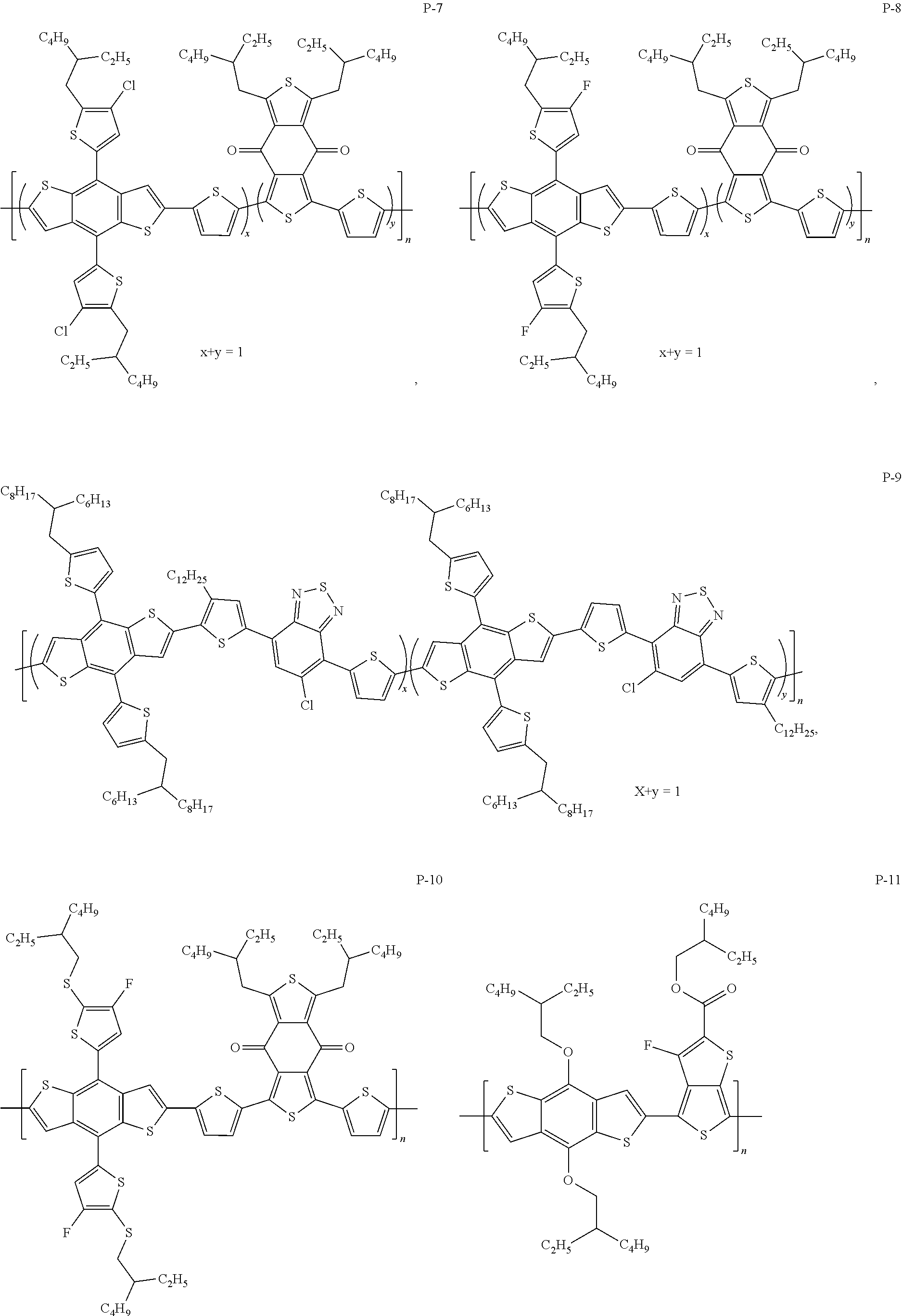

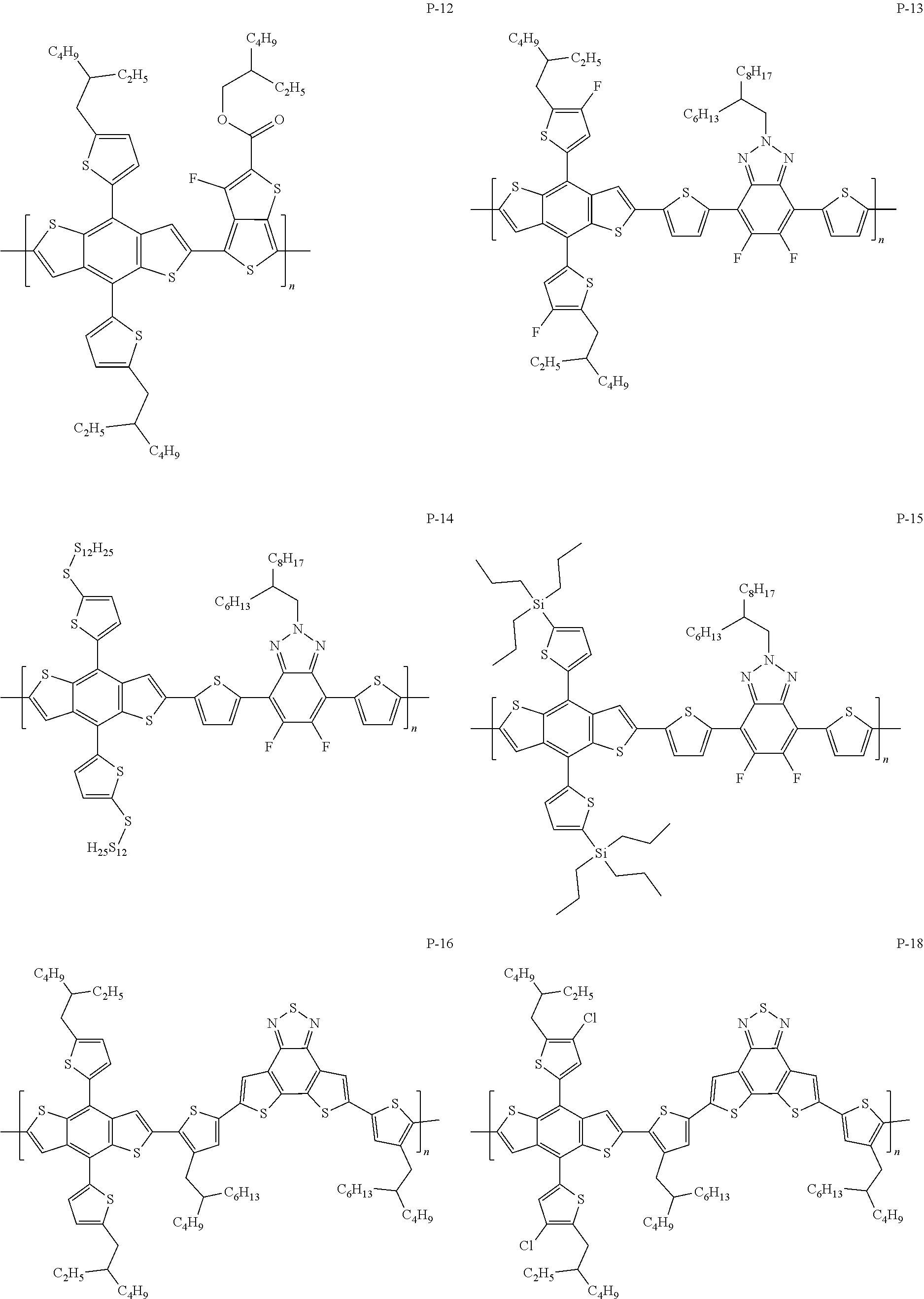

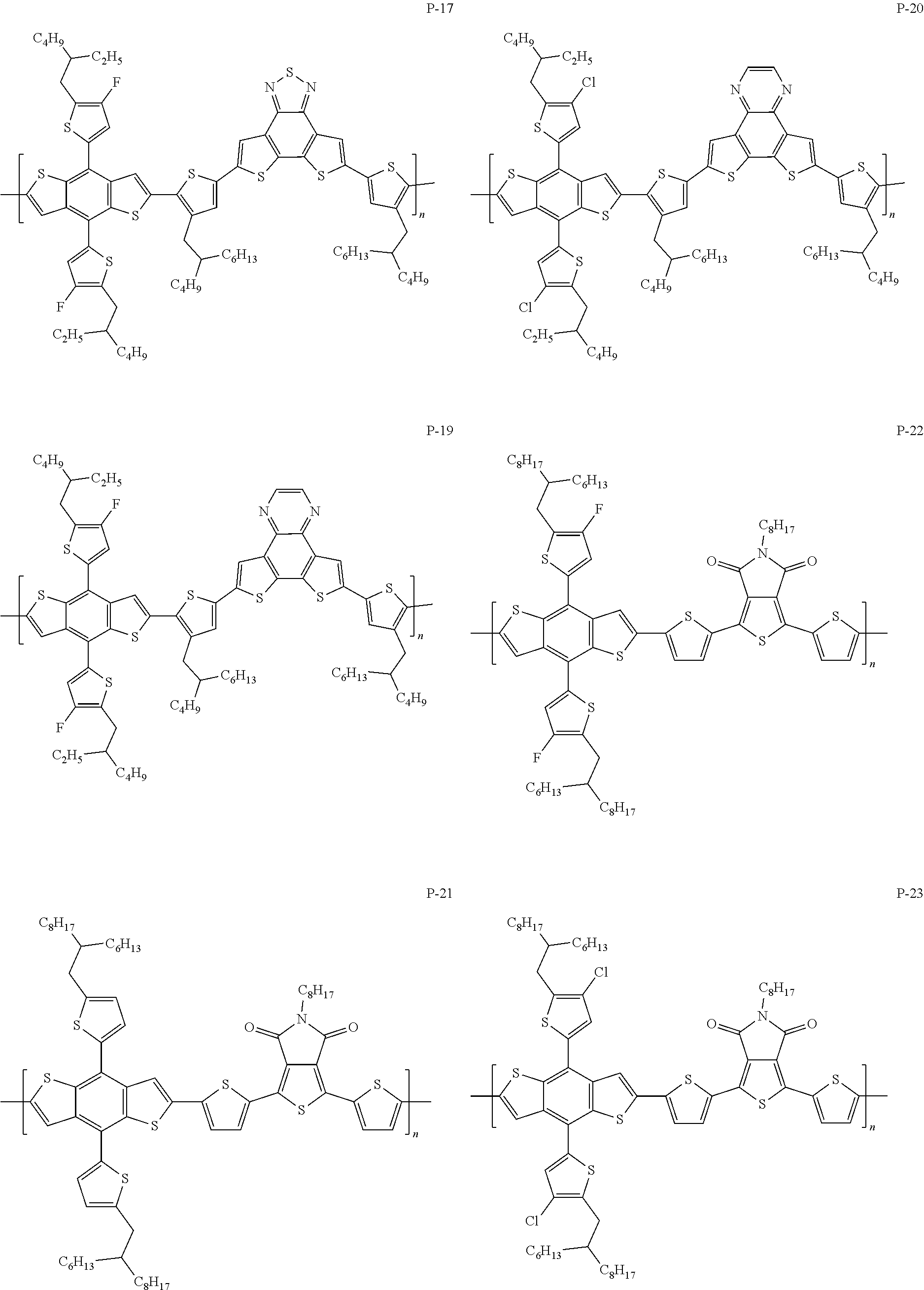

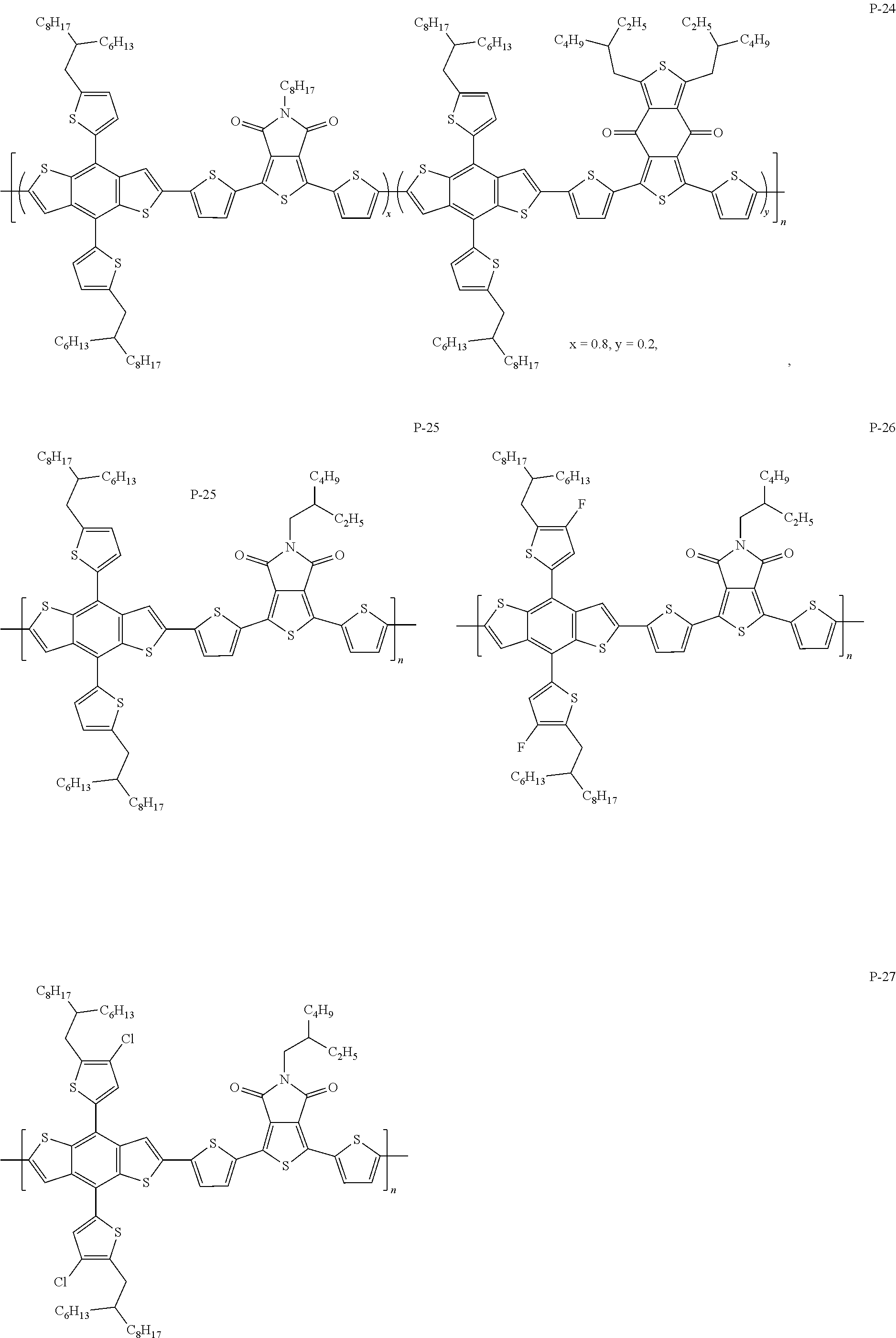

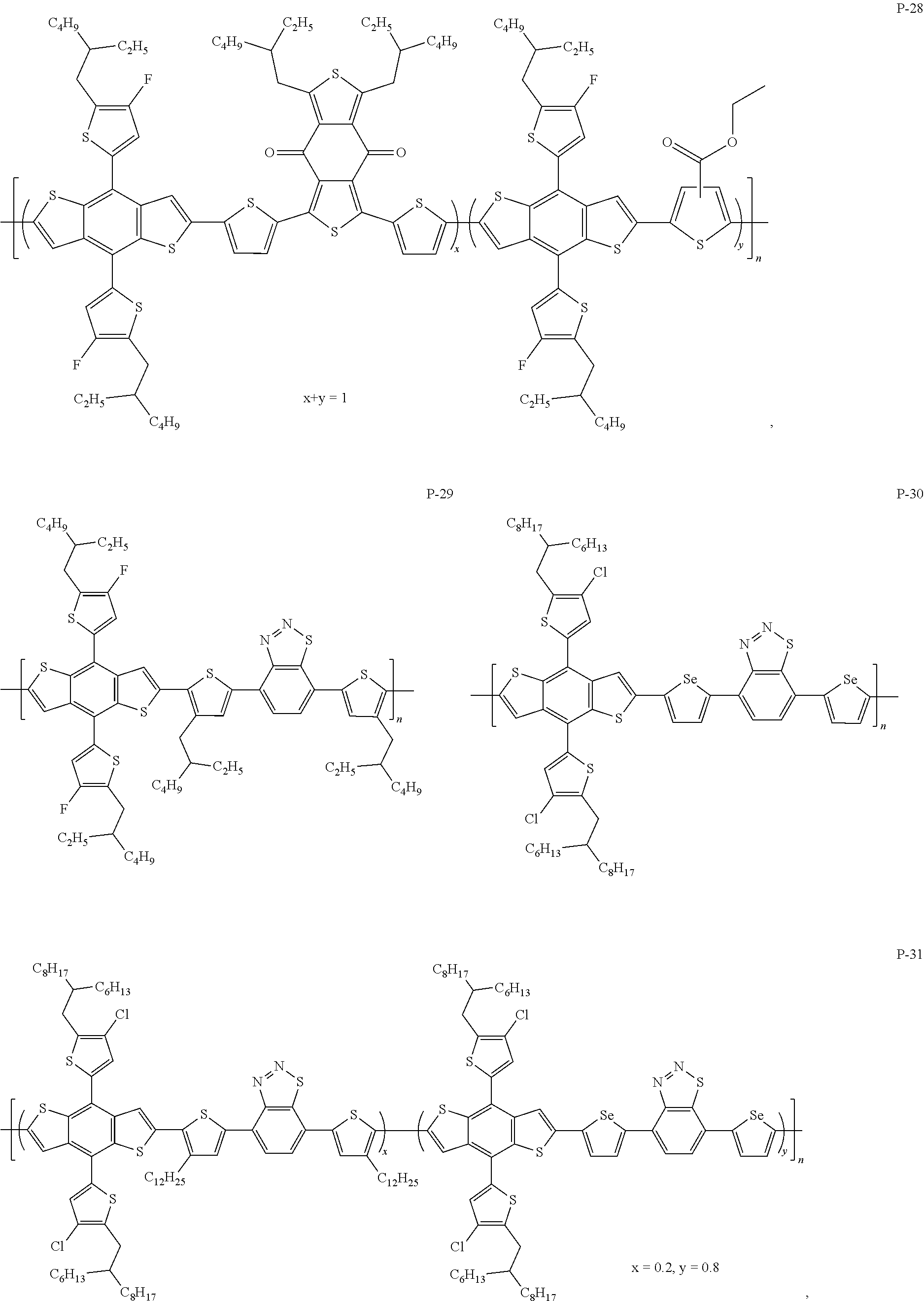

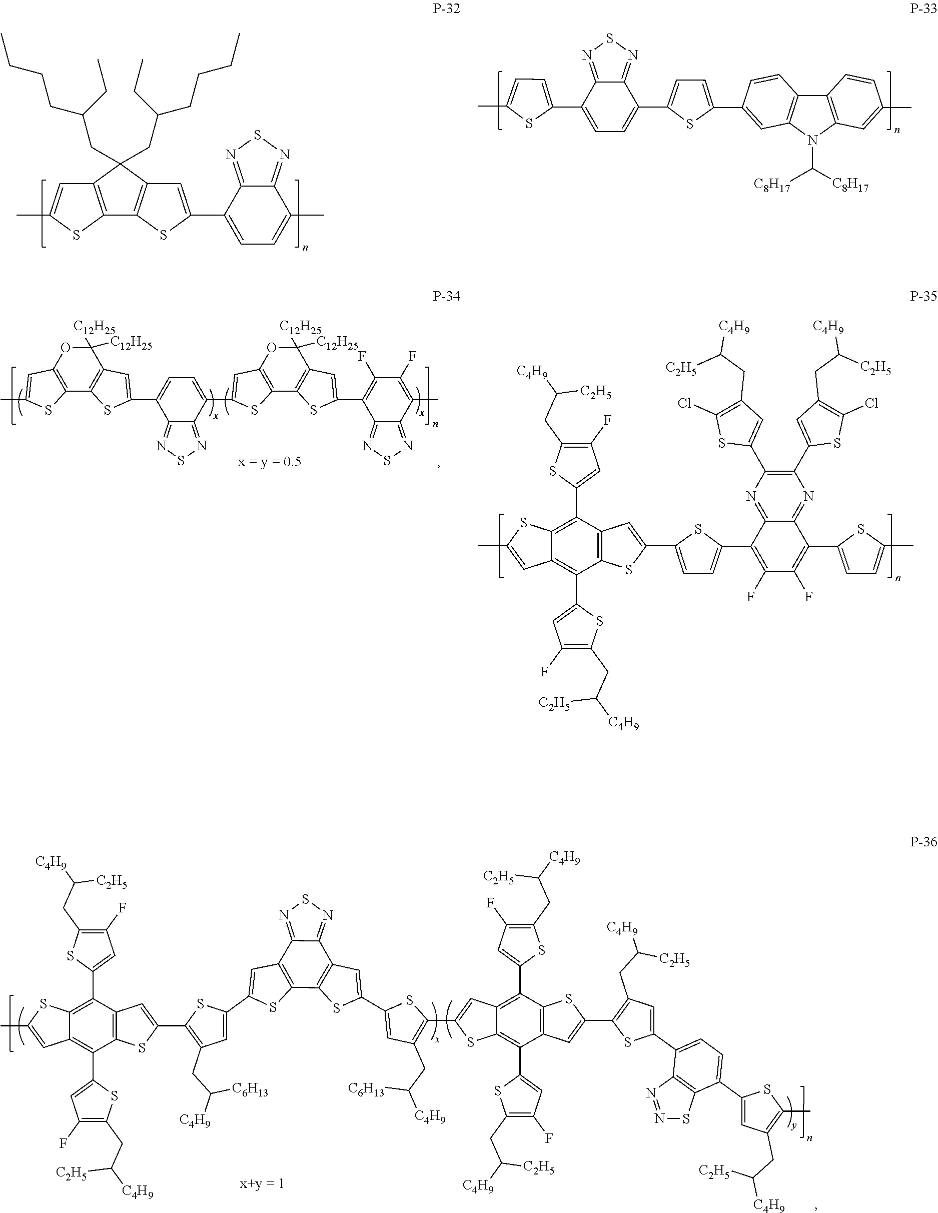

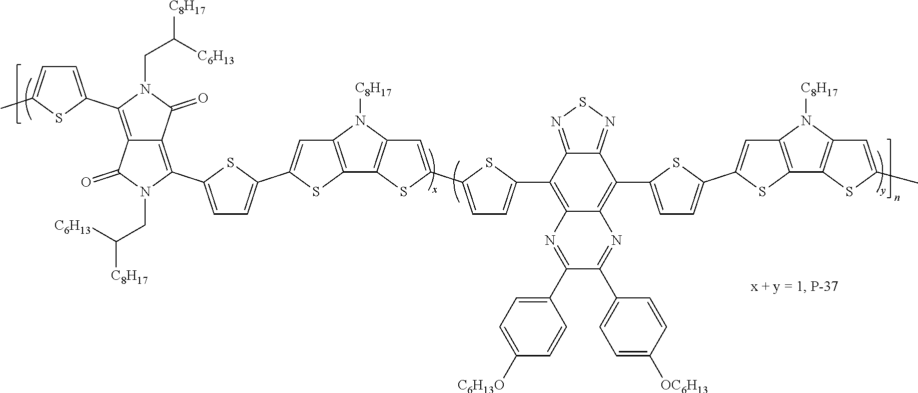

It should be understood that the above-listed embodiments are only intended to allow the person skilled in the art to understand the structure and composition of the present invention more clearly, and are not limited thereto.

Wherein, the N-type organic semiconductor material comprises the following embodiments N1˜N41:

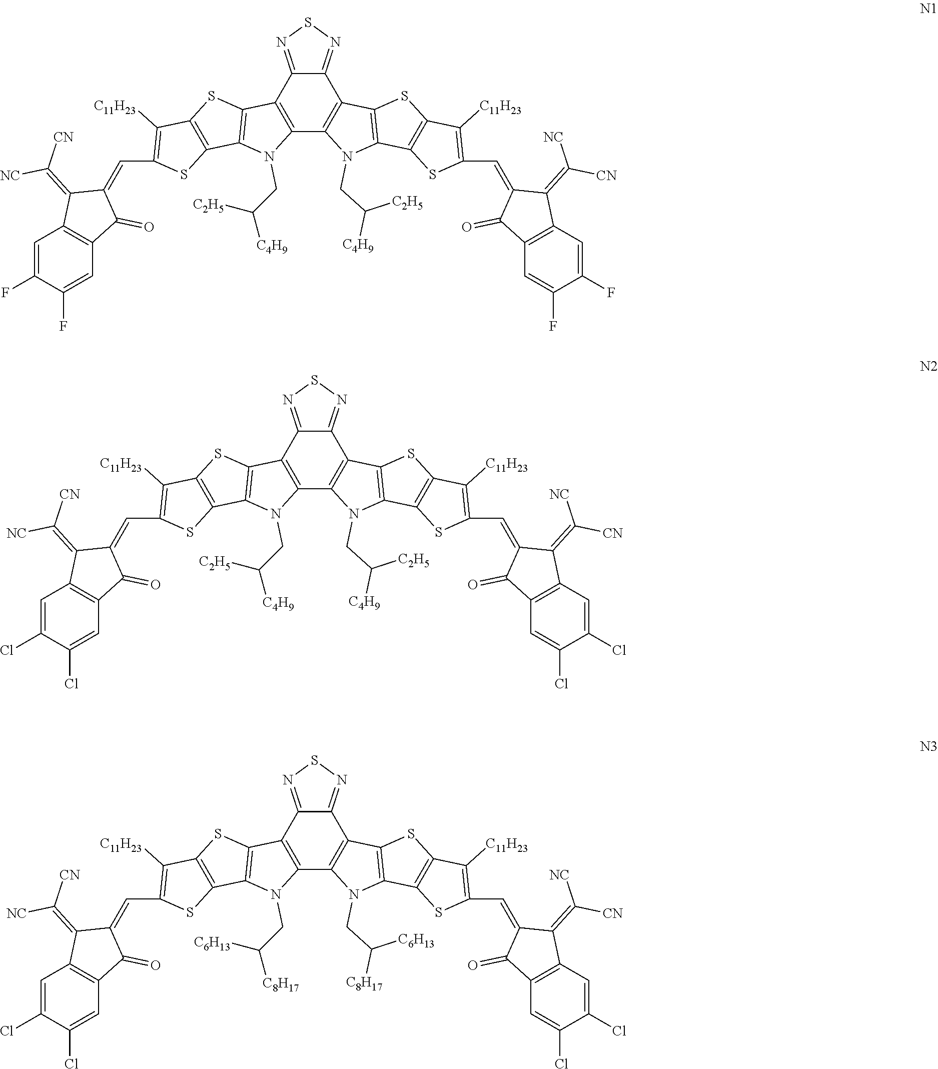

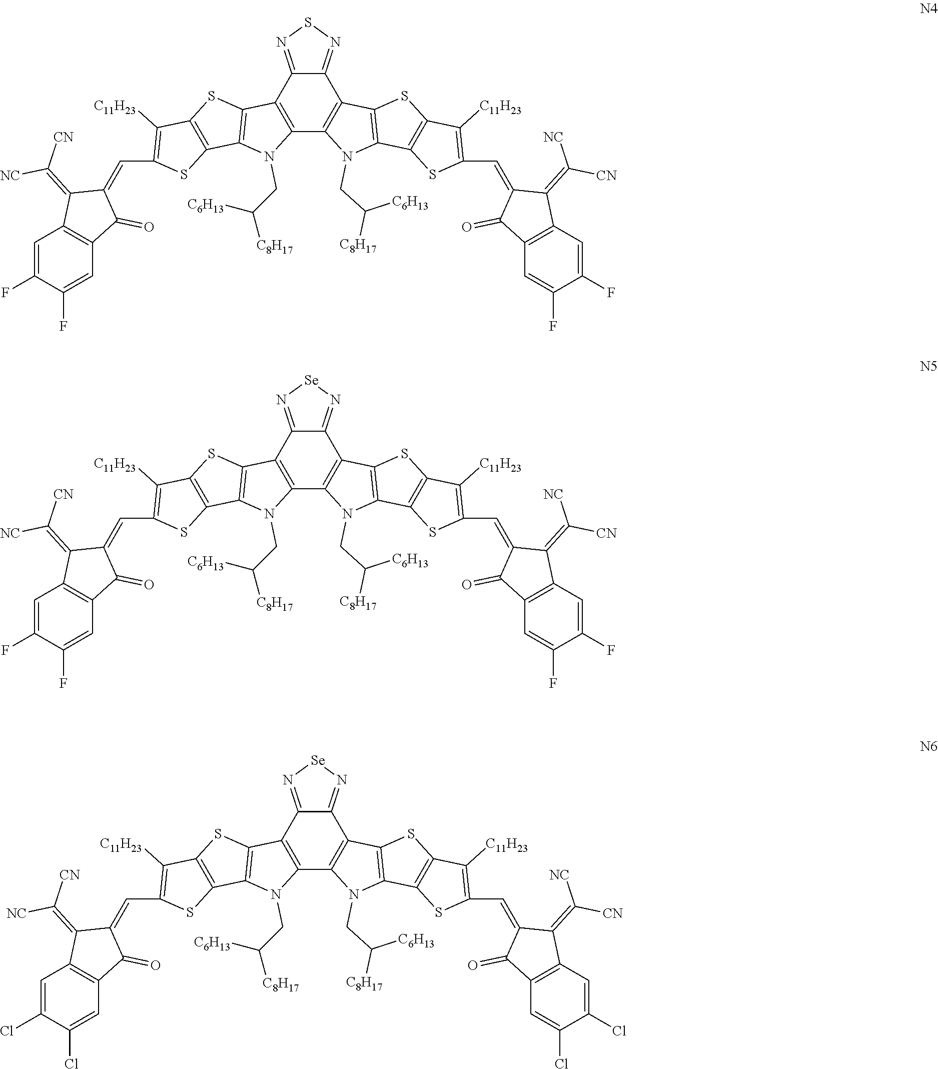

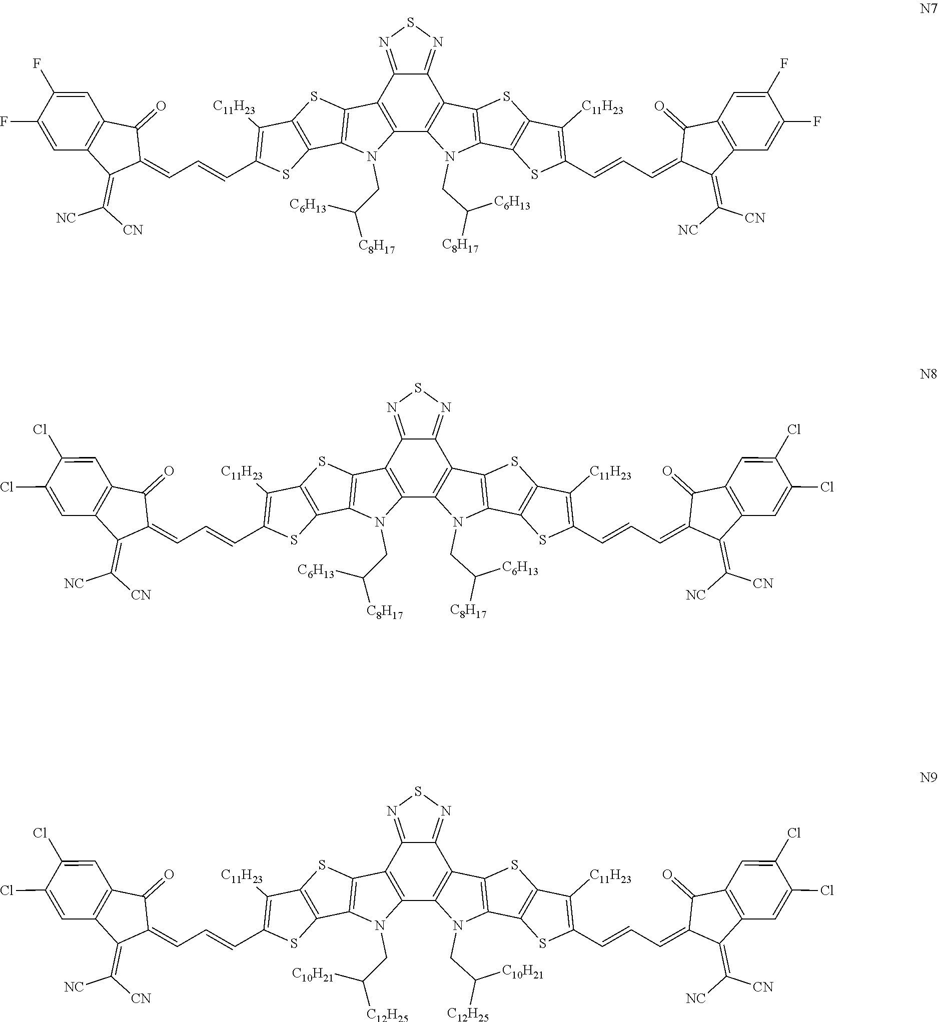

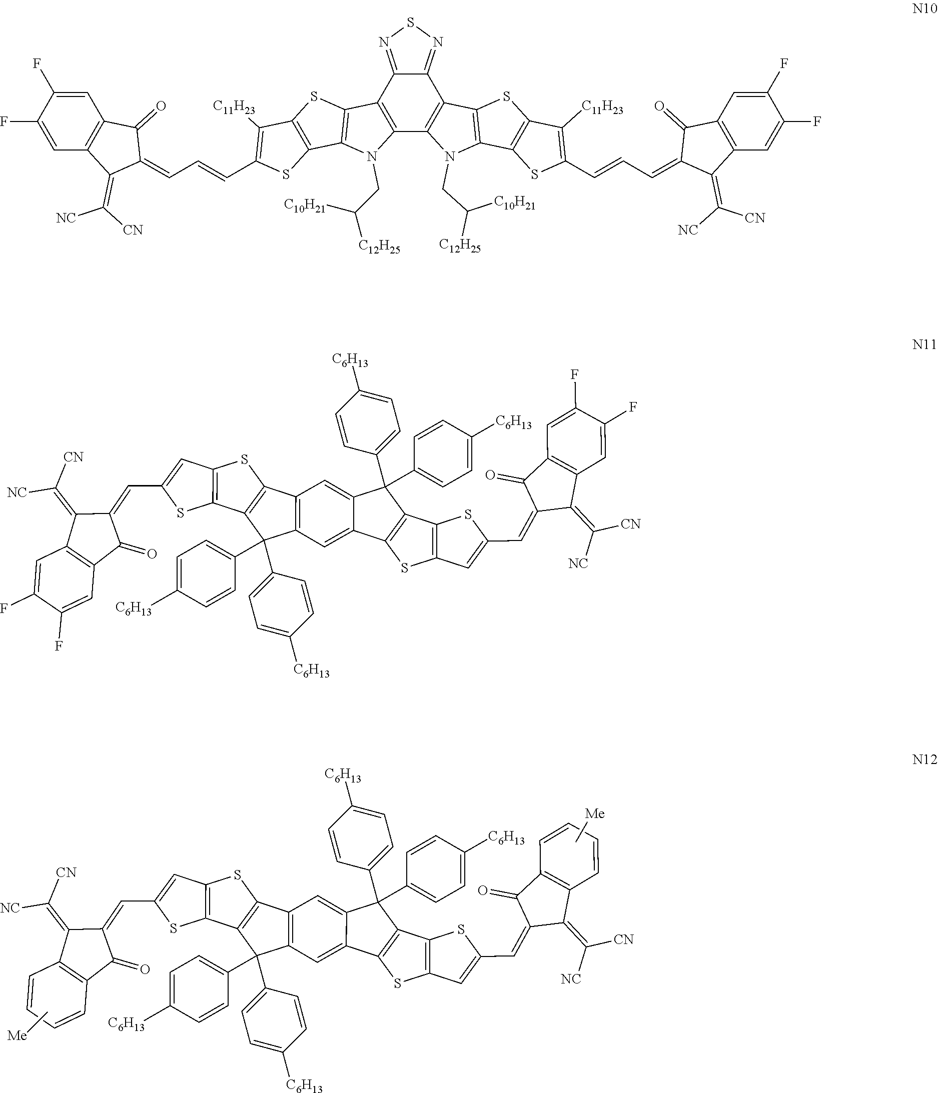

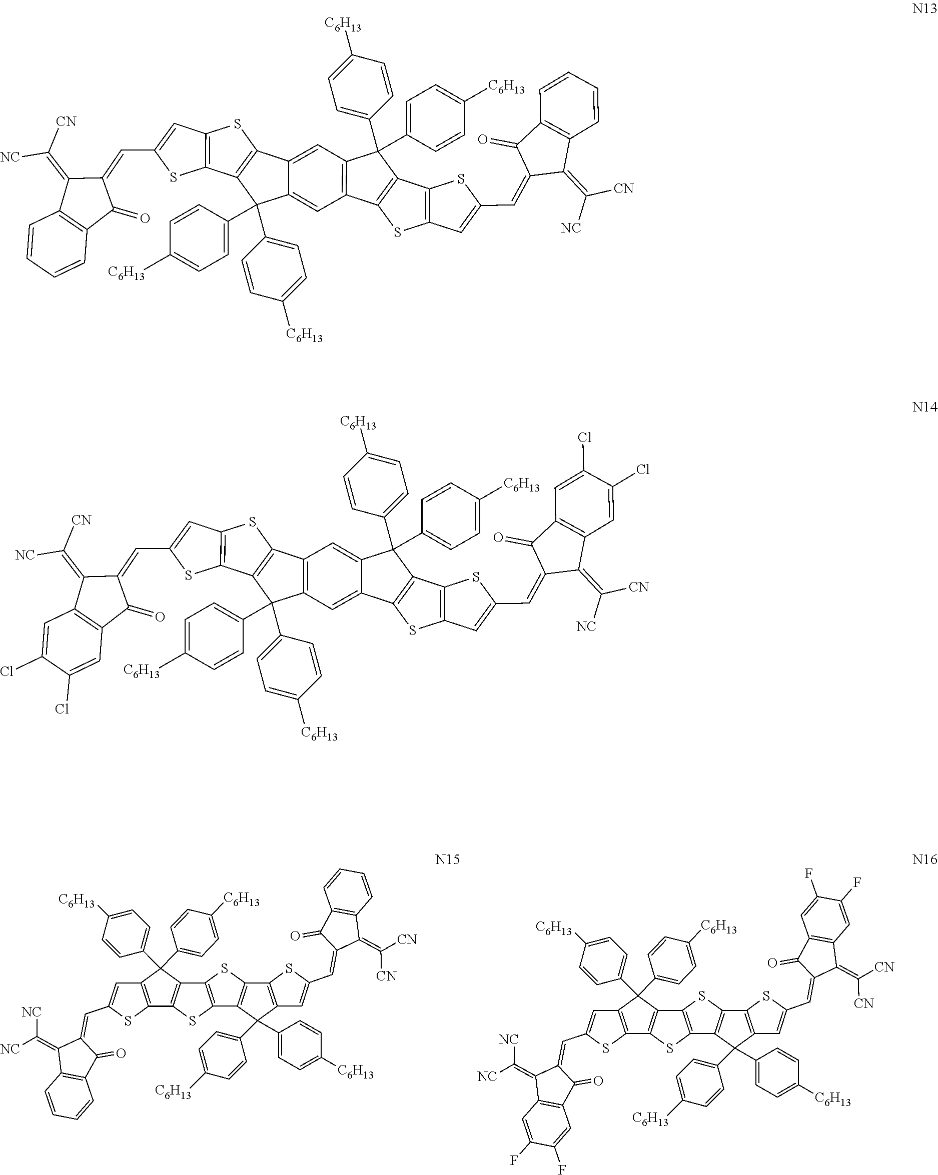

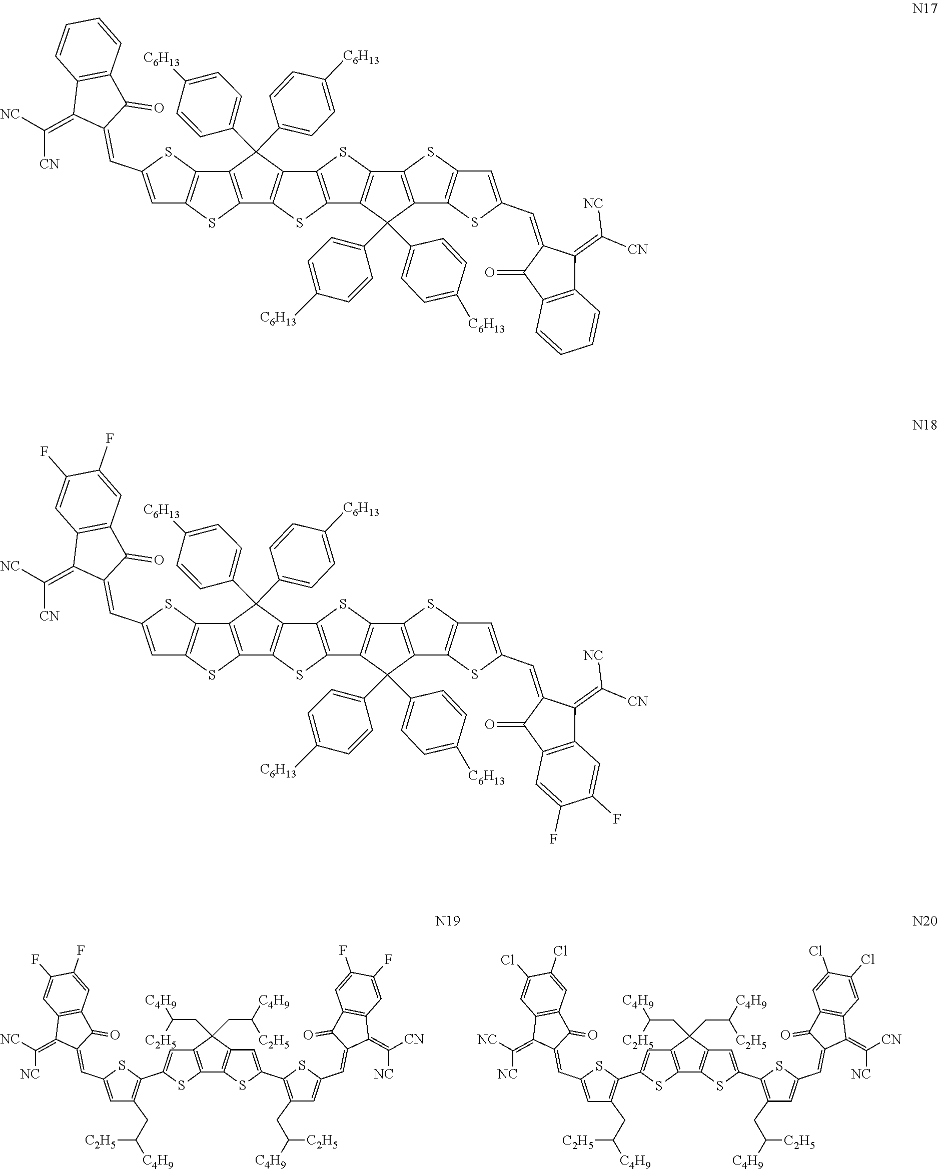

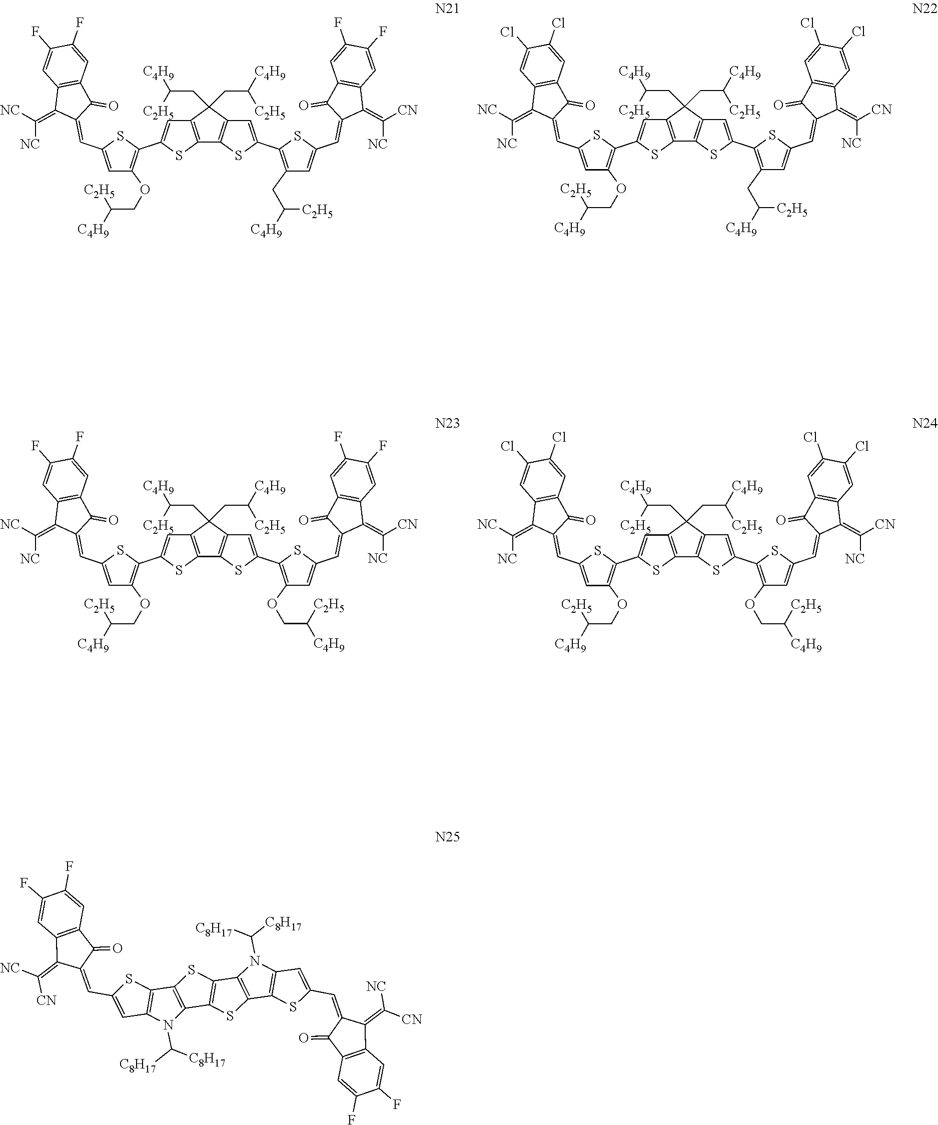

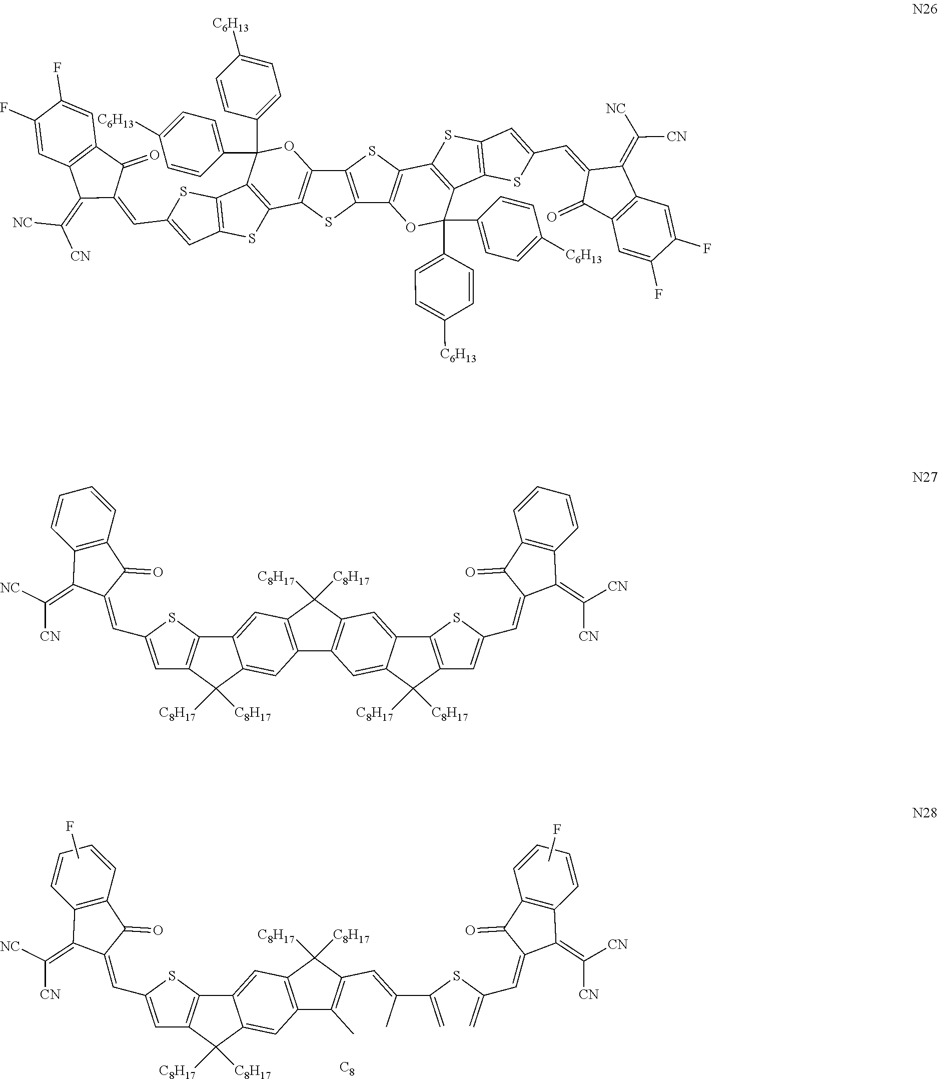

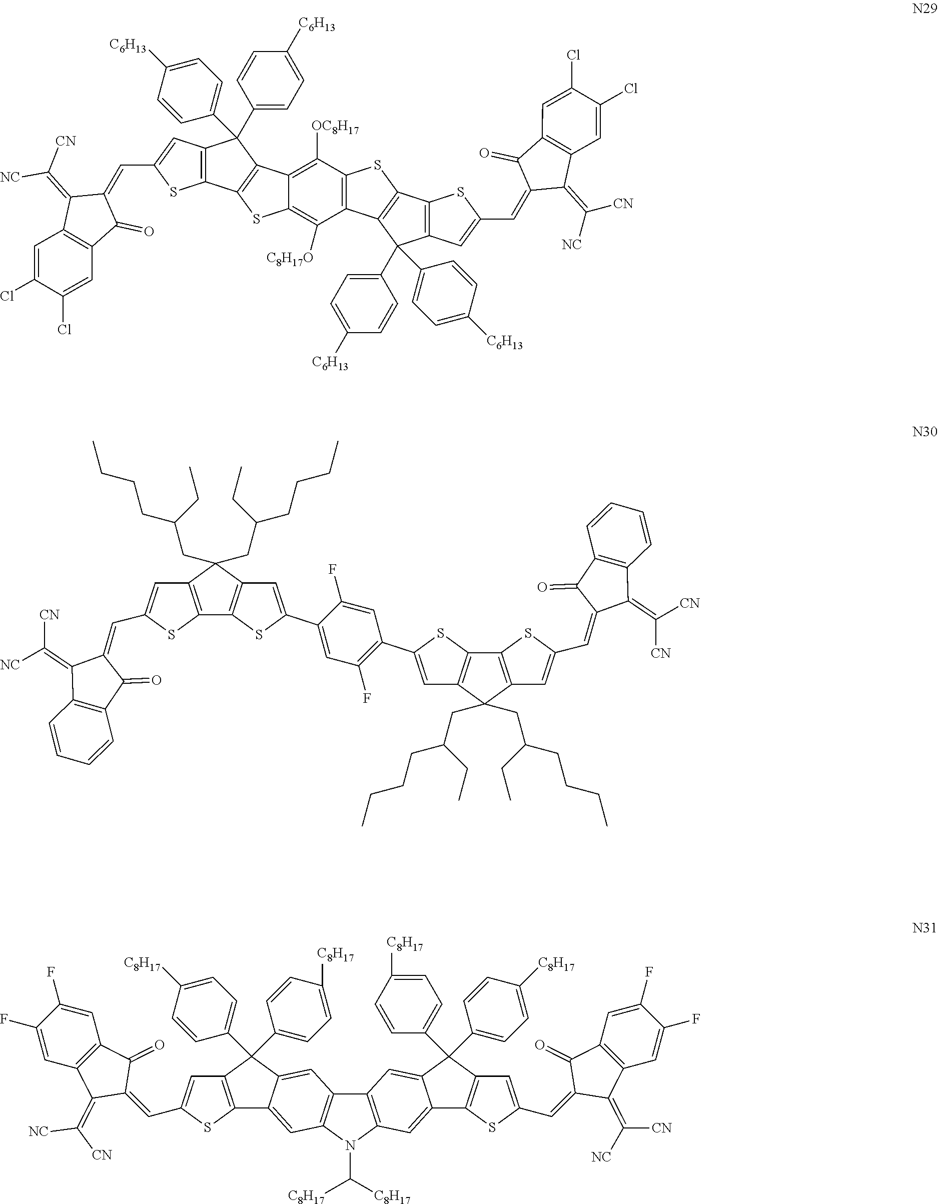

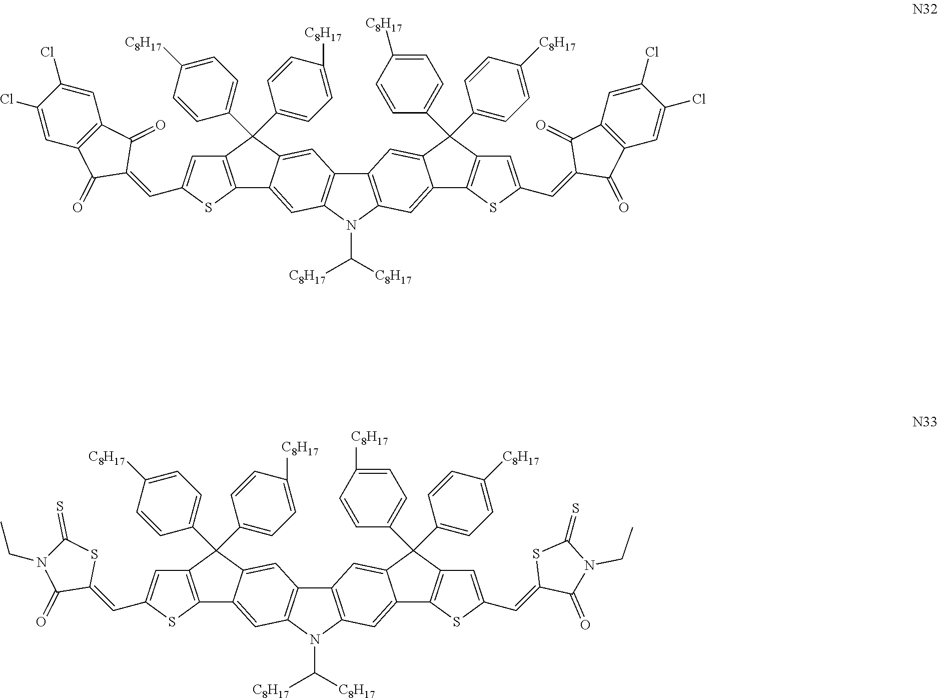

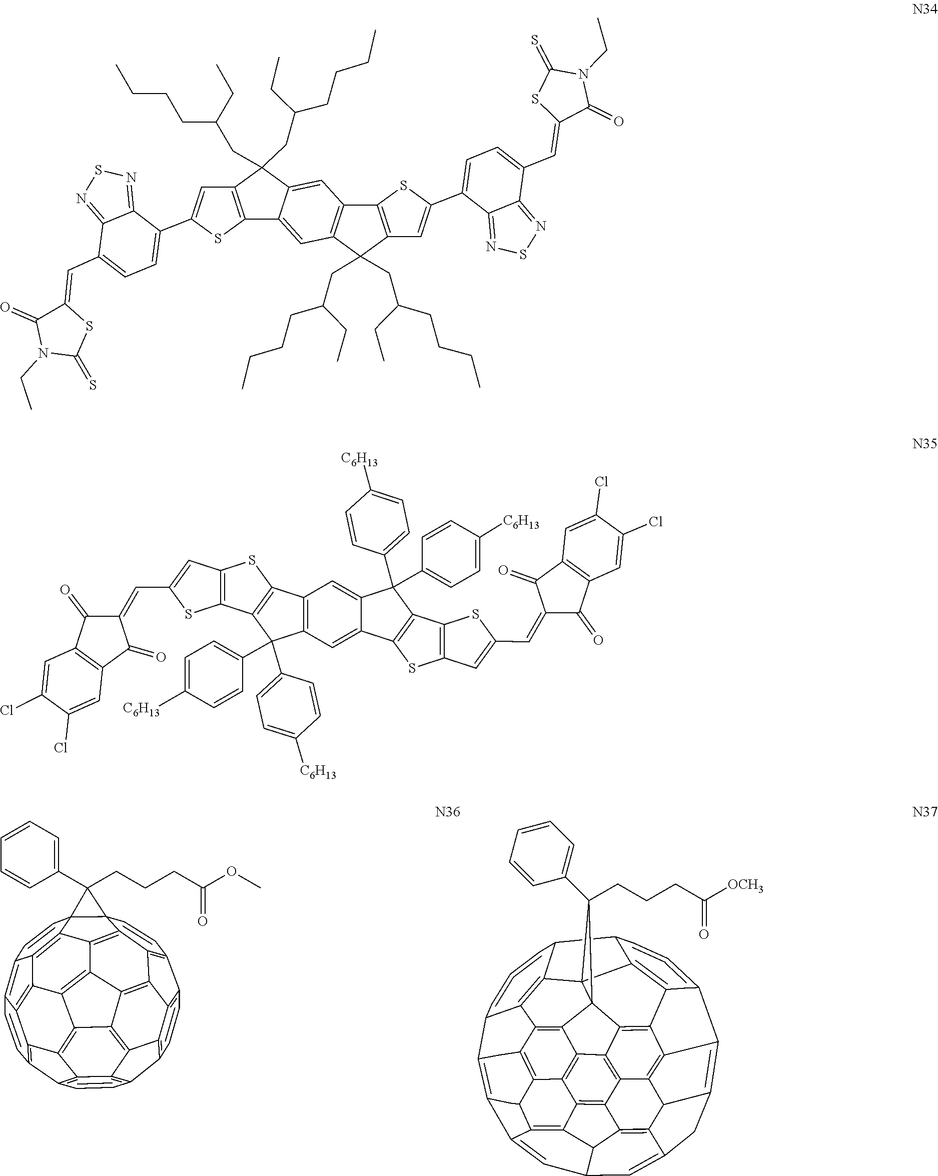

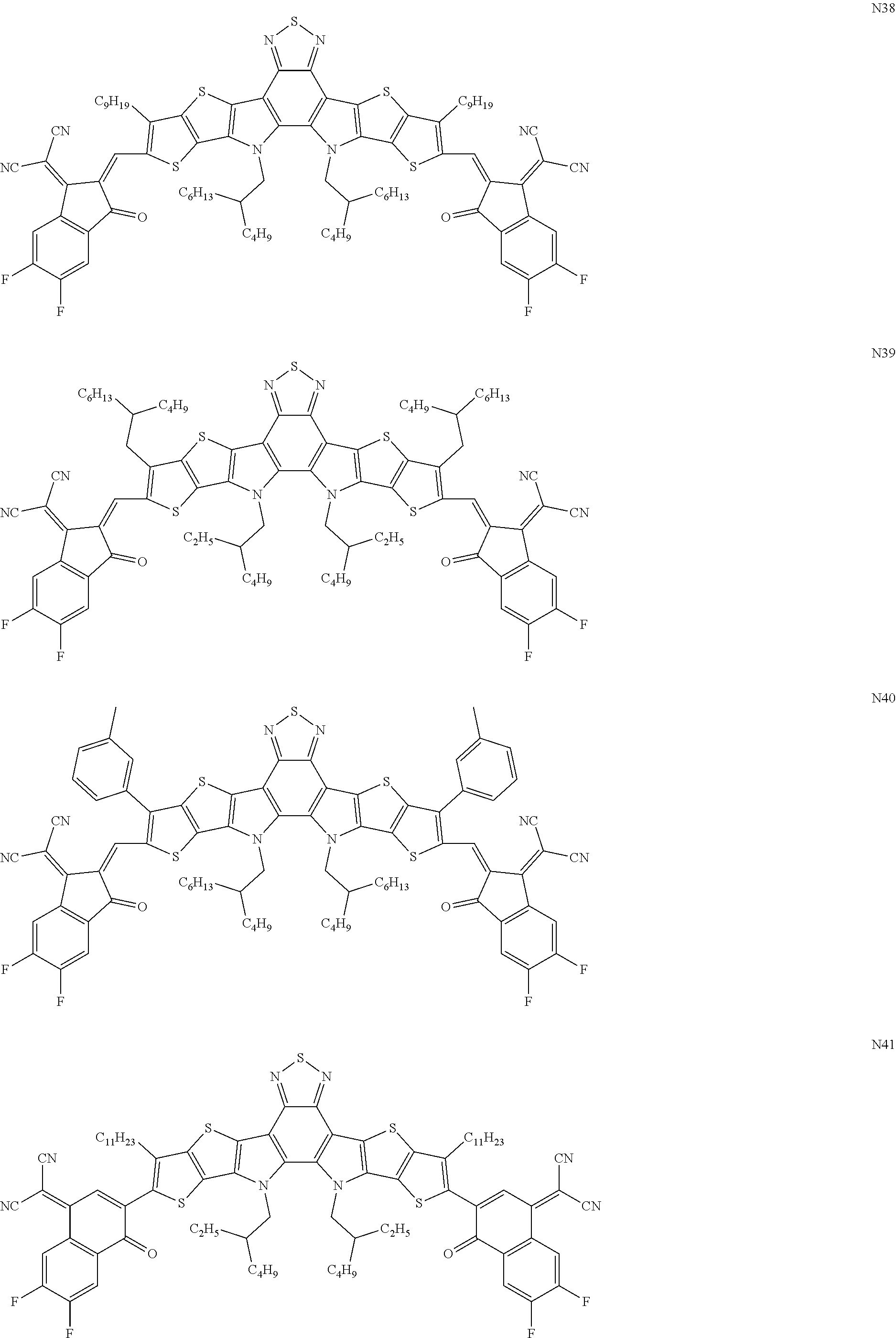

It should be understood that the above-listed embodiments are only intended to allow the person skilled in the art to understand the structure and composition of the present invention more clearly, and are not limited thereto.

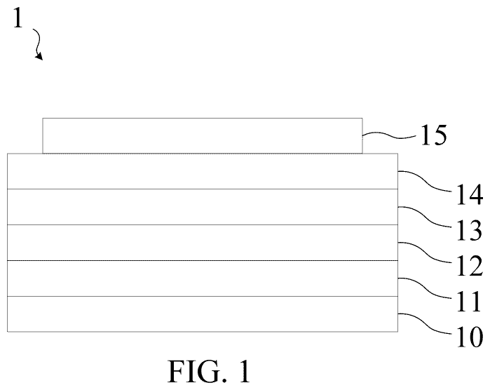

Please refer to FIG. 1. FIG. 1 shows a schematic structural diagram of one embodiment of an organic optoelectronic device of the present invention. As shown in FIG. 1, in another embodiment, the present invention further provides an organic optoelectronic device 1, which comprises a first electrode 11, a second electrode 15 and an active layer 13. The active layer 13, which comprises at least one of the organic random polymer previously and the organic composition previously comprising Formula I, is disposed between the first electrode 11 and the second electrode 15. The organic optoelectronic device 1 further comprises a first carrier transporting layer 12 and a second carrier transporting layer 14. The organic optoelectronic device 1 may have a stacked structure, which sequentially includes a substrate 10, the first electrode 11 (transparent or semi-transparent electrode), the first carrier transporting layer 12, the active layer 13, the second carrier transporting layer 14 and the second electrode 15. The first carrier transporting layer 12 is configured to transport carriers in the first electrode 11 and the active layer 13, and the second carrier transporting layer 14 is configured to transport carriers in the active layer 13 and the second electrode 15. Specifically, the first carrier transporting layer 12 is one of an electron transporting layer and a hole transporting layer, and the second carrier transporting layer 14 is the other one. In detail, when the first carrier transporting layer 12 is the electron transporting layer, the second carrier transporting layer 14 is the hole transporting layer, which is an inverted stacked structure; when the first carrier transporting layer 12 is the hole transporting layer, the second carrier transporting layer 14 is an electron transporting layer, which is a conventional stacked structure. In practice, the organic optoelectronic device 1 may comprise an organic photovoltaic device, an organic photodetector device, or an organic light emitting diode.

In order to illustrate the organic composition of the present invention more clearly, the following experiments will be conducted using Comparative Example 1 and organic random polymer Polymer 1˜Polymer 12 of the invention to illustrate the differences in efficacy. These materials will then be further utilized as an N-type organic semiconductor materials combined with a P-type organic semiconductor material (P-12 is used as an example herein for experimental description) to prepare the organic composition. The active layers comprising the organic random polymer or organic compositions previously described will be fabricated into organic optoelectronic devices for material testing and device performance evaluation.

For the optical physical quality testing part of material testing and device testing, the UV absorption spectrum measurement instrument model is Hitachi UH5700, and the oxidation potential is measured by using cyclic voltammetry with CH Instrument 611E.

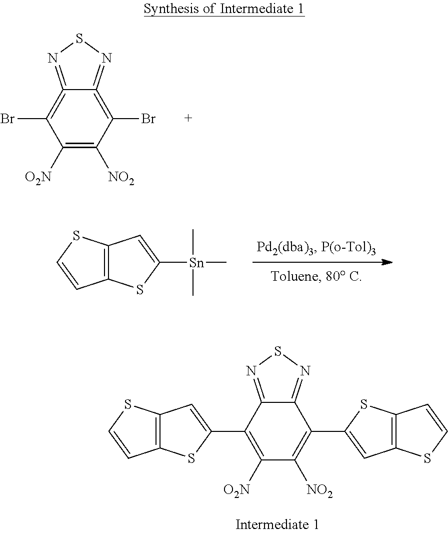

4,7-dibromo-5,6-dinitrobenzo[c][1,2,5]thiadiazole (1.470 g, 3.840 mmol), trimethyl(thieno[3,2-b]thiophen-2-yl) stannane (2.50 g, 8.25 mmol), tris(dibenzylideneacetone) dipalladium (140 mg, 0.154 mmol), and tri (o-tolyl)phosphine (187 mg, 0.612 mmol) were placed into a two necked flask, degassed under vacuum and refilled with argon three times. Toluene (29 mL) was then added under an argon atmosphere. The reaction mixture was heated at 80° C. in an oil bath under argon protection. After completion, the reaction was cooled, and the mixture was filtered through a Celite/silica gel pad and washed with dichloromethane (3×100 mL). The filtrate was concentrated under reduced pressure to remove the solvent. The resulting crude product was suspended in methanol (100 mL) to precipitate a solid Intermediate 1. After filtering and drying, Intermediate 1 was directly subjected to the next step of reaction without further purification.

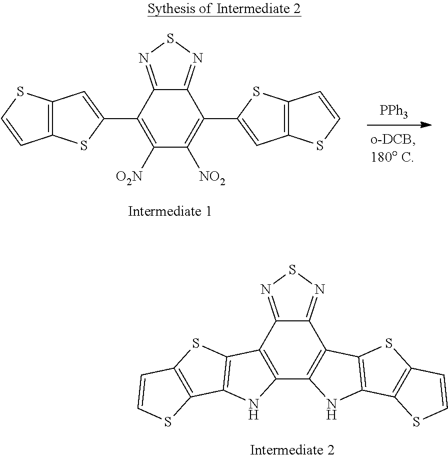 [SMILES: O=[N+]([O-])c1c([N+](=O)[O-])c(-c2cc3sccc3s2)c2nsnc2c1-c1cc2sccc2s1 ; c1cc2sc3c([nH]c4c5[nH]c6c7sccc7sc6c5c5nsnc5c43)c2s1 ; "PPh3"]

o-dichlorobenzene (15 mL) was added to a round-bottom flask containing Intermediate 1 (0.73 g, 1.453 mmol) and triphenylphosphine (3.81 g, 14.525 mmol). The mixture was heated at 180° C. in an oil bath under an argon atmosphere. After completion of the reaction, the mixture was cooled to room temperature, and o-dichlorobenzene was removed by rotary evaporation under reduced pressure. The resulting crude product was suspended in methanol (100 mL) to precipitate a solid Intermediate 2. After filtering and drying, Intermediate 2 was directly subjected to the next step of reaction without further purification.

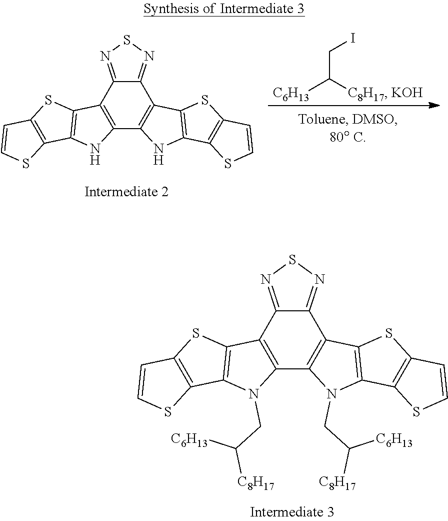

Toluene (15 mL) and dimethyl sulfoxide (15 mL) were added to a round-bottom flask containing Intermediate 2 (1.5 g, 3.420 mmol) and potassium hydroxide (1.151 g, 20.521 mmol). The reaction mixture was heated to 80° C. under an argon atmosphere and stirred for 30 minutes. Subsequently, 2-hexyl-1-iododecane (7.230 g, 20.521 mmol) was added, and the reaction was continued at 80° C. After completion, the mixture was cooled to room temperature and extracted with n-heptane (3×50 mL) and water. The organic layer was dried over anhydrous magnesium sulfate, filtered, and the solvent was removed under reduced pressure. The crude product was purified by silica gel column chromatography (the eluent was dichloromethane/n-heptane=1/2), affording Intermediate 3 (1.66 g, 55%). ¹H NMR (600 MHZ, CDCl₃): δ 7.43 (2H, d, J=5.4 Hz), 7.32 (2H, d, J=5.4 Hz), 4.57 (4H, d, J=9.0 Hz), 1.95-2.02 (2H, m), 0.65-1.18 (60H, m).

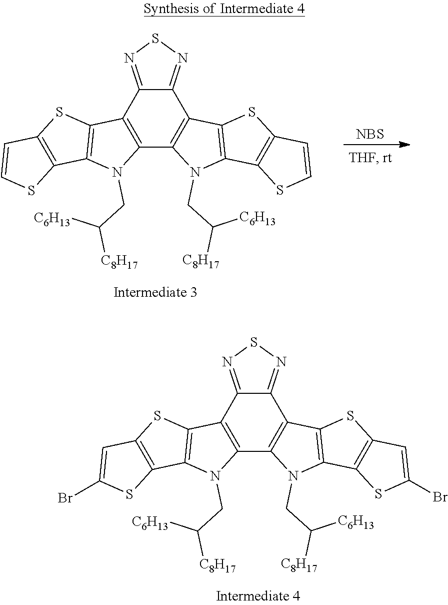

Tetrahydrofuran (THF, 83 mL) was added to a round-bottom flask containing Intermediate 3 (1.66 g, 1.871 mmol). Separately, N-bromosuccinimide (NBS, 0.699 g, 3.928 mmol) was slowly added to the flask at room temperature. The reaction was carried out under a nitrogen atmosphere at room temperature. After completing consumption of Intermediate 3, the reaction was quenched by the addition of water. The resulting mixture was extracted with dichloromethane (3×50 mL) and water. The organic layer was dried over anhydrous magnesium sulfate, filtered, and the solvent was removed under reduced pressure. The crude product was purified by silica gel column chromatography (the eluent was dichloromethane/n-heptane=1/2), affording Intermediate 4 (1.58 g, 81%). ¹H NMR (600 MHz, CDCl₃) δ 7.43 (2H, s), 4.57 (4H, d, J=9.0 Hz), 1.95-2.02 (2H, m), 0.65-1.18 (60H, m).

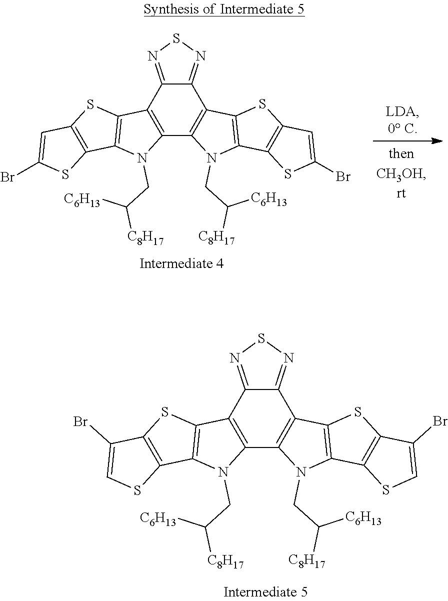

Intermediate 4 (1.0 g, 0.957 mmol) was placed into a three necked flask, degassed under vacuum, and refilled with argon three times. Anhydrous tetrahydrofuran (THF, 20 mL) was added under an argon atmosphere. The reaction mixture was cooled to 0° C., and 2.0 M lithium diisopropylamide (LDA) solution (1.913 mL, 3.826 mmol) was slowly added under argon. The reaction was stirred at 0° C. for 2 hours. Subsequently, methanol (0.206 mL, 4.874 mmol) was slowly added under argon, and the mixture was allowed to warm to room temperature and stirred until Intermediate 4 was completely consumed. The reaction was quenched by the addition of water. The resulting mixture was extracted with n-heptane (3×50 mL) and water. The organic layer was dried over anhydrous magnesium sulfate, filtered, and the solvent was removed under reduced pressure. The crude product was purified by silica gel column chromatography (the eluent was dichloromethane/n-heptane=1/3), affording Intermediate 5 (0.370 g, 37%). ¹H NMR (600 MHZ, CDCl₃) δ 7.30 (2H, s), 4.57 (4H, d, J=9.0 Hz), 2.01-2.04 (2H, m), 0.88-1.18 (60H, m).

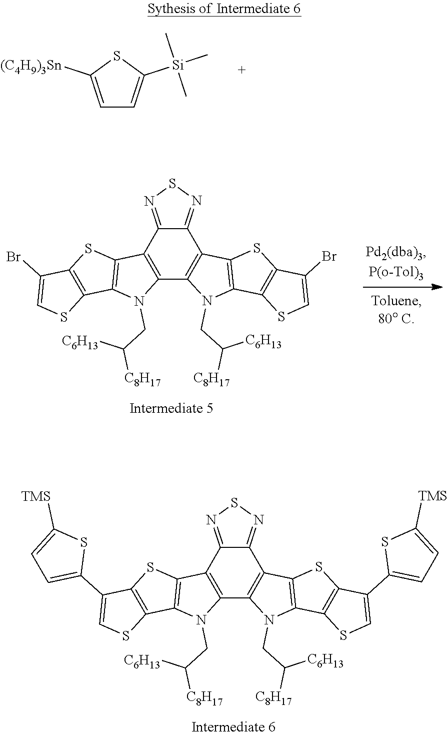

Intermediate 5 (0.300 g, 0.287 mmol), tributyl[5-(trimethylsilyl)-2-thienyl]stannane (0.281 g, 0.631 mmol), tris(dibenzylideneacetone) dipalladium (0) (10 mg, 0.011 mmol), and tri (o-tolyl)phosphine (14 mg, 0.046 mmol) were placed into a two necked flask. The mixture was degassed under vacuum and refilled with argon three times. Toluene (13 mL) was added under an argon atmosphere, and the reaction was heated at 80° C. under argon protection. After completion, the reaction mixture was cooled to room temperature and filtered through a Celite/silica gel pad. The filter cake was rinsed with dichloromethane (3×50 mL). The combined filtration was concentrated under reduced pressure to remove the solvent. The crude product was purified by silica gel column chromatography (the eluent was dichloromethane/n-heptane=1/3), affording Intermediate 6 (0.250 g, 74%). ¹H NMR (600 MHZ, CDCl₃) δ 7.61 (2H, d, J=3.6 Hz), 7.51 (2H, s), 7.29 (2H, d, J=3.6 Hz), 4.63 (4H, d, J=7.2 Hz), 2.07-2.10 (2H, m), 0.93-1.15 (60H, m), 0.39 (18H, s).

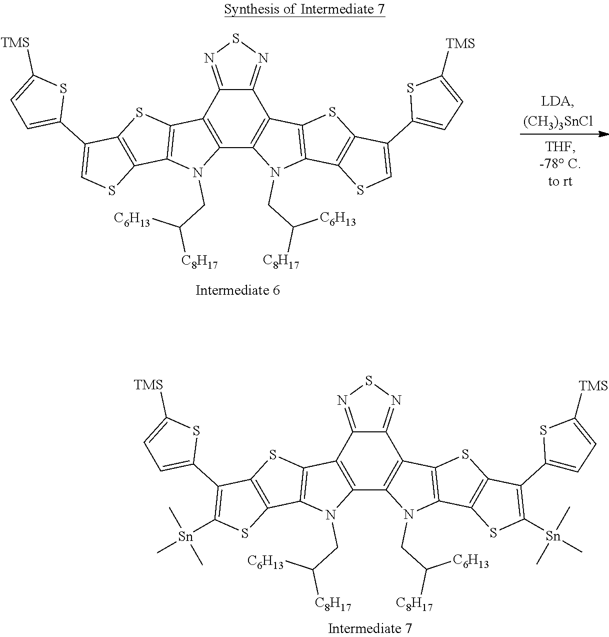

Intermediate 6 (0.250 g, 0.209 mmol) was placed into a three necked flask, degassed under vacuum, and refilled with argon three times. Anhydrous tetrahydrofuran (THF, 10 mL) was added under an argon atmosphere. The reaction mixture was cooled to −78° C., and 2.0 M lithium diisopropylamide (LDA) solution (0.418 mL, 0.836 mmol) was slowly added under argon. The mixture was stirred at −78° C. for 1 hour. Subsequently, THE solution of trimethyltin chloride (0.250 g, 1.254 mmol) was slowly added under argon, and the mixture was allowed to warm to room temperature and stirred until Intermediate 6 was completely consumed. The reaction was quenched by the addition of water. The resulting mixture was extracted with n-heptane (3×50 mL) and water. The organic layer was dried over anhydrous magnesium sulfate, filtered, and the solvent was removed under reduced pressure. The crude product was suspended in methanol (100 mL) to precipitate a solid, affording Intermediate 7 (0.308 g, 96%). ¹H NMR (600 MHz, CDCl₃) δ 7.42 (2H, d, J=3.0 Hz), 7.27 (2H, d, J=3.0 Hz), 4.63 (4H, d, J=7.8 Hz), 2.08-2.11 (2H, m), 0.81-1.17 (60H, m), 0.38 (36H, s).

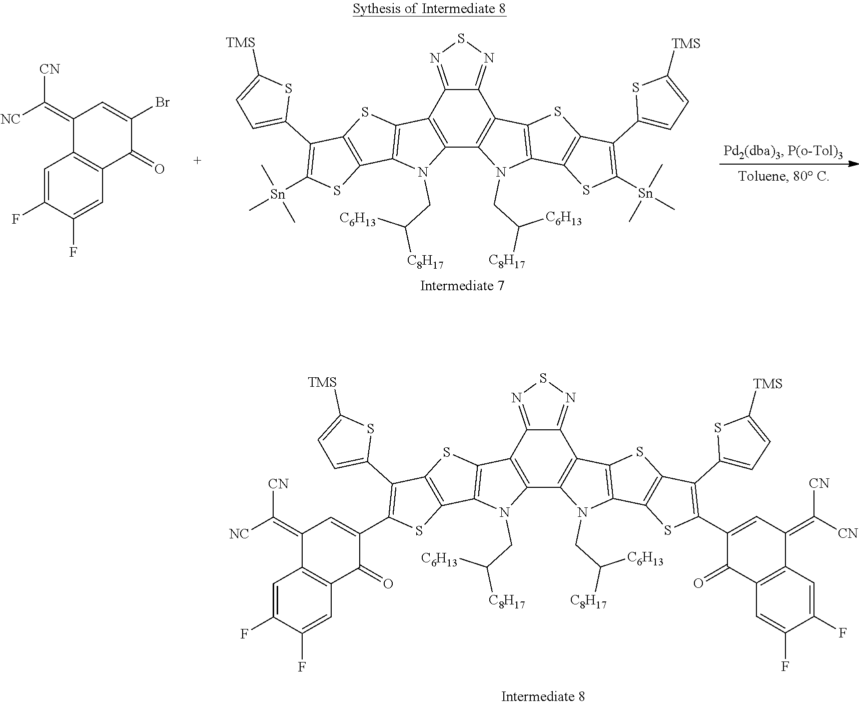

Intermediate 7 (0.472 g, 0.310 mmol), 2-(3-bromo-6,7-difluoro-4-oxonaphthalen-1 (4H)-ylidene) malononitrile (0.249 g, 0.775 mmol), tris(dibenzylideneacetone) dipalladium (11 mg, 0.012 mmol), and tri (o-tolyl)phosphine (15 mg, 0.050 mmol) were placed into a two necked flask. The mixture was degassed under vacuum and refilled with argon three times. Toluene (14 mL) was added under an argon atmosphere, and the reaction mixture was heated at 80° C. under argon protection. After completion, the reaction mixture was cooled to room temperature and filtered through a Celite/silica gel pad. The filter cake was rinsed with dichloromethane (3×100 mL). The combined filtration was concentrated under reduced pressure to remove the solvent. The crude product was purified by silica gel column chromatography (the eluent was dichloromethane/n-heptane=1/1.5), affording Intermediate 8 (174 mg, 33%). ¹H NMR (600 MHZ, CDCl₃) δ 8.17-8.19 (2H, m), 7.42 (2H, s), 7.36 (2H, d, J=3.6 Hz), 7.26 (4H, s), 4.69 (4H, d, J=7.8 Hz), 2.11-2.14 (2H, m), 0.67-1.16 (60H, m), 0.39 (18H, s).

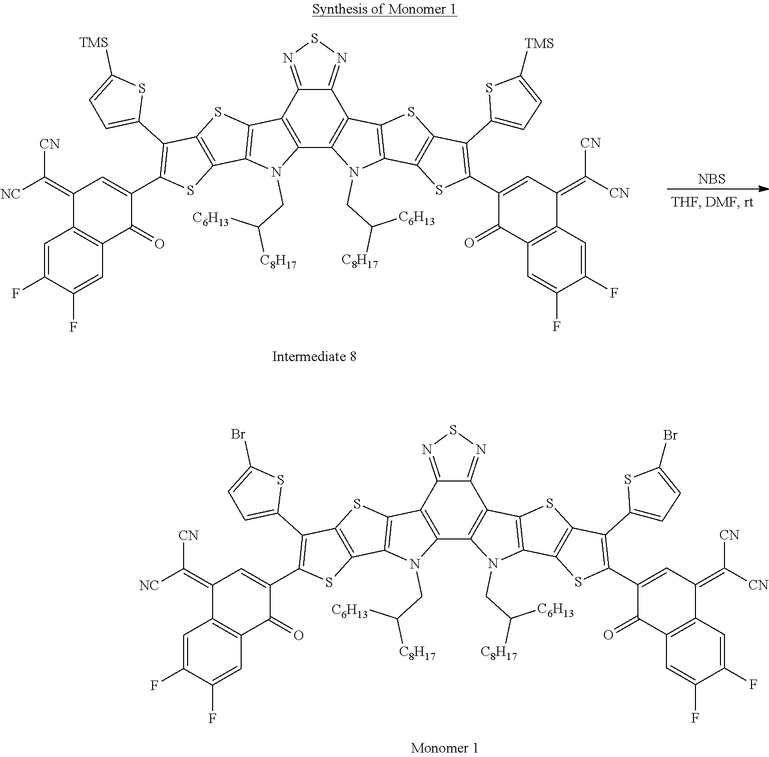

Tetrahydrofuran (THF, 5.2 mL) and N,N-dimethylformamide (DMF, 0.17 mL) were added to a round-bottom flask containing Intermediate 8 (174 mg, 0.111 mmol). Separately, N-bromosuccinimide (NBS, 59 mg, 0.334 mmol) was slowly added to the reaction flask at room temperature. The reaction was carried out at room temperature under a nitrogen atmosphere. After completing consumption of the starting material, the reaction was quenched by the addition of water. The mixture was extracted with dichloromethane (3×50 mL) and water. The organic layer was dried over anhydrous magnesium sulfate and filtered. The crude product was purified by silica gel column chromatography (the eluent was dichloromethane/n-heptane=1/1), affording Monomer 1 (129 mg, 74%). ¹H NMR (600 MHZ, CDCl₃) δ 8.72-8.75 (2H, m), 8.17-8.20 (2H, m), 8.00 (2H, s), 7.26 (2H, d, J=3.6 Hz), 7.19 (2H, d, J=3.6 Hz), 4.68 (m, d, J=7.8 Hz), 2.06-2.12 (2H, m), 0.87-1.16 (60H, m).

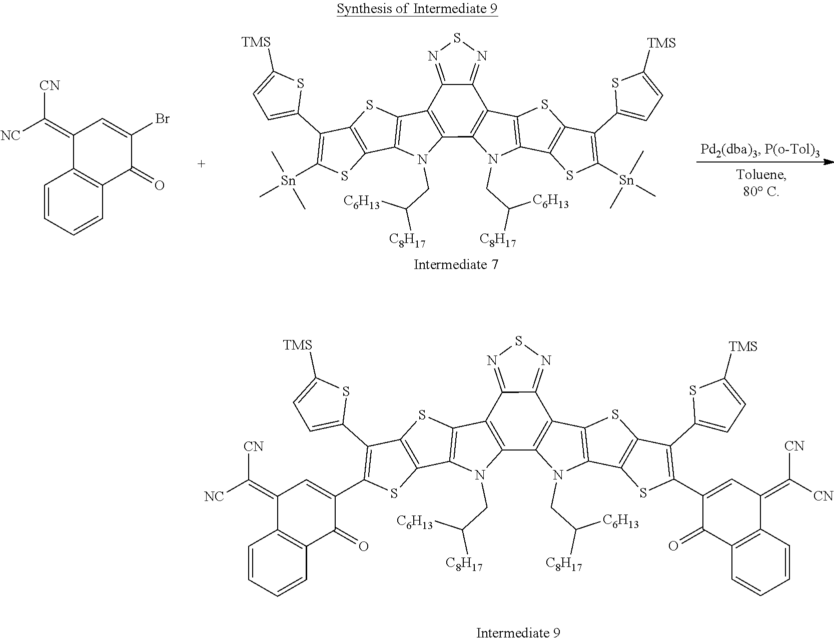

The synthesis method of Intermediate 9 is the same as that of Intermediate 8. Intermediate 7 (200 mg, 0.134 mmol), 2-(3-bromo-4-oxonaphthalen-1 (4H)-ylidene) malononitrile (82 mg, 0.289 mmol), tris(dibenzylideneacetone) dipalladium (5 mg, 0.005 mmol), and tri (o-tolyl)phosphine (6 mg, 0.021 mmol) were reacted under the same conditions. The crude product was purified by silica gel column chromatography (the eluent was dichloromethane/n-heptane=2/1), affording Intermediate 9 (91 mg, 43%). ¹H NMR (600 MHZ, CDCl₃) δ 8.81-8.83 (2H, m), 8.38-8.40 (2H, m), 7.88 (2H, s), 7.80-7.83 (4H, m), 7.44 (2H, d, J=4.2 Hz), 7.37 (2H, d, J=4.2 Hz), 4.70 (4H, d, J=9.6 Hz), 2.12-2.17 (2H, m), 0.67-1.16 (60H, m), 0.39 (18H, s).

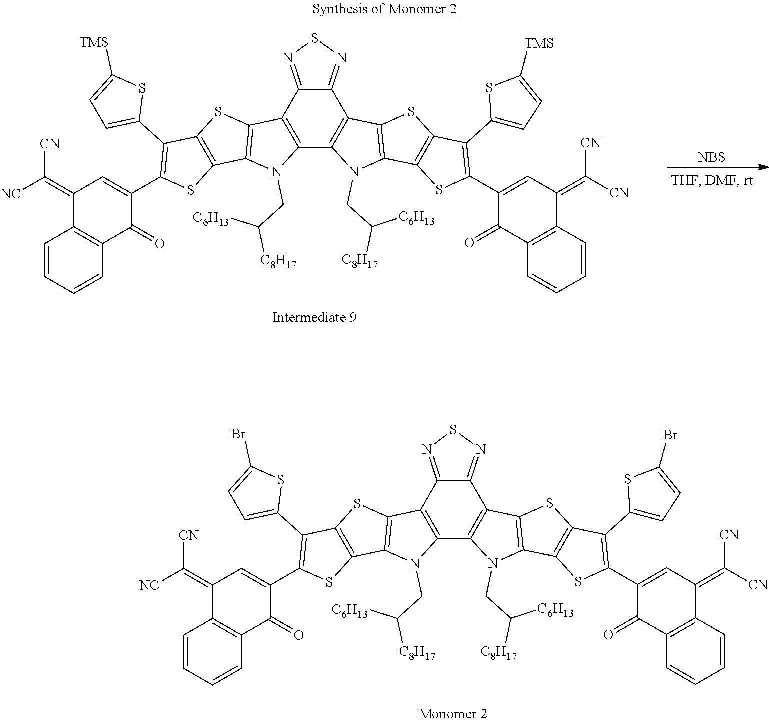

The synthesis method of Monomer 2 is the same as that of Monomer 1. Tetrahydrofuran (THF, 4.0 mL) and N,N-dimethylformamide (DMF, 0.1 mL) were added to a round-bottom flask containing Intermediate 9 (89 mg, 0.055 mmol). Separately, N-bromosuccinimide (NBS, 30 mg, 0.166 mmol) was slowly added at room temperature. The reaction was carried out at room temperature. The crude product was purified by silica gel column chromatography (the eluent was dichloromethane/n-heptane=1.5/1), affording Monomer 2 (161 mg, 92%). ¹H NMR (600 MHz, CDCl₃) δ 8.83-8.85 (2H, m), 8.38-8.40 (2H, m), 8.01 (2H, s), 7.82-7.85 (4H, m), 7.25 (2H, d, J=3.6 Hz), 7.19 (2H, d, J=3.6 Hz), 4.69 (4H, d, J=7.8 Hz), 2.11-2.13 (2H, m), 0.67-1.16 (60H, m).

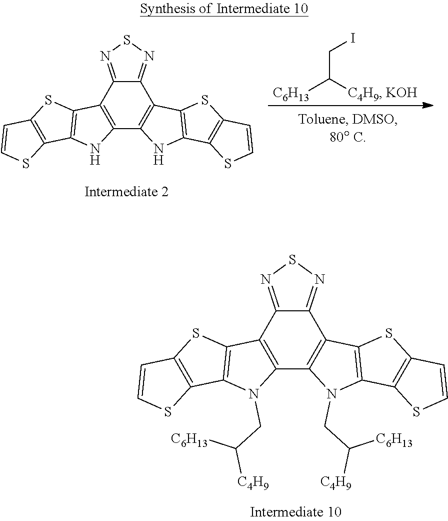

Toluene (10 mL) and dimethyl sulfoxide (DMSO, 10 mL) were added to a round-bottom flask containing Monomer 2 (1.0 g, 2.280 mmol) and potassium hydroxide (0.768 g, 13.681 mmol). The reaction mixture was heated at 80° C. under an argon atmosphere and stirred for 30 minutes. 2-Butyl-1-iodooctane (4.053 g, 13.681 mmol) was then added, and the reaction was continued at 80° C. After completion, the reaction mixture was cooled to room temperature and extracted with n-heptane (3×50 mL) and water. The organic layer was dried over anhydrous magnesium sulfate, filtered, and the solvent was removed under reduced pressure. The crude product was purified by silica gel column chromatography (the eluent was dichloromethane/n-heptane=1/2), affording Intermediate 10 (0.85 g, 48%). ¹H NMR (600 MHZ, CDCl₃) δ 7.43 (2H, d, J=5.4 Hz), 7.41 (2H, d, J=5.4 Hz), 4.62 (4H, t, J=7.8 Hz), 2.03-2.08 (2H, m), 0.55-1.32 (44H, m).

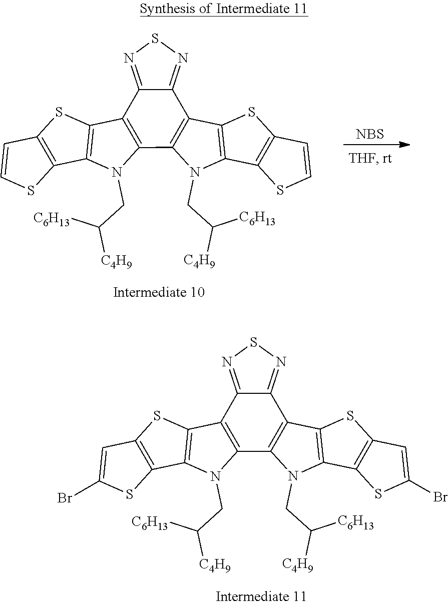

The synthesis method of Intermediate 11 is the same as that of Intermediate 4. Tetrahydrofuran (THF, 6.9 mL) was added to a round-bottom flask containing Intermediate 10 (0.85 g, 1.096 mmol). Separately, N-bromosuccinimide (NBS, 0.410 g, 2.303 mmol) was slowly added at 0° C., and the reaction was allowed to proceed at room temperature. The crude product was purified by silica gel column chromatography (the eluent was dichloromethane/n-heptane=1/3), affording Intermediate 11 (0.96 g, 94%). ¹H NMR (600 MHz, CDCl₃) δ 7.43 (2H, s), 4.53 (4H, t, J=7.8 Hz), 1.92-2.05 (2H, m), 0.59-1.30 (44H, m).

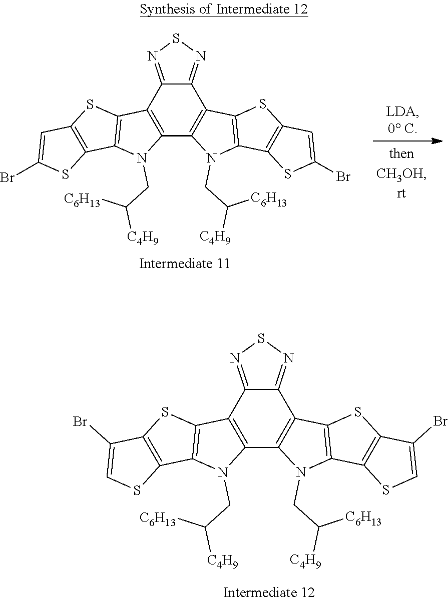

Intermediate 11 (0.943 g, 1.011 mmol) was placed into a three necked flask, degassed under vacuum, and refilled with argon three times. Anhydrous tetrahydrofuran (THF, 28 mL) was added under an argon atmosphere. The reaction mixture was cooled to 0° C., and 2.0 M lithium diisopropylamide (LDA) solution (2.527 mL, 5.034 mmol) was slowly added under argon. The mixture was stirred at 0° C. for 2 hours. Subsequently, methanol (0.434 mL, 10.107 mmol) was slowly added under argon, and the reaction was allowed to warm to room temperature and stirred until Intermediate 11 was completely consumed. The reaction was quenched by the addition of water. The resulting mixture was extracted with n-heptane (3×50 mL) and water. The organic layer was dried over anhydrous magnesium sulfate, filtered, and the solvent was removed under reduced pressure. The crude product was purified by silica gel column chromatography (the eluent was dichloromethane/n-heptane=1/2), affording Intermediate 12 (0.436 g, 46%). ¹H NMR (600 MHZ, CDCl₃) δ 7.30 (2H, s), 4.54-4.60 (4H, m), 2.00-2.06 (2H, m), 0.58-1.10 (44H, m).

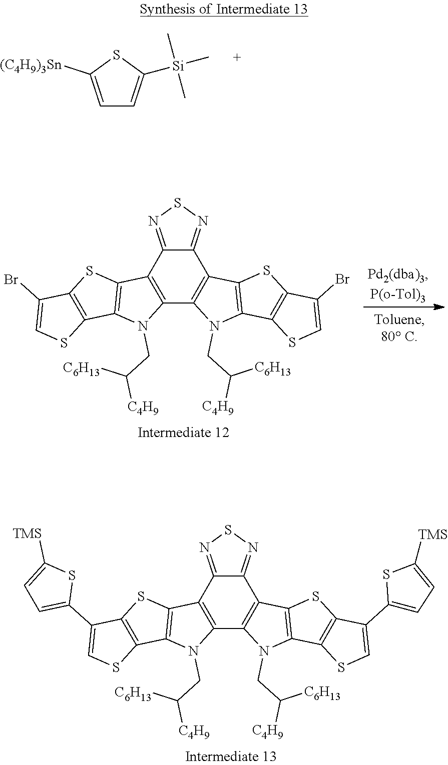

The synthesis method of Intermediate 13 is the same as that of Intermediate 6. Intermediate 12 (0.436 g, 0.467 mmol), tributyl[5-(trimethylsilyl)-2-thienyl]stannane (0.520 g, 1.168 mmol), tris(dibenzylideneacetone) dipalladium (17 mg, 0.019 mmol), and tri (o-tolyl)phosphine (23 mg, 0.075 mmol) were reacted under the same conditions. The crude product was purified by silica gel column chromatography (the eluent was dichloromethane/n-heptane=1/3), affording Intermediate 13 (0.377 g, 75%). ¹H NMR (600 MHz, CDCl₃) δ 7.62 (2H, d, J=3.4 Hz), 7.51 (2H, s), 7.30 (2H, d, J=3.4 Hz), 4.63 (4H, d=J=8.0 Hz), 2.07-2.13 (2H, m), 0.61-1.11 (44H, m), 0.40 (18H, s).

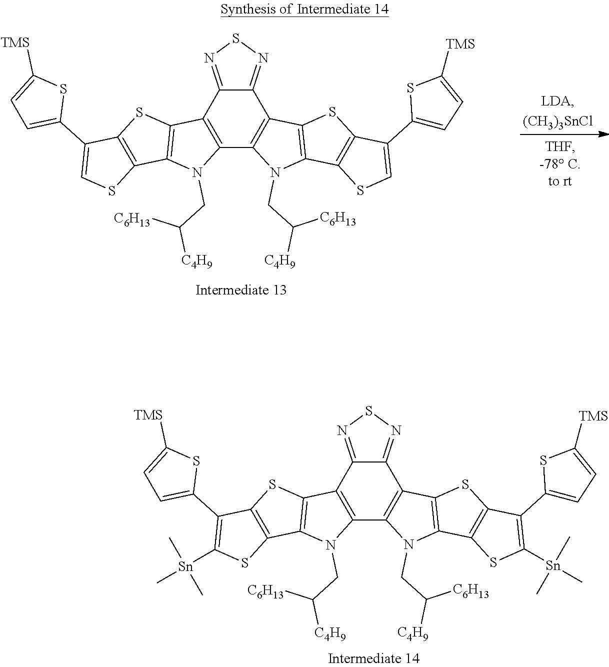

Intermediate 13 (0.377 g, 0.394 mmol) was placed into a three necked flask, degassed under vacuum, and refilled with argon three times. Anhydrous tetrahydrofuran (THF, 15 mL) was added under an argon atmosphere. The reaction mixture was cooled to −78° C., and 2.0 M lithium diisopropylamide (LDA) solution (0.708 mL, 1.416 mmol) was slowly added under argon. The mixture was stirred at −78° C. for 1 hour. Subsequently, a THF solution of trimethyltin chloride (0.423 g, 2.124 mmol) was slowly added under argon, and the mixture was allowed to warm to room temperature and stirred until the reaction was complete. The reaction was quenched by the addition of water. The resulting mixture was extracted with n-heptane (3×50 mL) and water. The organic layer was dried over anhydrous magnesium sulfate, filtered, and the solvent was removed under reduced pressure. The crude product was suspended in methanol (100 mL) to precipitate a solid, affording Intermediate 14 (0.498 g, 99%). ¹H NMR (600 MHz, CDCl₃) δ 7.43 (2H, d, J=3.3 Hz), 7.28 (2H, d, J=3.3 Hz), 4.64 (4H, d, J=7.8 Hz), 2.07-2.14 (2H, m), 0.60-1.16 (44H, m), 0.40 (18H, s), 0.39 (18H, s).

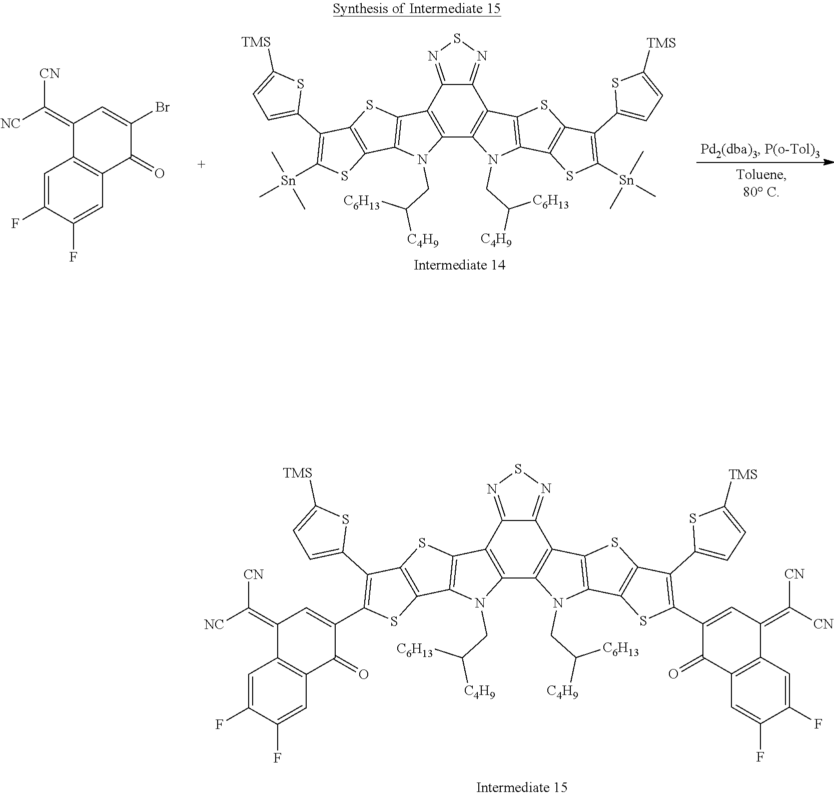

The synthesis method of Intermediate 15 is the same as that of Intermediate 8. Intermediate 14 (0.249 g, 0.177 mmol), 2-(3-bromo-6,7-difluoro-4-oxonaphthalen-1 (4H)-ylidene) malononitrile (0.142 g, 0.442 mmol), tris(dibenzylideneacetone) dipalladium (6 mg, 0.007 mmol), and tri (o-tolyl)phosphine (8 mg, 0.028 mmol) were reacted under the same conditions. The crude product was purified by silica gel column chromatography (the eluent was dichloromethane/n-heptane=1/1), affording Intermediate 15 (139 mg, 50%). ¹H NMR (600 MHZ, CDCl₃) δ 8.70-8.73 (2H, m), 8.17-8.20 (2H, m), 7.87 (2H, s), 7.43 (2H, d, J=3.4 Hz), 7.38 (2H, d, J=3.3 Hz), 4.64-4.74 (4H, m), 2.11-2.14 (2H, m), 0.63-1.10 (44H, m), 0.40 (18H, s).

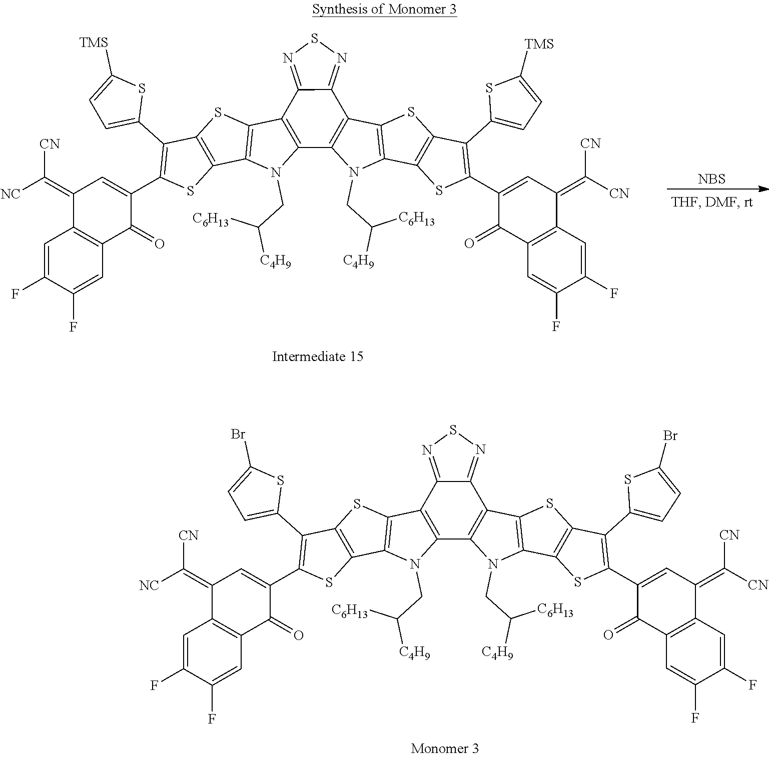

The synthesis method of Monomer 3 is the same as that of Monomer 1. Tetrahydrofuran (THF, 5.6 mL) and N,N-dimethylformamide (DMF, 0.14 mL) were added to a round-bottom flask containing Intermediate 15 (139 mg, 0.089 mmol). Separately, N-bromosuccinimide (NBS, 62 mg, 0.267 mmol) was slowly added at room temperature. The reaction was carried out at room temperature under a nitrogen atmosphere. The crude product was purified by silica gel column chromatography (the eluent was dichloromethane/n-heptane=2/1), affording Monomer 3 (110 mg, 79%). ¹H NMR (600 MHZ, CD₂Cl₂) δ 8.71-8.74 (2H, m), 8.17-8.20 (2H, m), 7.98 (2H, s), 7.28 (2H, d, J=3.7 Hz), 7.21 (2H, d, J=3.9 Hz), 4.68-4.77 (m, 4H), 2.12-2.15 (2H, m), 0.62-1.20 (44H, m).

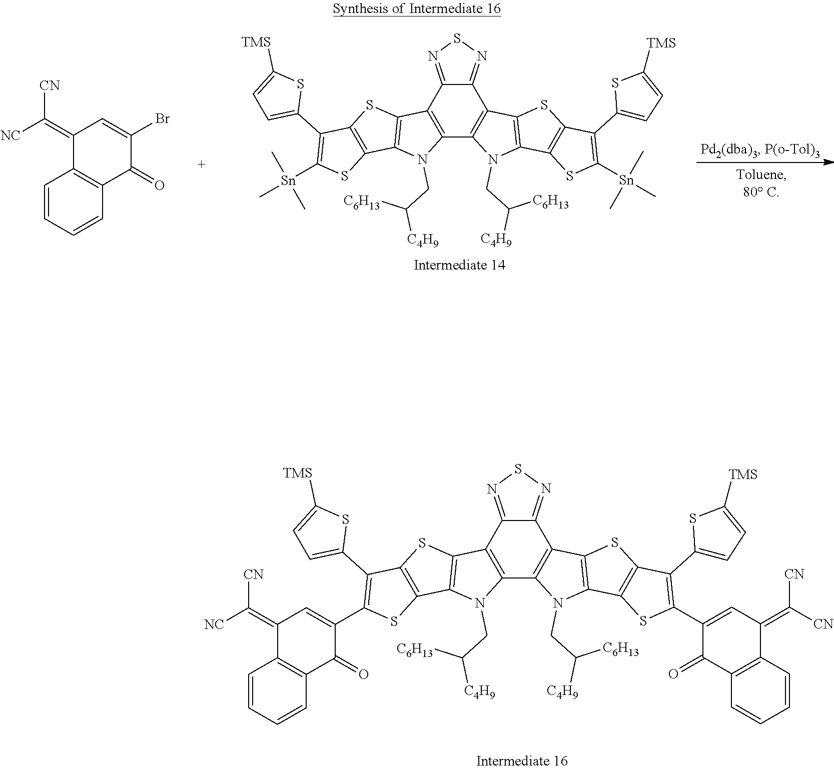

The synthesis method of Intermediate 16 is the same as that of Intermediate 8. Intermediate 14 (0.249 g, 0.177 mmol), 2-(3-bromo-4-oxonaphthalen-1 (4H)-ylidene) malononitrile (0.126 g, 0.442 mmol), tris(dibenzylideneacetone) dipalladium (6 mg, 0.007 mmol), and tri (o-tolyl)phosphine (8 mg, 0.028 mmol) were reacted under the same conditions. The crude product was suspended in methanol (100 mL) to precipitate a solid, affording Intermediate 16 (173 mg, 66%). ¹H NMR (600 MHZ, CDCl₃) δ 8.81-8.83 (2H, m), 8.38-8.39 (2H, m), 7.88 (2H, s), 7.80-7.84 (4H, m), 7.44 (2H, d, J=3.3 Hz), 7.37 (2H, d, J=3.4 Hz), 4.68-4.71 (4H, m), 2.14-2.18 (2H, m), 0.63-1.12 (44H, m), 0.40 (18H, s).

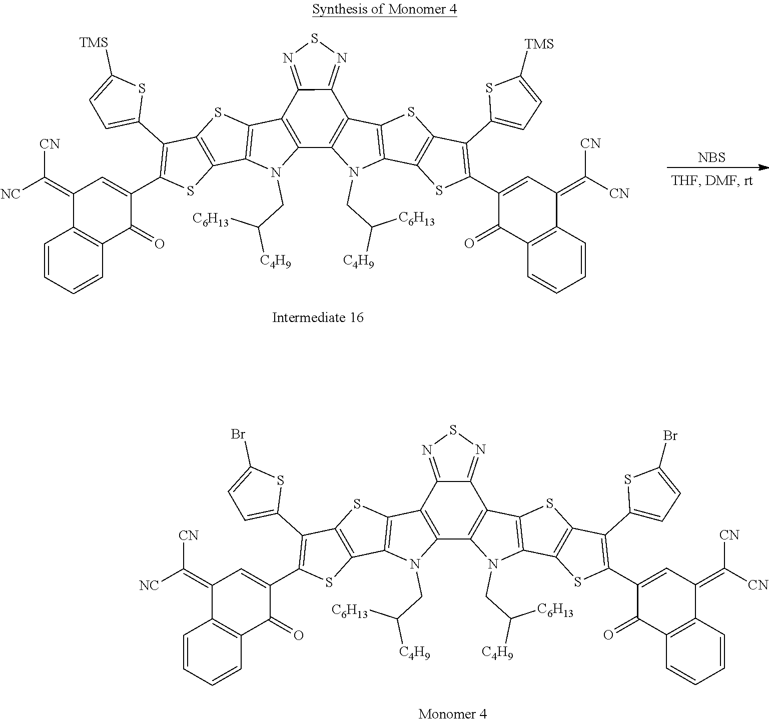

The synthesis method of Monomer 4 is the same as that of Monomer 1. Tetrahydrofuran (THF, 6.9 mL) and N,N-dimethylformamide (DMF, 0.17 mL) were added to a round-bottom flask containing Intermediate 16 (173 mg, 0.116 mmol). Separately, N-bromosuccinimide (NBS, 62 mg, 0.348 mmol) was slowly added at room temperature. The reaction was carried out at room temperature. The crude product was suspended in methanol (100 mL) to precipitate a solid, affording Monomer 4 (161 mg, 92%). ¹H NMR (600 MHZ, CDCl₃) δ 8.79 (2H, d, J=9.1 Hz), 8.33 (2H, d, J=8.9 Hz), 7.95 (2H, s), 7.80-7.85 (4H, m), 7.24 (2H, d, J=4.3 Hz), 7.18 (2H, d, J=4.3 Hz), 4.66-4.76 (4H, m), 2.09-2.15 (2H, m), 0.59-1.17 (44H, m).

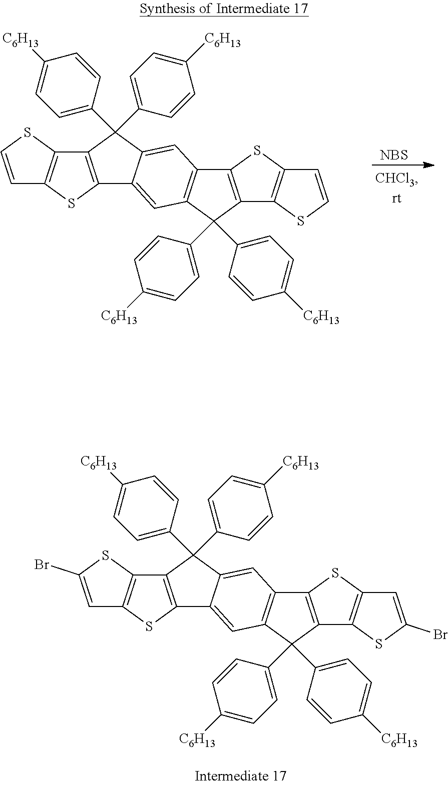

Chloroform (134 mL) was added to a round-bottom flask containing 6,6,12,12-tetra(4-hexylphenyl)-s-dibenzodithiopheno[3,2-b]thiophene (4.476 g, 4.390 mmol). Separately, N-bromosuccinimide (NBS, 1.602 g, 10.975 mmol) was slowly added at room temperature. The reaction was carried out at room temperature. The crude product was suspended in methanol (250 mL) to precipitate a solid, affording Intermediate 17 (4.570 g, 88%). ¹H NMR (500 MHZ, CDCl₃) δ 7.47 (2H, s), 7.27 (2H, s), 7.12 (8H, d, J=7.5 Hz), 7.08 (8H, d, J=8.0 Hz), 2.55 (8H, t, J=7.5 Hz), 1.54-1.59 (8H, m), 1.26-1.34 (24H, m), 0.86 (12H, t, J=7 Hz).

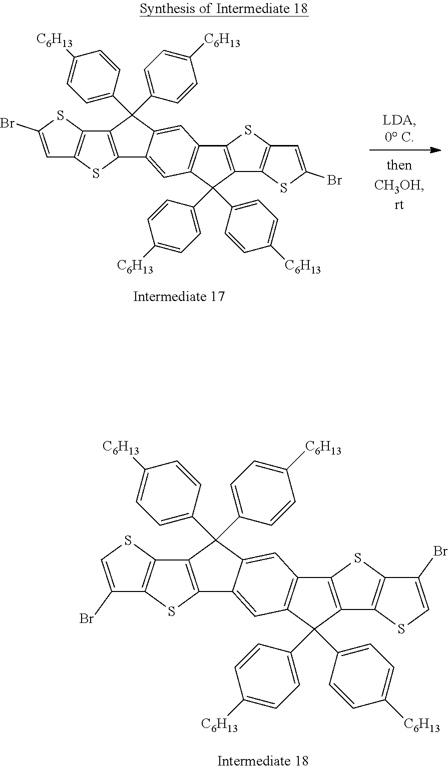

Intermediate 17 (4.570 g, 3.882 mmol) was placed into a three-neck flask, degassed under vacuum, and refilled with argon three times. Anhydrous tetrahydrofuran (THF, 28 mL) was added under an argon atmosphere. The reaction mixture was cooled to 0° C., and 2.0 M lithium diisopropylamide (LDA) solution (9.704 mL, 19.407 mmol) was slowly added under argon. The reaction was stirred at 0° C. for 2 hours. Subsequently, methanol (1.668 mL, 38.815 mmol) was slowly added under argon, and the mixture was allowed to warm to room temperature and stirred until Intermediate 17 was completely consumed. The reaction was quenched by the addition of water. The resulting mixture was extracted with n-heptane (3×100 mL) and water. The organic layer was dried over anhydrous magnesium sulfate, filtered, and the solvent was removed under reduced pressure. The crude product was purified by silica gel column chromatography (the eluent was dichloromethane/n-heptane=1/7), affording Intermediate 18 (2.805 g, 61%). ¹H NMR (500 MHZ, CDCl₃) δ 7.52 (2H, s), 7.15 (2H, s), 7.14 (8H, d, J=8.0 Hz), 7.08 (8H, d, J=8.0 Hz), 2.55 (8H, t, J=8 Hz), 1.55-1.62 (8H, m), 1.22-1.35 (24H, m), 0.86 (12H, t, J=7 Hz).

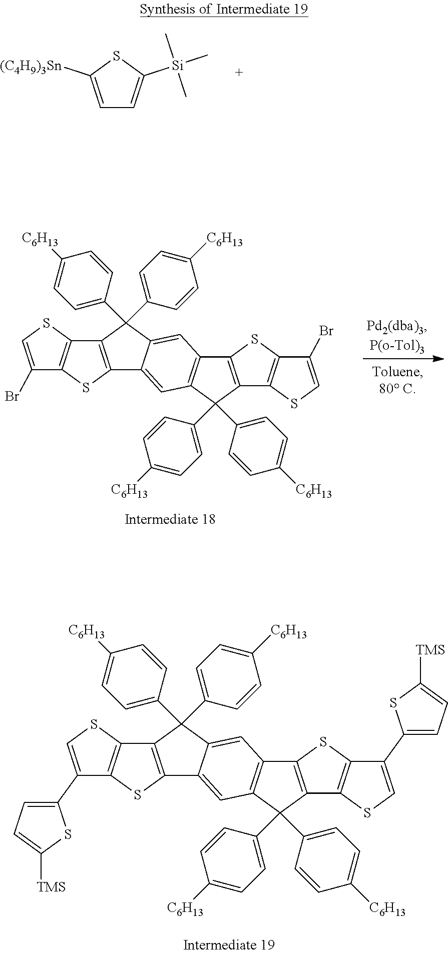

The synthesis method of Intermediate 19 is the same as that of Intermediate 6. Intermediate 18 (2.805 g, 2.382 mmol), tributyl[5-(trimethylsilyl)-2-thienyl]stannane (2.653 g, 5.956 mmol), tris(dibenzylideneacetone) dipalladium (87 mg, 0.095 mmol), and tri (o-tolyl)phosphine (116 mg, 0.381 mmol) were reacted under the same conditions. The crude product was purified by silica gel column chromatography (the eluent was dichloromethane/n-heptane=1/8), affording Intermediate 19 (1.733 g, 55%). ¹H NMR (600 MHZ, CDCl₃) δ 7.55 (2H, s), 7.42 (2H, d, J=3.0 Hz), 7.36 (2H, s), 7.23 (2H, d, J=3.0 Hz), 7.19 (8H, d, J=8.4 Hz), 7.09 (8H, d, J=8.4 Hz), 2.55 (8H, t, J=7.8 Hz), 1.55-1.61 (8H, m), 1.25-1.33 (24H, m), 0.86 (12H, t, J=7.2 Hz), 0.36 (18H, s).

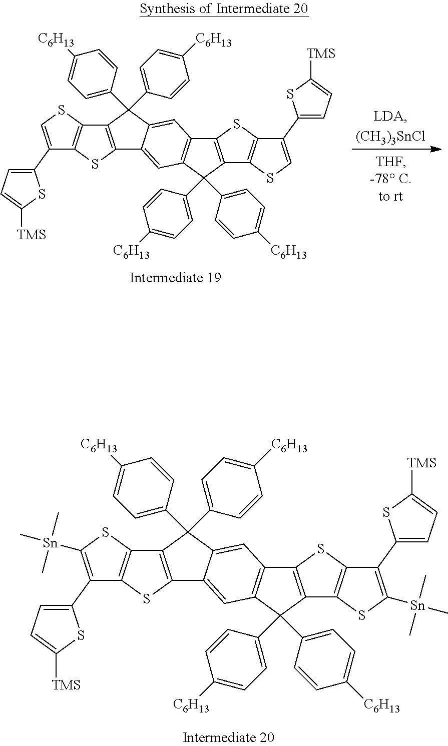

Intermediate 19 (0.945 g, 0.711 mmol) was placed into a three necked flask, degassed under vacuum, and refilled with argon three times. Anhydrous tetrahydrofuran (THF, 15 mL) was added under an argon atmosphere. The reaction mixture was cooled to −78° C., and 2.0 M lithium diisopropylamide (LDA) solution (1.422 mL, 2.846 mmol) was slowly added under argon. The mixture was stirred at −78° C. for 1 hour. Subsequently, a THF solution of trimethyltin chloride (0.851 g, 4.269 mmol) in anhydrous THF (20 mL) was slowly added under argon, and the mixture was allowed to warm to room temperature and stirred until Intermediate 19 was completely consumed. The reaction was quenched by the addition of water. The resulting mixture was extracted with n-heptane (3×75 mL) and water. The organic layer was dried over anhydrous magnesium sulfate, filtered, and the solvent was removed under reduced pressure. The crude product was suspended in methanol (100 mL) to precipitate a solid, affording Intermediate 20 (1.060 g, 90%). ¹H NMR (600 MHz, CDCl₃) δ 7.46 (2H, s), 7.25 (2H, d, J=3.0 Hz), 7.21 (2H, s), 7.20 (8H, d, J=7.8 Hz), 7.08 (8H, d, J=8.4 Hz), 2.56 (8H, t, J=7.8 Hz), 1.55-1.61 (8H, m), 1.26-1.35 (24H, m), 0.86 (12H, t, J=7.2 Hz), 0.35 (18H, s), 0.27 (18H, s).

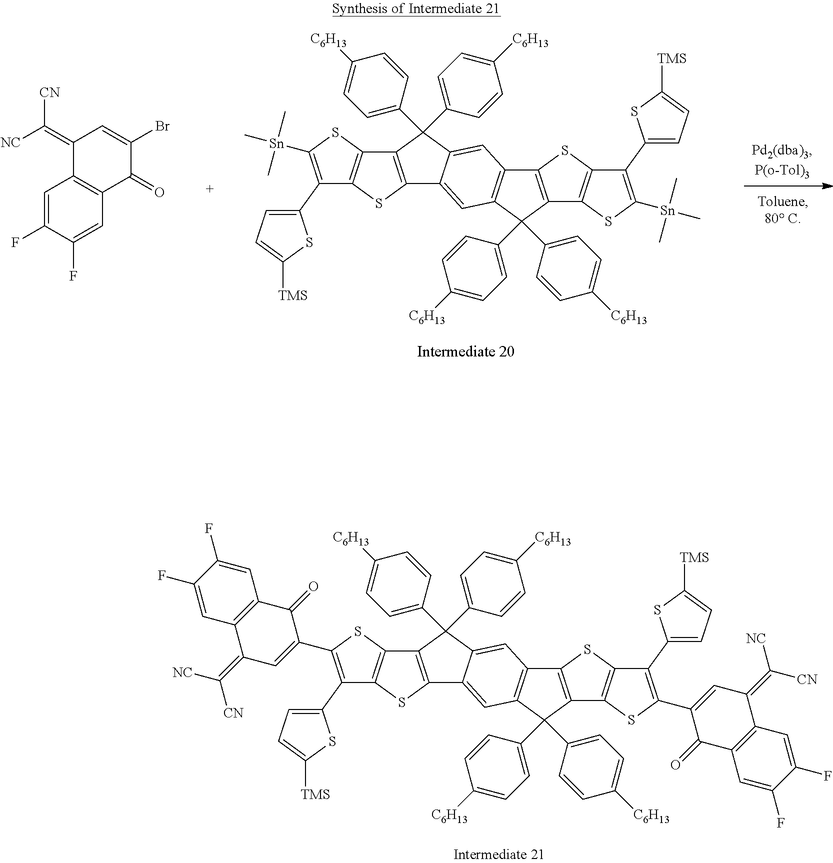

The synthesis method of Intermediate 21 is the same as that of Intermediate 8. Intermediate 20 (0.350 g, 0.212 mmol), 2-(3-bromo-6,7-difluoro-4-oxonaphthalen-1 (4H)-ylidene) malononitrile (0.170 g, 0.529 mmol), tris(dibenzylideneacetone) dipalladium (8 mg, 0.008 mmol), and tri (o-tolyl)phosphine (10 mg, 0.034 mmol) were reacted under the same conditions. The crude product was purified by silica gel column chromatography (the eluent was dichloromethane/n-heptane=1/1.5), affording Intermediate 21 (155 mg, 40%). ¹H NMR (500 MHZ, CDCl₃) δ 8.64-8.68 (2H, m), 8.05-8.09 (2H, m), 7.71 (2H, s), 7.54 (2H, s), 7.30 (2H, d, J=3.5 Hz), 7.27 (2H, d, J=3.0 Hz), 7.19 (8H, d, J=8.5 Hz), 7.11 (8H, d, J=8.5 Hz), 2.56 (8H, t, J=8.0 Hz), 1.55-1.61 (8H, m), 1.25-1.33 (24H, m), 0.86 (12H, t, J=7.0 Hz), 0.35 (18H, s).

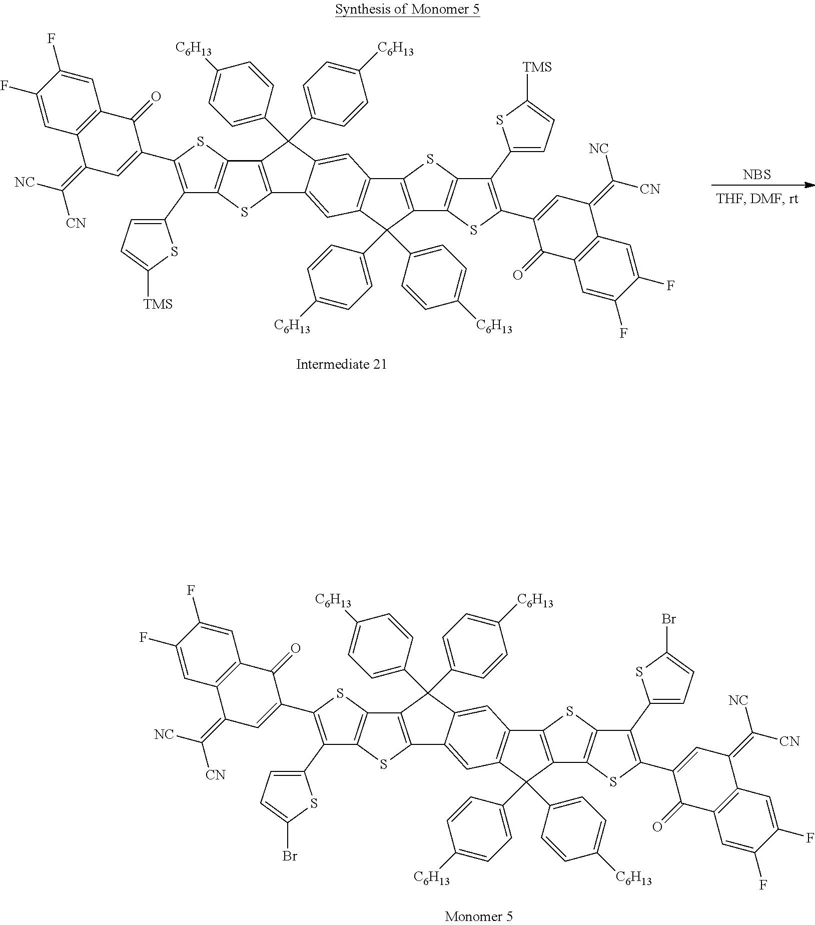

The synthesis method of Monomer 5 is the same as that of Monomer 1. Tetrahydrofuran (THF, 6 mL) and N,N-dimethylformamide (DMF, 0.16 mL) were added to a round-bottom flask containing Intermediate 21 (155 mg, 0.086 mmol). Separately, N-bromosuccinimide (NBS, 46 mg, 0.257 mmol) was slowly added at room temperature. The reaction was carried out at room temperature. The crude product was suspended in methanol (100 mL) to precipitate a solid, affording Monomer 5 (119 mg, 76%). ¹H NMR (600 MHZ, CDCl₃) δ 8.66-8.69 (2H, m), 8.06-8.09 (2H, m), 7.84 (2H, s), 7.55 (2H, s), 7.18 (8H, d, J=8.4 Hz), 7.16 (2H, d, J=3.6 Hz), 7.12 (8H, d, J=7.8 Hz), 7.01 (2H, d, J=3.6 Hz), 2.56 (8H, t, J=7.8 Hz), 1.56-1.61 (8H, m), 1.26-1.36 (24H, m), 0.86 (12H, t, J=7.2 Hz).

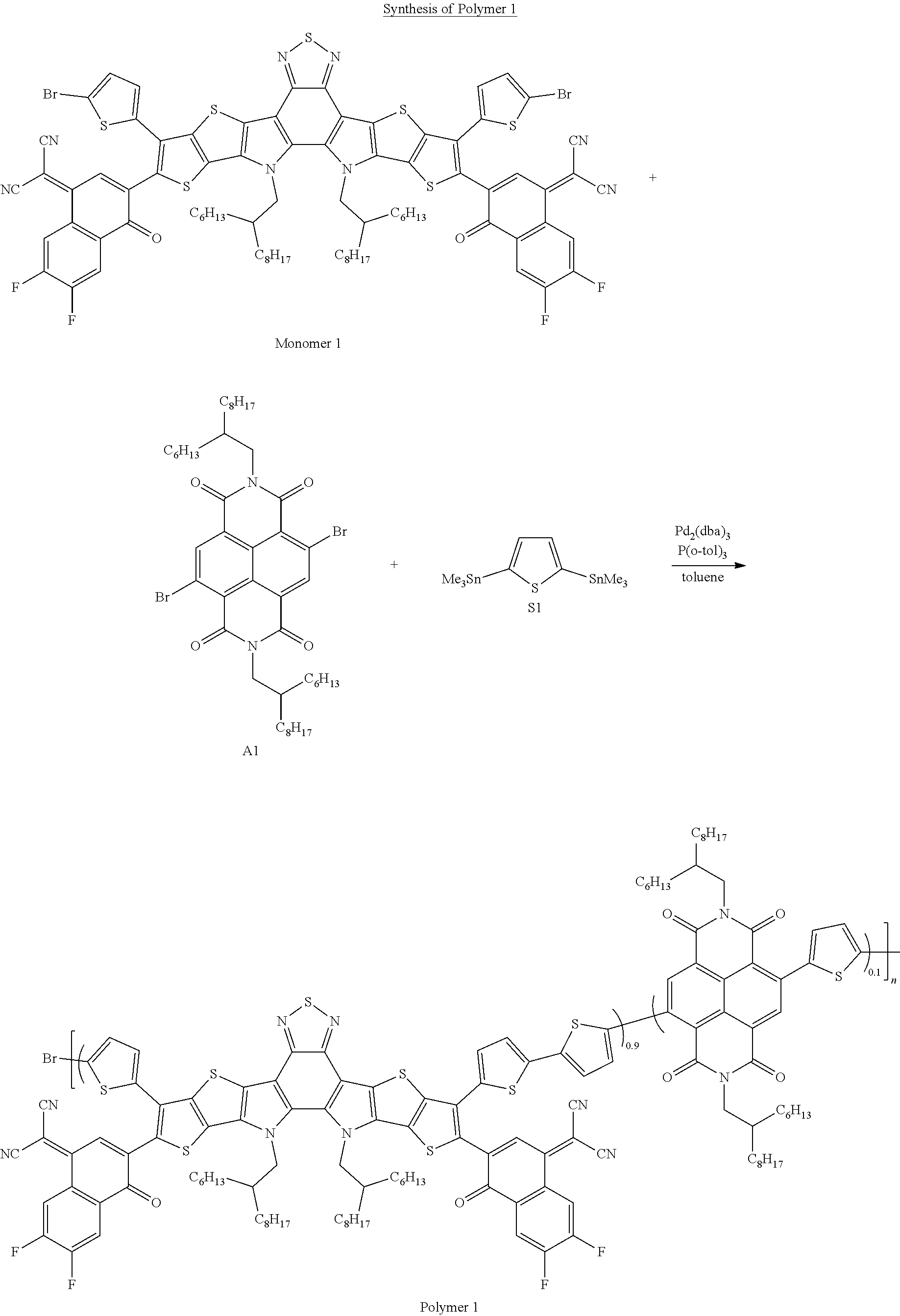

Monomer 1 (100 mg, 0.059 mmol), A1 (5.7 mg, 0.007 mmol), S1 (27 mg, 0.066 mmol), tris(dibenzylideneacetone) dipalladium (1.2 mg, 2 mol %), and tri (o-tolyl)phosphine (1.6 mg, 8 mol %) were placed into a two necked flask. The flask was degassed under vacuum and refilled with argon three times, then maintained under an argon atmosphere. Degassed toluene (1.9 mL) was added, and the reaction mixture was stirred at 110° C. in an oil bath for 30 minutes. Subsequently, 0.14 mL of bromobenzene was added, and the mixture was further reacted at 110° C. for 2 hours. After completion of the reaction, the solution was poured into methanol to precipitate the product. The solid was collected by filtration and sequentially purified by Soxhlet extraction with methanol, acetone, and chloroform. The chloroform fraction was concentrated under reduced pressure and poured into methanol to reprecipitate the product. The resulting solid was collected by filtration and dried to obtain Polymer 1 (48 mg, yield: 53%).

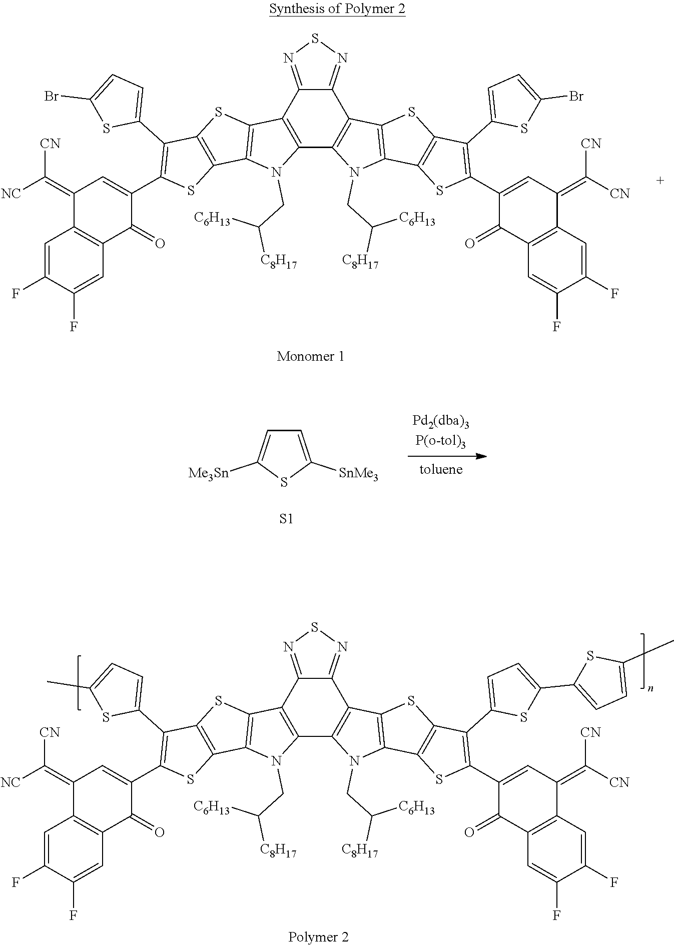

Monomer 1 (150 mg, 0.089 mmol), S1 (36 mg, 0.089 mmol), tris(dibenzylideneacetone) dipalladium (1.6 mg, 2 mol %), and tri (o-tolyl)phosphine (2.1 mg, 8 mol %) were placed into a two necked flask. The flask was degassed under vacuum and refilled with argon three times, then maintained under an argon atmosphere. Degassed toluene (1.9 mL) was added, and the mixture was heated in an oil bath at 110° C. for 30 minutes. Subsequently, 0.18 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 2 (44 mg, yield: 31%).

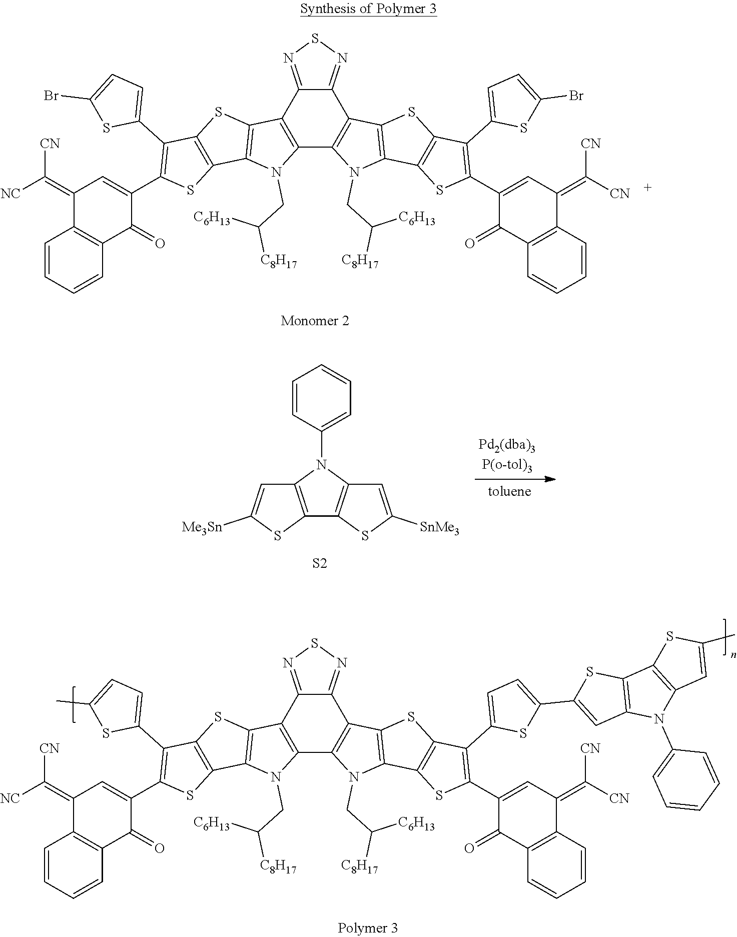

Monomer 2 (48 mg, 0.030 mmol), S2 (17 mg, 0.030 mmol), tris(dibenzylideneacetone) dipalladium (0.6 mg, 2 mol %), and tri (o-tolyl)phosphine (0.7 mg, 8 mol %) were placed into a two necked flask. The flask was degassed under vacuum and refilled with argon three times, then maintained under an argon atmosphere. Degassed toluene (1.9 mL) was added, and the mixture was heated in an oil bath at 90° C. for 80 minutes. Subsequently, 0.24 mL of bromobenzene was added, and the reaction was continued for an additional 2 hours at 90° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 3 (40 mg, yield: 78%).

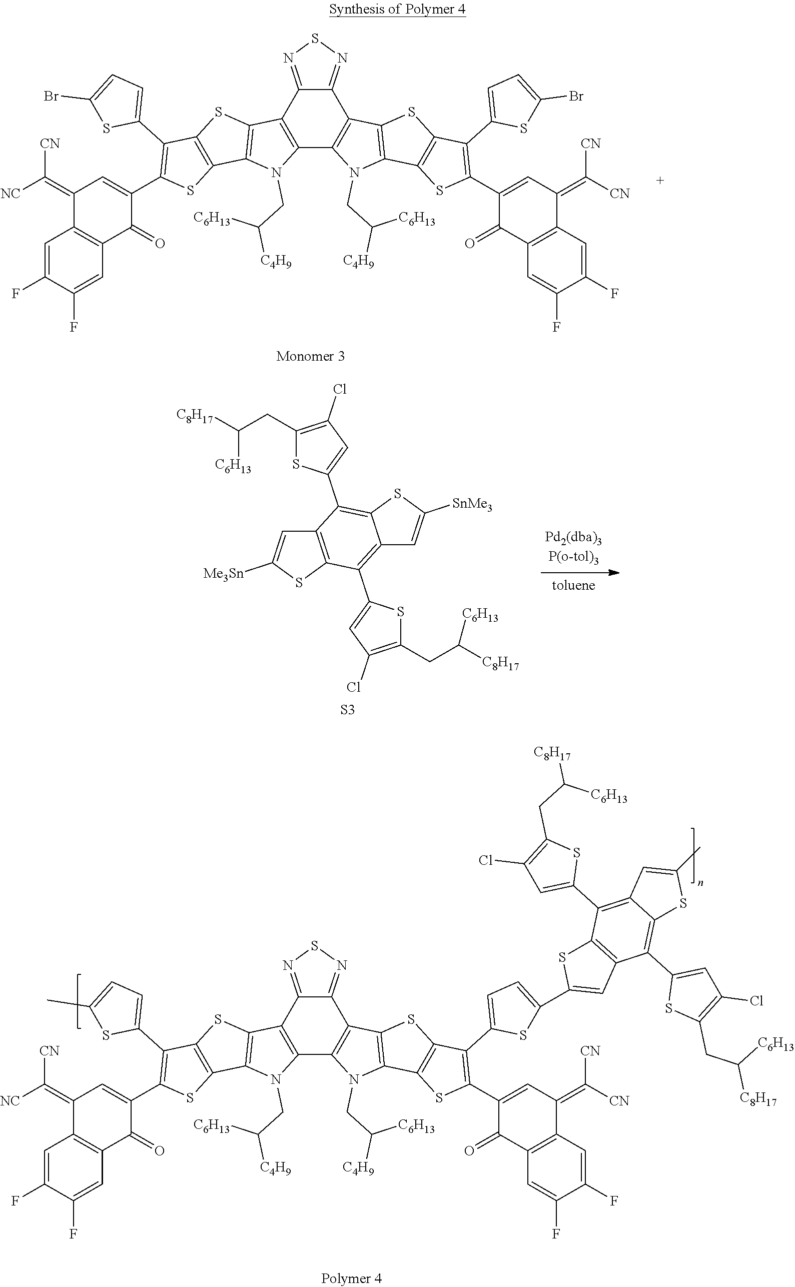

Monomer 3 (90 mg, 0.057 mmol), S3 (68 mg, 0.057 mmol), tris(dibenzylideneacetone) dipalladium (0) (1.0 mg, 2 mol %), and tri (o-tolyl)phosphine (1.4 mg, 8 mol %) were placed into a two necked flask. The flask was degassed under vacuum and refilled with argon three times, then maintained under an argon atmosphere. Degassed toluene (4.8 mL) was added, and the mixture was heated in an oil bath at 110° C. for 120 minutes. Subsequently, 0.35 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 4 (104 mg, yield: 80%).

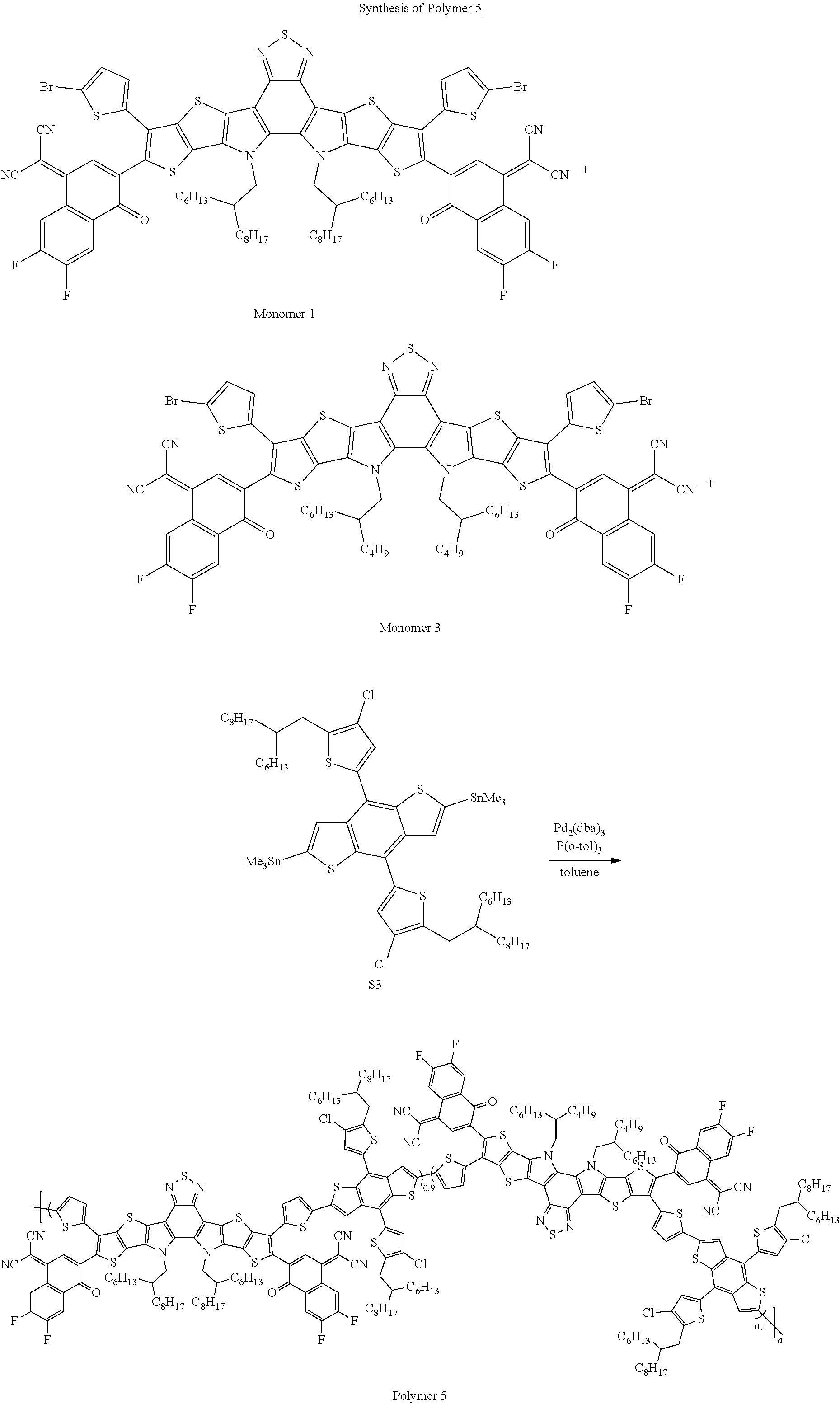

Monomer 1 (80 mg, 0.047 mmol), Monomer 3 (8.3 mg, 0.005 mmol), S3 (63 mg, 0.053 mmol), tris(dibenzylideneacetone) dipalladium (1.0 mg, 2 mol %), and tri (o-tolyl)phosphine (1.3 mg, 8 mol %) were placed into a two necked flask. The flask was degassed under vacuum and refilled with argon three times, then maintained under an argon atmosphere. Degassed toluene (4.4 mL) was added, and the mixture was heated in an oil bath at 110° C. for 120 minutes. Subsequently, 0.32 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 5 (95 mg, yield: 76%).

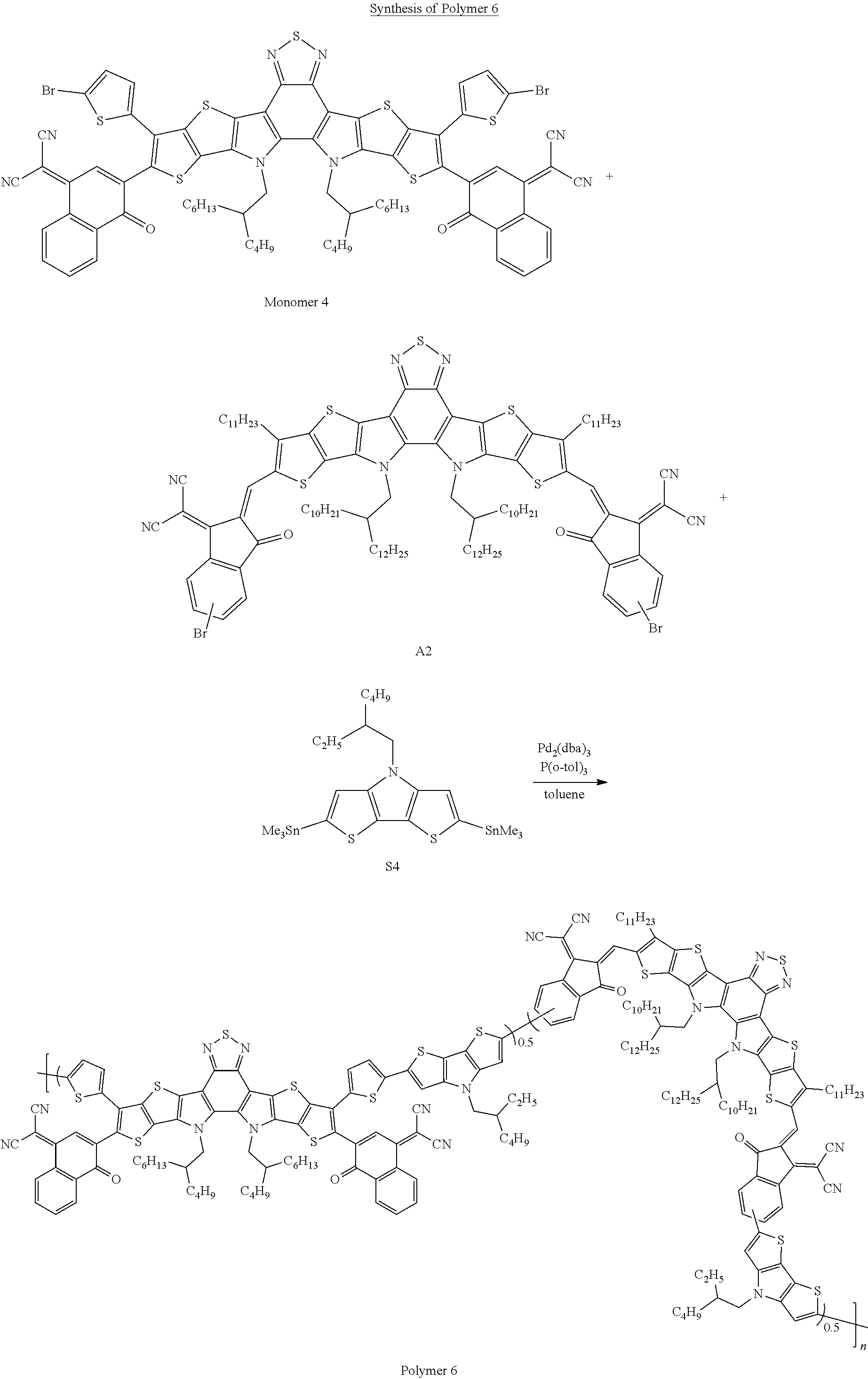

Monomer 4 (60 mg, 0.040 mmol), A2 (79 mg, 0.040 mmol), S4 (49 mg, 0.080 mmol), tris(dibenzylideneacetone) dipalladium (1.5 mg, 2 mol %), and tri (o-tolyl)phosphine (2.0 mg, 8 mol %) were placed into a two necked flask. The flask was degassed under vacuum and refilled with argon three times, then maintained under an argon atmosphere. Degassed toluene (3.4 mL) was added, and the mixture was heated in an oil bath at 110° C. for 120 minutes. Subsequently, 0.25 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 6 (45 mg, yield: 31%).

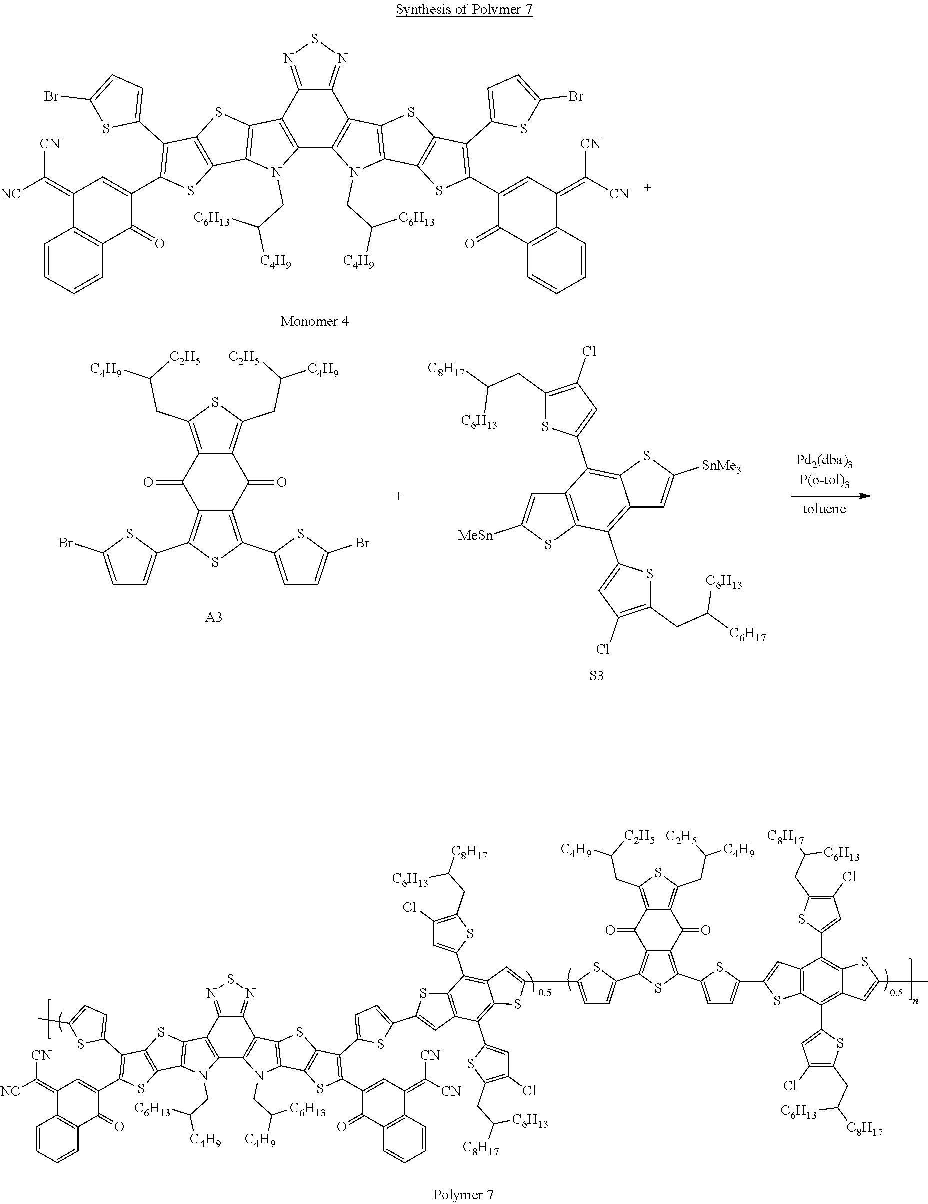

Monomer 4 (40 mg, 0.027 mmol), A3 (16 mg, 0.027 mmol), S3 (64 mg, 0.054 mmol), tris(dibenzylideneacetone) dipalladium (1.0 mg, 2 mol %), and tri (o-tolyl)phosphine (1.3 mg, 8 mol %) were placed into a two necked flask. The flask was degassed under vacuum and refilled with argon three times, then maintained under an argon atmosphere. Degassed toluene (4.5 mL) was added, and the mixture was heated in an oil bath at 110° C. for 120 minutes. Subsequently, 0.32 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 7 (72 mg, yield: 73%).

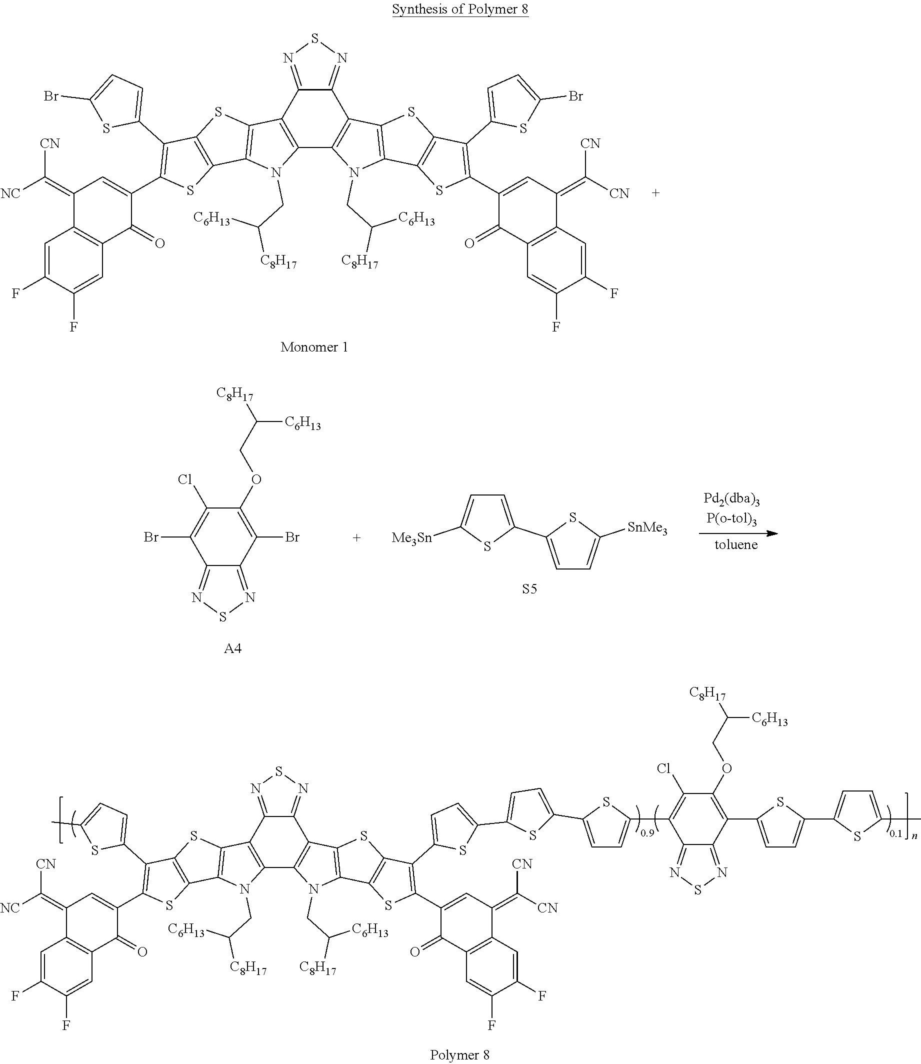

Monomer 1 (50 mg, 0.030 mmol), A4 (2.0 mg, 0.003 mmol), S5 (16 mg, 0.033 mmol), tris(dibenzylideneacetone) dipalladium (0.6 mg, 2 mol %), and tri (o-tolyl)phosphine (0.8 mg, 8 mol %) were placed into a two necked flask. The flask was degassed under vacuum and refilled with argon three times, then maintained under an argon atmosphere. Degassed toluene (1.1 mL) was added, and the mixture was heated in an oil bath at 110° C. for 120 minutes. Subsequently, 0.1 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 8 (17 mg, yield: 33%).

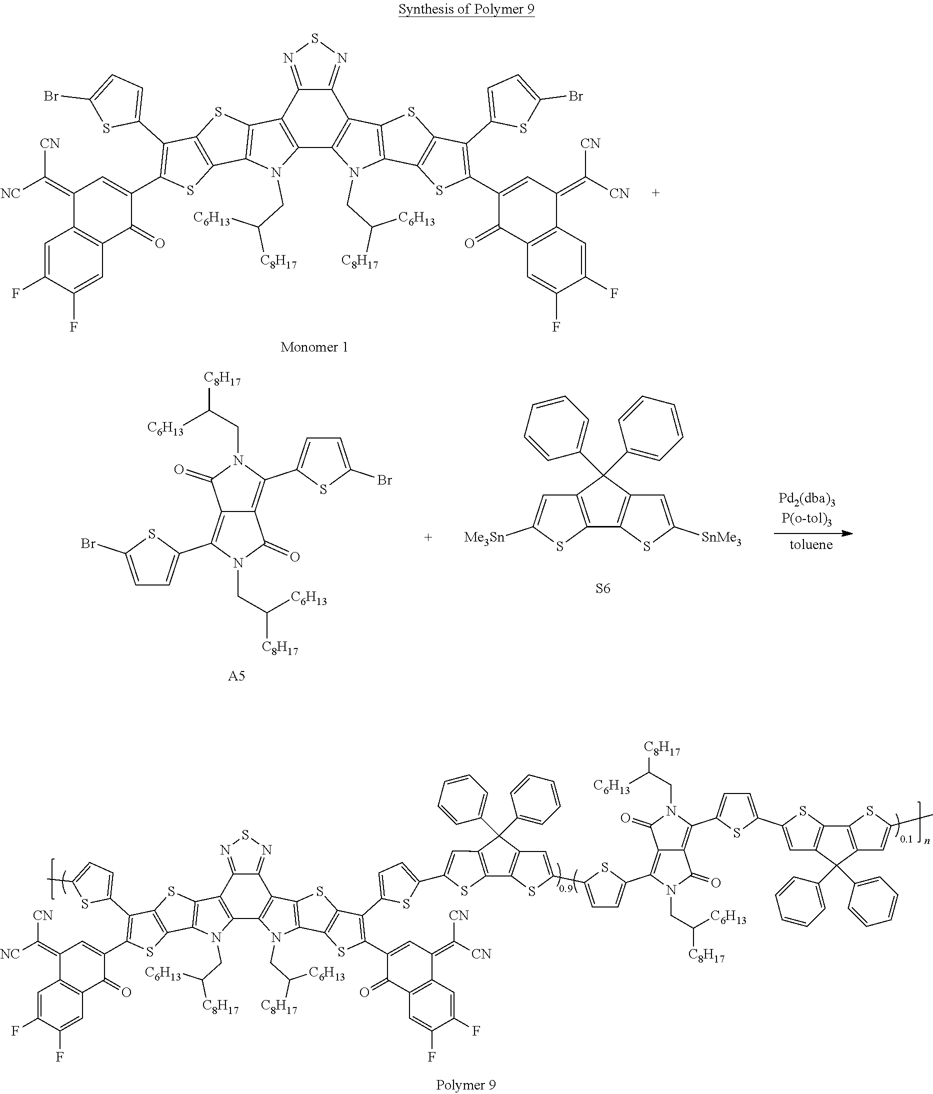

Monomer 1 (50 mg, 0.030 mmol), A5 (3.0 mg, 0.003 mmol), S6 (22 mg, 0.033 mmol), tris(dibenzylideneacetone) dipalladium (0.6 mg, 2 mol %), and tri (o-tolyl)phosphine (0.8 mg, 8 mol %) were placed into a two necked flask. The flask was degassed under vacuum and refilled with argon three times, then maintained under an argon atmosphere. Degassed toluene (1.5 mL) was added, and the mixture was heated in an oil bath at 110° C. for 120 minutes. Subsequently, 0.1 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 9 (33 mg, yield: 56%).

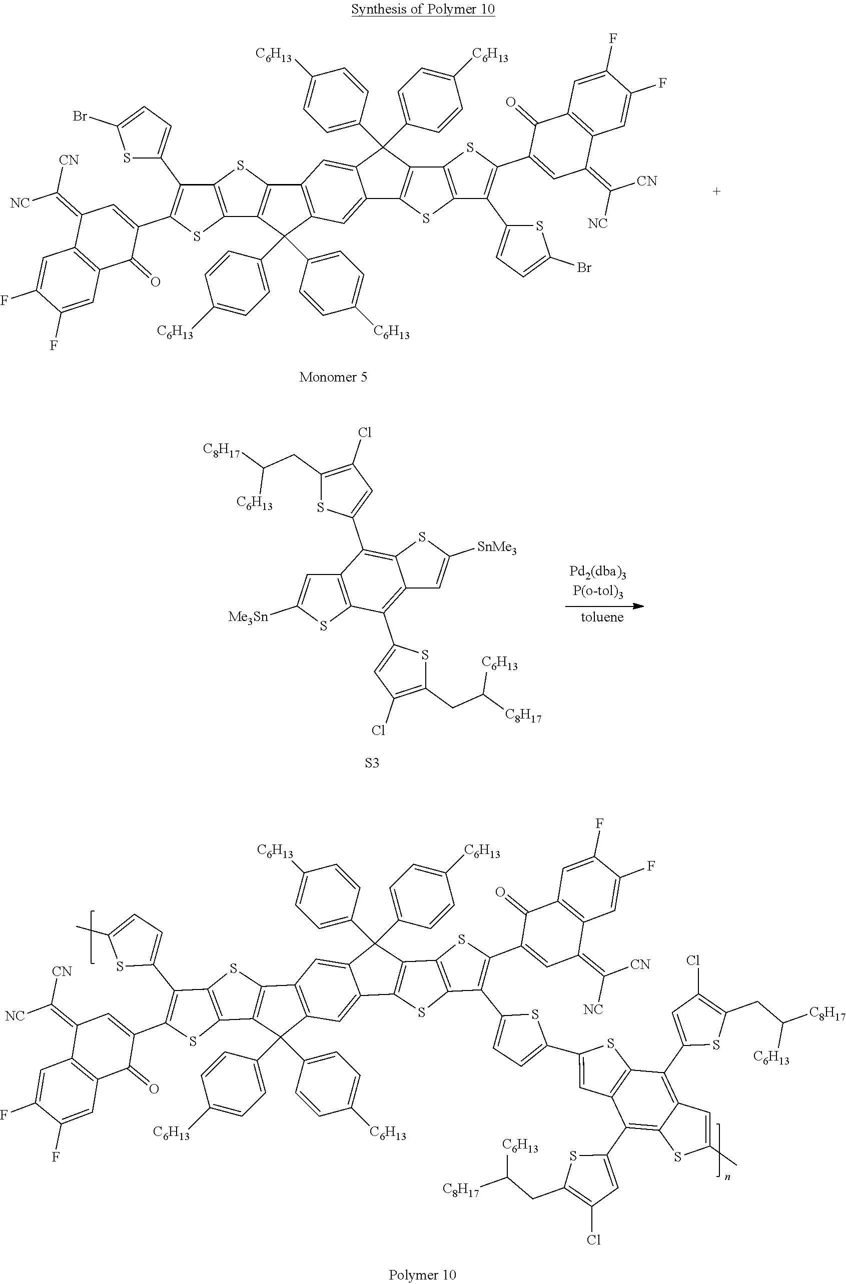

Monomer 5 (50 mg, 0.027 mmol), S3 (31 mg, 0.027 mmol), tris(dibenzylideneacetone) dipalladium (0.5 mg, 2 mol %), and tri (o-tolyl)phosphine (0.7 mg, 8 mol %) were placed into a two necked flask. The flask was degassed under vacuum and refilled with argon three times, then maintained under an argon atmosphere. Degassed toluene (2.2 mL) was added, and the mixture was heated in an oil bath at 110° C. for 120 minutes. Subsequently, 0.15 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 10 (49 mg, yield: 73%).

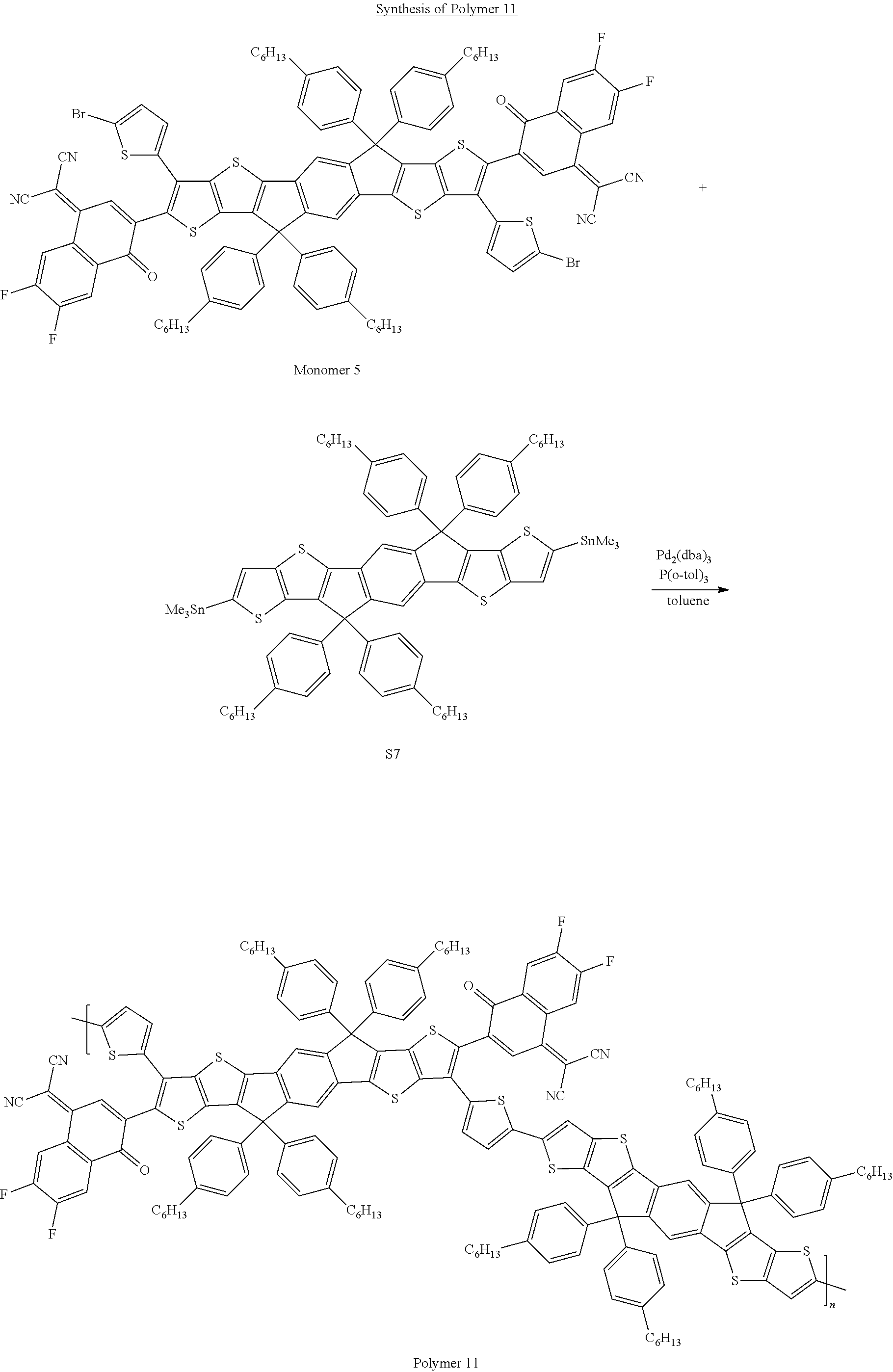

Monomer 5 (150 mg, 0.089 mmol), S7 (37 mg, 0.089 mmol), tris(dibenzylideneacetone) dipalladium (0.5 mg, 2 mol %), and tri (o-tolyl)phosphine (0.7 mg, 8 mol %) were placed into a two necked flask. The flask was degassed under vacuum and refilled with argon three times, then maintained under an argon atmosphere. Degassed toluene (2.6 mL) was added, and the mixture was heated in an oil bath at 110° C. for 120 minutes. Subsequently, 0.19 mL of bromobenzene was added, and the reaction was continued for an additional 2 hours at 110° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 11 (52 mg, yield: 71%).

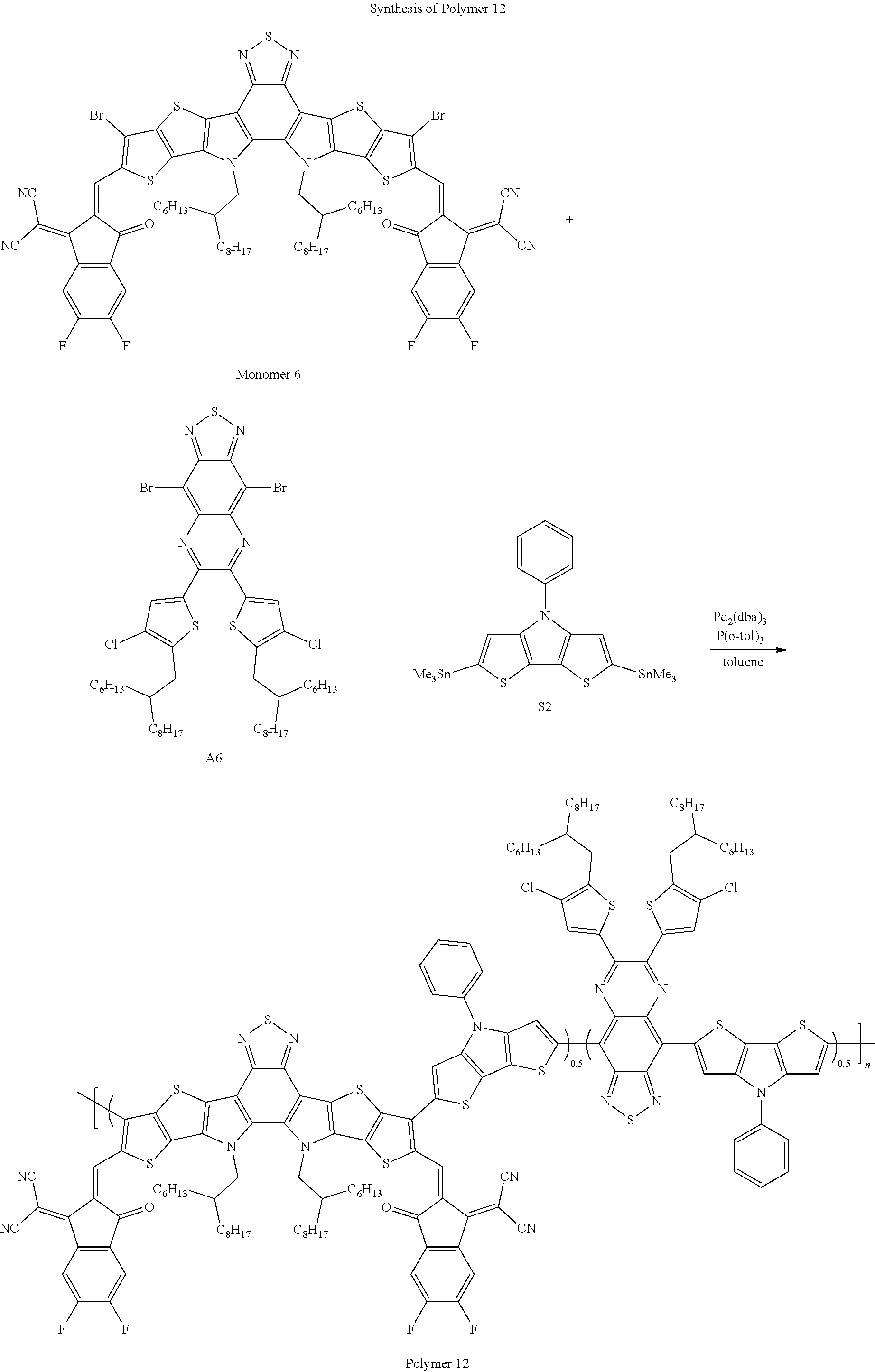

Monomer 6 (49 mg, 0.032 mmol), A6 (33 mg, 0.032 mmol), S2 (37 mg, 0.064 mmol), tris(dibenzylideneacetone) dipalladium (1.2 mg, 2 mol %), and tri (o-tolyl)phosphine (1.6 mg, 8 mol %) were placed into a two necked flask. The flask was degassed under vacuum and refilled with argon three times, then maintained under an argon atmosphere. Degassed toluene (2.6 mL) was added, and the mixture was heated in an oil bath at 90° C. for 24 hours. Subsequently, 0.19 mL of bromobenzene was added, and the reaction was continued for an additional 2 hours at 90° C. Upon completion of the reaction, the solution was poured into methanol to precipitate the product. The resulting solid was collected by filtration and subjected to Soxhlet extraction sequentially with methanol, acetone, and chloroform. The chloroform extract was concentrated under reduced pressure and poured into methanol to reprecipitate the product. The resulting solid was collected by filtration and dried to obtain Polymer 12 (44 mg, yield: 50%).

Material testing of organic random polymer Polymer 1 to Polymer 12 and Comparative Example 1 includes material optical property testing:

The structure of Comparative Example 1 is as follows:

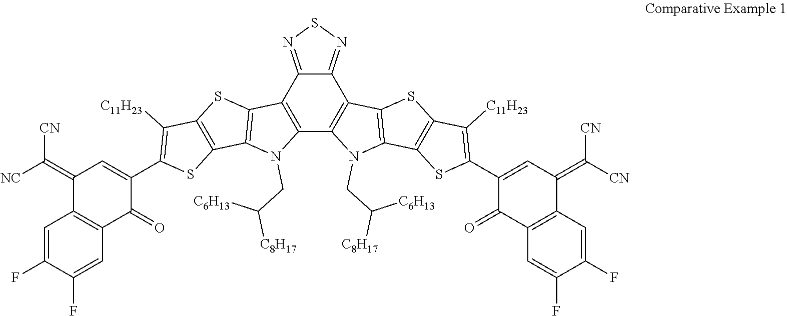

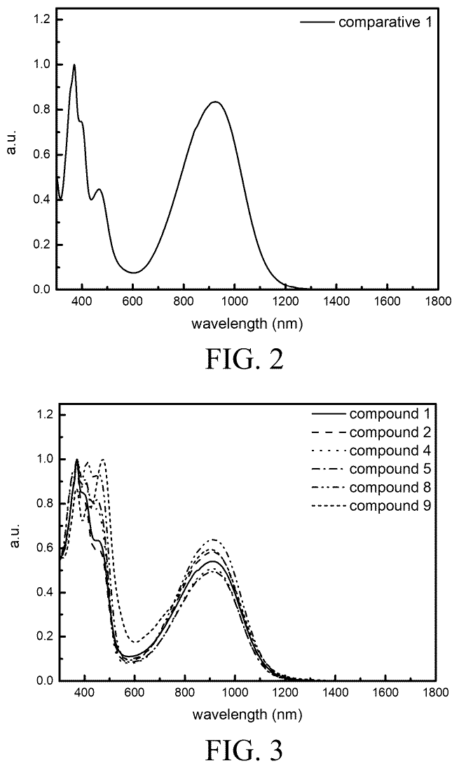

Please refer to FIG. 2, FIG. 3 and Table 1. FIG. 2 shows absorption spectra in solution state of Comparative Example 1. FIG. 3 shows absorption spectra in solution state of Polymer 1, Polymer 2, Polymer 4, Polymer 5, Polymer 8, and Polymer 9 of the organic random polymer of the present invention. Table 1 shows the material performance results of Comparative Example 1 and Polymers 1 to Polymer 11 of the organic random polymers of the present invention (including the numerical data corresponding to FIG. 2 and FIG. 3).

TABLE 1
the material performance results of Comparative Example
1 and Polymers 1 to Polymer 11 of the organic random
polymers of the present invention (including the numerical
data corresponding to FIG. 2 and FIG. 3)

| | ε [10⁵ | λ^{solu.}ₘₐₓ | λ^{film}ₘₐₓ | λ^{film}ₒₙₛₑₜ | HOMO | LUMO |
|---|---|---|---|---|---|---|
| | M⁻¹cm⁻¹] | [nm] | [nm] | [nm] | [eV] | [eV] |
| Comparative | 0.560 | 925 | 1,141 | 1,483 | −5.51 | −4.67 |
| Example 1 | | | | | | |
| Polymer 1 | 0.480 | 909 | 974 | 1,317 | −5.44 | −4.50 |
| Polymer 2 | 0.469 | 907 | 992 | 1,342 | −5.47 | −4.55 |
| Polymer 3 | 0.279 | 851 | 904 | 1,213 | −5.23 | −4.21 |
| Polymer 4 | 0.408 | 913 | 979 | 1,302 | −5.50 | −4.55 |
| Polymer 5 | 0.377 | 909 | 973 | 1,283 | −5.73 | −4.76 |
| Polymer 6 | 0.681 | 761 | 778 | 1,170 | −5.48 | −4.42 |
| Polymer 7 | 0.188 | 843 | 914 | 1,174 | −5.80 | −4.74 |
| Polymer 8 | 0.379 | 913 | 968 | 1,322 | −5.42 | −4.48 |
| Polymer 9 | 0.308 | 905 | 964 | 1,304 | −5.26 | −4.31 |
| Polymer 10 | 0.587 | 843 | 885 | 1,063 | −5.65 | −4.48 |
| Polymer 11 | 0.460 | 842 | 847 | 1,081 | −5.36 | −4.21 |

As shown in FIG. 2, FIG. 3 and Table 1, Polymer 1 to Polymer 11 of the organic random polymers exhibit favorable performance in the absorption spectra. The Comparative Example 1 also exhibits maximum absorption values and absorption wavelength positions in solution that are comparable to those of Polymer 1 to Polymer 11 of the organic random polymers of the present invention, and possesses similar HOMO and LUMO energy levels. Furthermore, the absorption spectra of Polymer 6, Polymer 7, Polymer 10, and Polymer 11 demonstrate that the energy levels of the organic random polymers can be readily tuned, thereby fulfilling the objectives of the present invention.

Thermal stability performance test of single material absorbance:

Please refer to Table 2. Table 2 shows the material testing results of Comparative Example 1 and Polymer 1 to Polymer 12 of the organic random polymers of the present invention. In the testing procedure, each organic random polymer was dissolved in o-xylene at a concentration of 14 mg/mL by heating. The resulting solution was spin-coated onto a glass substrate at a rotation speed of 360 rpm. The coated films were baked in air at 100° C. for one minute. After cooling, the film absorption spectrum was measured and the maximum absorption peak was recorded as the first measurement. The second measurement was conducted after baking the sample at 100° C. for 5 minutes, then cooling and measuring the absorbance at the same wavelength position recorded in the first measurement. Subsequent baking steps were performed at 160° C., 180° C., 200° C., and 220° C. for 5 minutes accordingly, followed by absorbance measurements at the same maximum absorption wavelength position. The absorbance values after each thermal baking step were compared with the first measurement to calculate the absorption retention ratio.

TABLE 2
material testing results of Comparative Example 1 and Polymer 1 to
Polymer 12 of the organic random polymers of the present invention.

| | absorption retention ratio | | | | | |
|---|---|---|---|---|---|---|
| | 100° C./ | 100° C./ | 160° C./ | 180° C./ | 200° C./ | 220° C./ |
| | 1 min | 5 min | 5 min | 5 min | 5 min | 5 min |
| Polymer 1 | 1.000 | 0.990 | 0.995 | 0.995 | 0.928 | 0.794 |
| Polymer 2 | 1.000 | 0.962 | 1.075 | 1.066 | 0.901 | 0.825 |
| Polymer 3 | 1.000 | 0.960 | 0.970 | 0.920 | 0.910 | 0.830 |
| Polymer 4 | 1.000 | 0.988 | 0.946 | 0.875 | 0.845 | 0.524 |
| Polymer 5 | 1.000 | 0.994 | 0.901 | 0.877 | 0.848 | 0.789 |
| Polymer 6 | 1.000 | 1.020 | 1.020 | 1.050 | 1.080 | 1.150 |
| Polymer 7 | 1.000 | 1.000 | 0.950 | 0.906 | 0.885 | 0.827 |
| Polymer 8 | 1.000 | 1.005 | 1.023 | 1.028 | 1.050 | 0.973 |
| Polymer 9 | 1.000 | 0.995 | 1.000 | 0.991 | 0.968 | 0.910 |
| Polymer 10 | 1.000 | 0.950 | 0.950 | 0.911 | 0.839 | 0.772 |
| Polymer 11 | 1.000 | 0.989 | 0.962 | 0.941 | 0.914 | 0.849 |
| Polymer 12 | 1.000 | 1.023 | 0.986 | 0.981 | 1.000 | 0.944 |
| Comparative | 1.000 | 0.845 | 0.864 | 0.709 | 0.837 | 0.112 |
| Example 1 | | | | | | |

As shown in Table 2, the thermal baking experiments of the polymer films indicate that the absorbance of Polymer 1 to Polymer 12 remained above 70% of their initial values after thermal treatment at temperatures ranging from 100° C. to 220° C. In contrast, Comparative Example 1 retained only 11.2% of its initial absorbance after thermal treatment at 220° C. These results demonstrate that, compared to Comparative Example 1, Polymer 1 to Polymer 12 of the organic random polymers of the present invention exhibit superior thermal stability.

### Preparation and Performance Testing of Organic Photodetectors of Organic Optoelectronic Devices:

A glass coated by a pre-patterned indium tin oxides (ITO) with a sheet resistance of ˜15 Ω/sq is used as a substrate. The substrate is ultrasonically oscillated in soap deionized water, deionized water, acetone, and isopropanol in sequence, and washed in each step for 15 minutes. The washed substrate is further treated with a UV-ozone cleaner for 15 minutes. The top coat of AZO (Aluminum-doped zinc oxide) solution is spin coated on the ITO substrate with a spin rate of 2000 rpm for 40 seconds, and then baked at 120° C. in air for 5 minutes to form an electron transporting layer (ETL). The active layer solution comprises the aforementioned organic composition, wherein at least one P-type organic semiconductor material is used as a donor material (in the following tests, P-12 is used as an example of the P-type organic semiconductor material, but is not limited thereto), and at least one N-type organic semiconductor material (in the following tests, Polymer 1, Polymer 2, Polymer 4, and Polymer 5 of the organic random polymers are used as embodiments, but are not limited thereto) is used as an acceptor material (the weight ratio of donor material to acceptor material is in the range of 1:1 to 1:2). The concentration of the donor material was 10˜20 mg/mL. In order to completely dissolve the active layer material, the active layer solution needs to be stirred on a hot plate at 100° C. for at least 3 hours. After completely dissolving the active layer material, the active layer solution is filtered with PTFE filter membrane (pore size 0.45˜1.2 μm) and heated for 1 hour. Then, the active layer solution is cooled to the room temperature for spin coating, and the spin rate was used to control the film thickness in the range of 100-800 nm. Finally, the thin film formed by the coated active layer is annealed at 100° C. for 5 minutes, and then transferred to a thermal evaporation machine. A thin layer (8 nm) of MoO₃ is deposited as a hole transporting layer (HTL) under a vacuum of 3×10−6 Torr. In this experiment, a Keithley™ 2400 source meter was used to record the dark current density (J_{dark}, at a bias of 0˜−8 V) in the absence of light. External quantum efficiency system was used to measure external quantum efficiency (EQE) with a range of 300-1100 nm (bias voltage 0˜−8 V), and silicon (300-1100 nm) is used for light source calibration.

It should be noted here that, in practical applications, the first electrode preferably has good light transmittance. The first electrode is usually made of the transparent conductive material, preferably selected from one of the following conductive material groups: indium oxide, tin oxide, fluorine-doped tin oxide (FTO) derivative, or composite metal oxides such as indium tin oxide (ITO) and indium zinc oxide (IZO). The material of the second electrode is a conductive metal, preferably silver or aluminum, more preferably silver. Suitable and preferred materials for electron transporting layer include, but are not limited to, metal oxides such as ZnOₓ, aluminum doped ZnO (AZO), TiOₓ or nanoparticles thereof, salts (such as LiF, NaF, CsF, Cs₂CO₃), amines (such as primary amines, secondary or tertiary amines), conjugated polymer electrolytes (such as polyethyleneimine), conjugated polymers (such as poly[3-(6-trimethylammoniumhexyl)thiophene], poly(9,9)-bis(2-ethylhexyl-fluorene)-b-poly[3-(6-trimethylammoniumhexyl)thiophene] or poly[(9,9-bis(3′—(N,N-dimethylamino)) propyl)-2,7-fluorene)-alt-2,7-(9,9-dioctylfluorene)], and organic compounds such as tris(8-quinolinyl)-aluminum (III) (Alq₃), 4,7-diphenyl-1,10-phenanthroline, or a combination of one or more of the foregoing. Suitable and preferred materials for hole transporting layer include, but are not limited to metal oxides such as ZTO (Zinc Tin Oxide), MoOx, WOx, NiOx, SnOx and nanoparticles thereof, metal-containing salts, such as copper sulfide, copper thiocyanate, copper iodide, copper indium sulfide, lead sulfide, cobalt acetate, and tungsten disulfide, conjugated polymer electrolytes such as PEDOT:PSS, polymeric acids such as polyacrylates, conjugated polymers such as polytriarylamine (PTAA), insulating polymers such as Nafion films, polyethyleneimine and polystyrene sulfonates, organic compounds such as N,N′-diphenyl-N,N′-bis(1-naphthyl) (1,1′-biphenyl)-4,4′-diamine (NPB), N,N′-diphenyl-N,N′-(3-methylbenzene base)-1,1′-biphenyl-4,4′-diamine (TPD), and a combination of one or more of the above.

Please refer to Table 3. Table 3 shows the external quantum efficiency test results in the thermal stability of organic optoelectronic devices in which the acceptor materials were, respectively, Comparative Example 1 and Polymer 1, Polymer 2, Polymer 4, and Polymer 5 of the organic random polymers of the present invention.

TABLE 3
external quantum efficiency (EQE) results under thermal
stability testing for organic optoelectronic devices
using Comparative Example 1 and Polymer 1, Polymer 2,
Polymer 4, and Polymer 5 of the organic random polymers
of the present invention as the acceptor materials.

| | EQE¹⁰²⁰ (initial/annealing)@−4 V | | |
|---|---|---|---|
| | Initial | 160° C., 30 min | 180° C., 30 min |
| Comparative | 14.1% (1.000) | 1.8% (0.128) | 0.1% (0.007) |
| Example 1 | | | |
| Polymer 1 | 4.4% (1.000) | 3.4% (0.773) | 2.2% (0.500) |
| Polymer 2 | 8.2% (1.000) | 6.8% (0.829) | 4.5% (0.549) |
| Polymer 4 | 4.0% (1.000) | 3.9% (0.975) | 3.3% (0.875) |
| Polymer 5 | 4.9% (1.000) | 3.9% (0.795) | 3.3% (0.673) |

As shown in Table 3, the thermal stability data of the organic optoelectronic devices indicate that the organic optoelectronic devices using Polymer 1, Polymer 2, Polymer 4, and Polymer 5 of the organic random polymers are able to retain 50-88% of their external quantum efficiency (EQE) after thermal annealing at 180° C. for 30 minutes. In contrast, the organic optoelectronic devices using Comparative Example 1 exhibited an EQE of only 0.1% under the same conditions, corresponding to merely 0.7% of its initial EQE. These results demonstrate that the organic optoelectronic devices using Polymer 1, Polymer 2, Polymer 4, and Polymer 5 of the organic random polymers possess superior thermal stability compared to the organic optoelectronic device using Comparative Example 1. Thermal stability is a critical factor in the commercialization of organic semiconductors. The relevant temperature processes include the high-temperature steps required during device fabrication and the operational temperatures during device use. While organic photovoltaic cells typically do not require high-temperature processing and thus mainly encounter operational temperatures, literature reports indicate that such temperatures generally range from 50° C. to 80° C. during summer, with rare instances exceeding 100° C. Therefore, most studies on thermal stability for organic photovoltaics have focused on conditions below 120° C. However, organic photodetector devices differ from conventional organic photovoltaic cells. In the fabrication of organic optoelectronic devices, integration with semiconductor components such as integrated circuits and color filters is often required, and these processes typically involve temperatures exceeding 120° C. Accordingly, ensuring high-temperature thermal stability is even more critical in the development of organic photodetectors.

In summary, the organic random polymers of the present invention, as well as the organic compositions and organic optoelectronic devices incorporating the same, offer the following advantages:
1. The organic random polymer of the present invention utilizes the 3-position of thiophene as the polymerization site instead of the 2-(3-oxo-2,3-dihydro-1H-inden-1-ylidene) malononitrile (IC) terminal group, thereby eliminating the formation of isomers. As a result, the structural design of the polymers reduces synthetic complexity, lowers production costs, improves synthetic yield, and enables large-scale production and commercial viability advantages that conventional NFA systems polymerized via IC terminals cannot achieve;
2. The organic random polymer of the present invention exhibits excellent thermal stability;
3. The organic random polymer of the present invention is allowed for structural tuning of the “y-block” to extend light absorption from the visible region to the short wavelength infrared region, according to application requirements;
4. Due to their tunable absorption spectra, the organic random polymer of the present invention is also suitable for use as a single-junction active layer. These polymers possess sufficiently high molecular weight to prevent significant morphological changes during thermal treatment, thereby providing superior thermal stability. Moreover, the single-junction active layer formulation avoids the reproducibility issues often encountered in double-junction systems arising from formulation variability;
5. The organic random polymer of the present invention features tunable energy levels and solubility, allowing polymer synthesis with different functional groups to meet specific performance specifications.
6. The organic random polymer of the present invention is processable in non-halogenated solvents, offering a more environmentally friendly alternative to commonly reported solvents such as chloroform and chlorobenzene.

With the detailed description of the above embodiments, it is hoped that the features and spirit of the present invention can be more clearly described, and the scoped of the present invention is not limited by the embodiments disclosed above. On the contrary, the intention is to cover various changes and equivalent arrangements within the scope of the patents to be applied for in the present invention.

What is claimed is:

1. An organic random polymer comprising a structure such as Formula I: 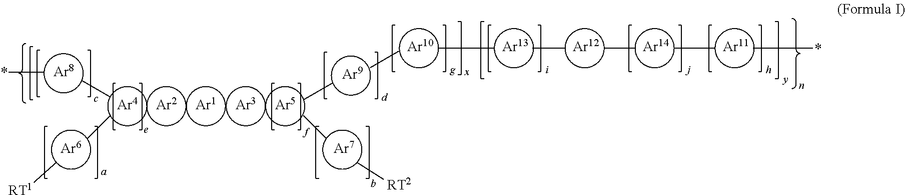
wherein Ar¹, Ar⁴, Ar⁵, Ar¹³, and Ar¹⁴ are each independently selected from arylene or heteroarylene having 5 to 20 ring atoms, Ar¹, Ar⁴, Ar⁵, Ar¹³, and Ar¹⁴ comprise monocyclic, polycyclic, or fused ring structure, and optionally unsubstituted or substituted with one or more identical or different R¹ or L¹;
Ar² and Ar³ are each independently selected from the group consisting of 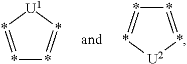
wherein U¹ and U² are each independently selected from the group consisting of NR¹, C═O, O, S, Se, SiR¹R², and CR¹R²;
Ar⁶, Ar⁷, Ar⁸, and Ar⁹ are each independently selected from the group consisting of a structure having —CY¹=CY²— or —C≡C—, arylene having 5 to 20 ring atoms and heteroarylene having 5 to 20 ring atoms, Ar⁶, Ar⁷, Ar⁸, and Ar⁹ comprise monocyclic, polycyclic, or fused ring structure, and optionally unsubstituted or substituted with one or more identical or different R 1 or L¹;
Ar¹⁰, Ar¹¹, and Ar¹² are each independently selected from arylene or heteroarylene having 5 to 30 ring atoms, Ar¹⁰, Ar¹¹, and Ar¹² comprise monocyclic, polycyclic, or fused ring structure, and optionally unsubstituted or substituted with one or more identical or different R¹ or L¹;
wherein R¹ and R² are independently selected from the group consisting of H, F, Cl, CN, C1-C30 straight-chain alkyl, C1—C30 branched alkyl, and C1-C30 cyclic alkyl, wherein one or more CH₂ of alkyl are optionally replaced by at least one group selected from the group consisting of —O—, —S—, —C(═O)—, —C(═S)—, —C(═O)—O—, —O—C(═O)—, —NR⁰—, —SiR⁰R⁰⁰—, —CF₂—, —CR⁰=CR⁰⁰—, —CY¹=CY²—, and —C≡C—, wherein O and S are not directly bonded to each other, and one or more atoms are optionally substituted with F, Cl, Br, I, or CN, and wherein one or more CH₂ or CH₃ are optionally substituted with at least one of cation, anion, aryl, heteroaryl, aralkyl, heteroaralkyl, aryloxy, and heteroaryloxy, wherein the aryl and the heteroaryl are each independently selected from monocyclic, polycyclic, or fused ring structures having 5 to 20 ring atoms, and the alkyl is optionally unsubstituted or substituted with one or more identical or different L¹; and
L¹ is selected from the group consisting of F, Cl, —NO₂, —CN, —NC, —NCO, —NCS, —OCN, —SCN, R⁰, OR⁰, SR⁰, —C(═O)X⁰, —C(═O)R⁰, —C(═O)—OR⁰, —O—C(═O)—R⁰, —NH₂, —NHR⁰, —NR⁰R⁰⁰, —C(═O)NHR⁰, —C(, O)NR⁰R⁰⁰, —SO₃R⁰, —SO₂R⁰, —OH, —NO₂, —CF₃, —SF₅, and C1-C30 silane, C1-C30 carbonyl and C1-C30 hydrocarbon optionally substituted or unsubstituted with one or more heteroatoms, wherein the heteroatom comprises N, O, S, and Se;
wherein R⁰ and R⁰⁰ are each independently selected from the group consisting of H and C1-C20 straight-chain alkyl and C1-C20 branched alkyl, and optionally fluorinated; and
X⁰ is halogen;
Y¹ and Y 2 are each independently selected from the group consisting of H, F, Cl, and CN;
a, b, c, d, e, f, g, h, i, and j are integers, each independently selected from 0 or 1 to 10;
x and y are mole ratio, and x+y=1;
n is the number of repeating units and is an integer selected from 1 to 1000;
RT¹ and RT² are electron-withdrawing groups; and
* is a bonding position.

2. The organic random polymer of claim 1, wherein Ar¹ is further selected from the group consisting of the following structures: 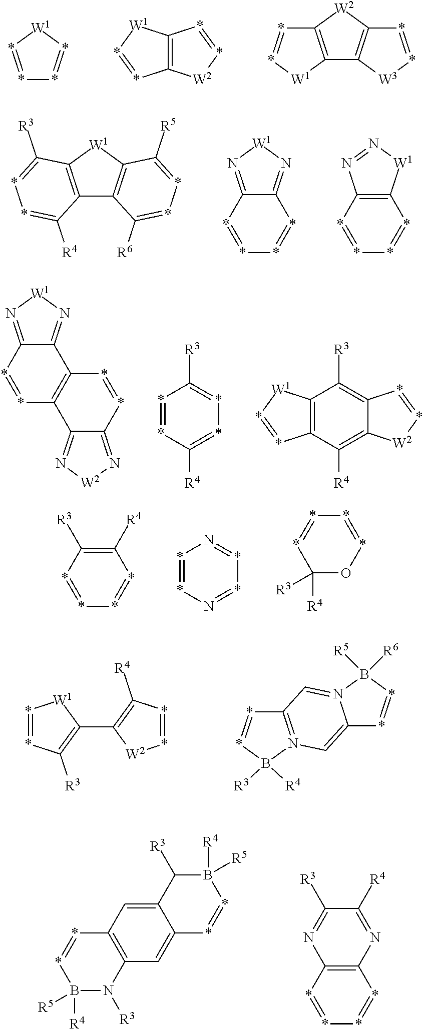
wherein W¹, W², and W³ are each independently selected from the group consisting of S, O, Se, CR³R⁴, SiR³R⁴, C═O, and NR³; and
R³, R⁴, R⁵ and R⁶ are each independently defined as R¹ as defined in claim 1, and are optionally covalently bonded to at least one of the others, or each is a separate group.

3. The organic random polymer of claim 1, wherein Ar² and Ar³ are further each independently selected from the group consisting of the following structures: 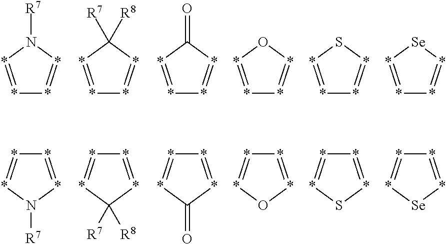
wherein R⁷ and R⁸ are each independently defined as R¹ as defined in claim 1.

4. The organic random polymer of claim 1, wherein Ar⁴ and Ar⁵ are further each independently selected from the group consisting of the following structures and their enantiomeric forms: 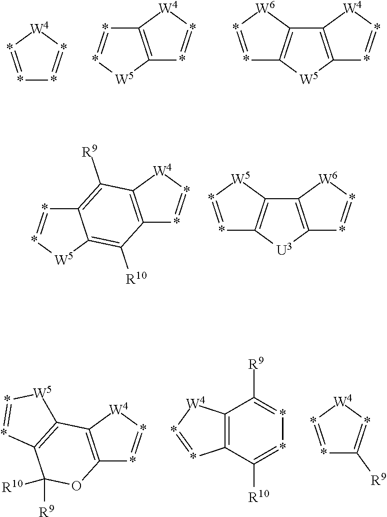
wherein W⁴, W⁵, and W⁶ are each independently selected from the group consisting of S, O, Se, CR⁹R¹⁰, SIR⁹R¹⁰, C═O, and NR⁹;
R⁹ and R¹⁰ are each independently defined as R¹ as defined in claim 1; and
U³ is defined as U¹ as defined in claim 1.

5. The organic random polymer of claim 1, wherein Ar⁶, Ar⁷, Ar⁸ and Ar⁹ are further each independently selected from the group consisting of the following structures and their enantiomeric forms: 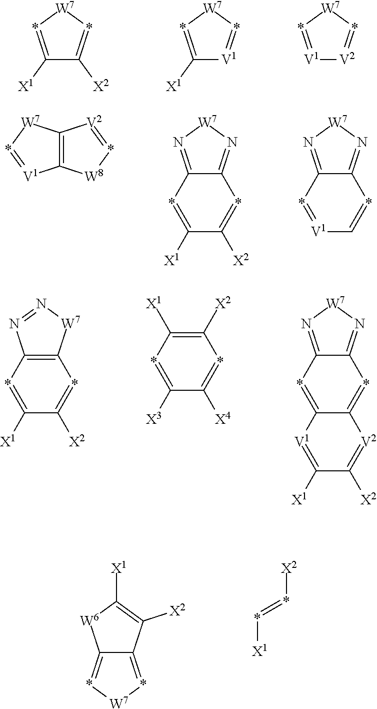
wherein W⁷ and W⁸ are further independently selected from the group consisting of S, O, Se, CR¹¹R¹², SIR¹¹R¹², C═O, and NR¹¹;
V¹ and V² are further independently selected from CR¹¹ and N, wherein R¹¹ and R¹² are each independently defined as R¹ as defined in claim 1; and
X¹, X², X³ and X⁴ are each independently defined as R¹ as defined in claim 1.

6. The organic random polymer of claim 1, wherein Ar¹⁰ and Ar¹¹ are further each independently selected from the group consisting of the following structures and their enantiomeric forms: 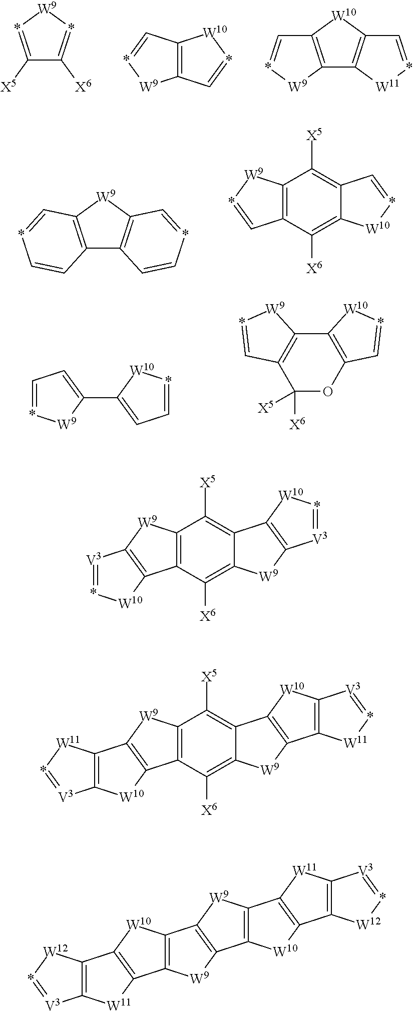
wherein W⁹, W¹⁰, W¹¹ and W¹² are further independently selected from the group consisting of S, O, Se, CR¹³R¹⁴, SiR¹³R¹⁴, C═O, and NR¹³;
each V 3 are further independently selected from CR 13 and N; and
wherein R¹³ and R¹⁴ are each independently defined as R¹ as defined in claim 1;
X⁵ and X⁶ are each independently defined as R¹ as defined in claim 1.

7. The organic random polymer of claim 1, wherein Ar¹² is further selected from the group consisting of the following structures and their enantiomeric forms: 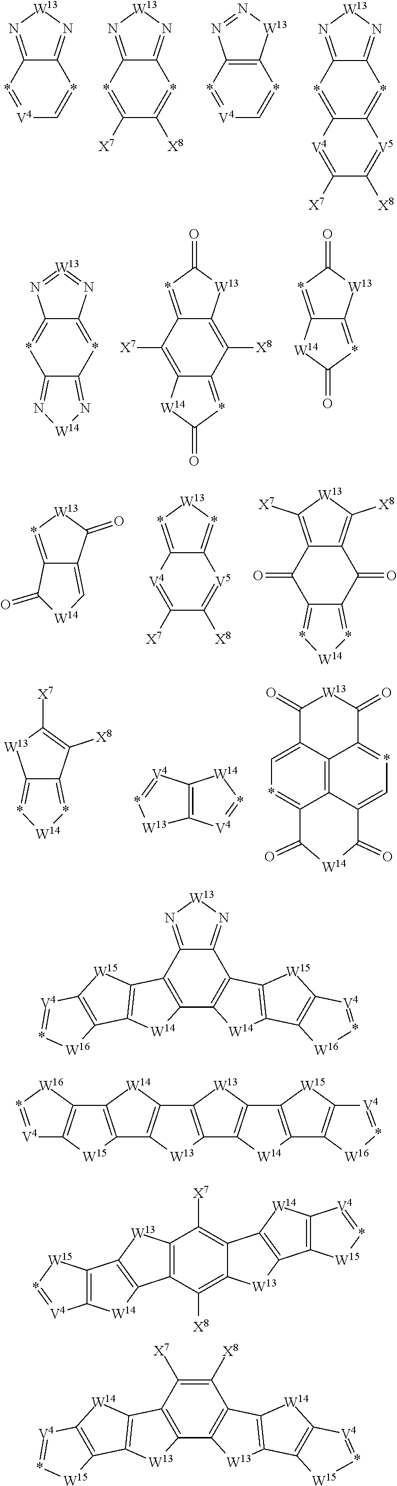 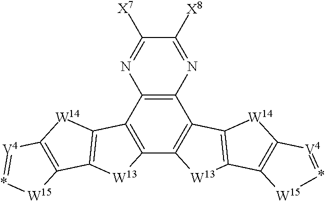
wherein W¹³, W¹⁴, W¹⁵ and W¹⁶ are further independently selected from the group consisting of S, O, Se, CR¹⁵R¹⁶, SiR¹⁵R¹⁶, C═O, and NR¹⁵;
V⁴ and V⁵ are further independently selected from CR 15 and N;
R¹⁵, R¹⁶, X⁷ and X⁸ are each independently defined as R¹ as defined in claim 1, and are optionally covalently bonded to at least one of the others, or each is a separate group.

8. The organic random polymer of claim 1, wherein Ar¹³ and Ar¹⁴ are further each independently selected from the group consisting of the following structures and their enantiomeric forms: 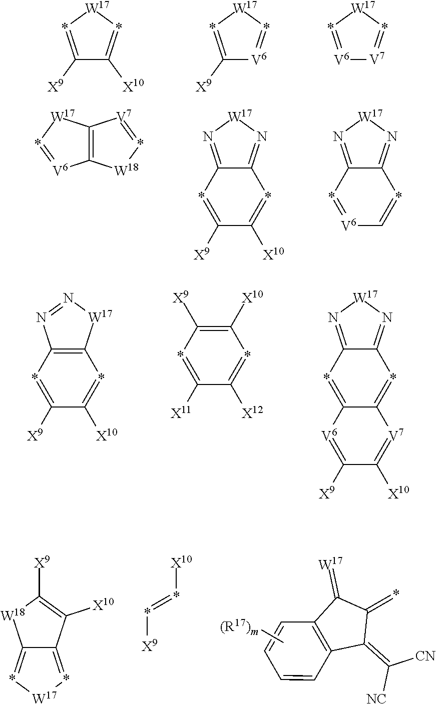
wherein W¹⁷ and W¹⁸ are further independently selected from the group consisting of S, O, Se, CR¹⁷R¹⁸, SiR¹⁷R¹⁸, C═O, and NR¹⁷;
V⁶ and V⁷ are further independently selected from CR¹⁷ and N;
R¹⁷, R¹⁸, X⁹, X¹⁰, X¹¹ and X¹² are each independently defined as R¹ as defined in claim 1, and are optionally covalently bonded to at least one of the others, or each is a separate group; and
m is selected from the group consisting of 0, 1, 2, 3, and 4.

9. The organic random polymer of claim 1, wherein RT¹ and RT² are further each independently selected from the group consisting of the following structures: 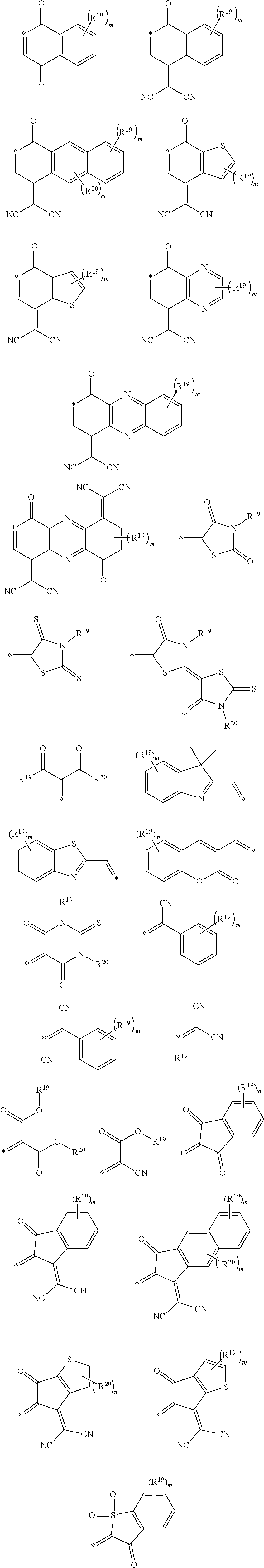
wherein R¹⁹ and R²⁰ are each independently defined as R¹ as defined in claim 1; and
m is selected from the group consisting of 0, 1, 2, 3, and 4.

10. An organic composition, comprising:
the organic random polymer of claim 1; and
at least one of a P-type organic semiconductor material and an N-type organic semiconductor material;
wherein the P-type organic semiconductor material comprises at least one organic conjugated polymer or one organic conjugated small molecule, and the energy band gap of the N-type organic semiconductor material is from 0.5 to 2.0 eV.

11. An organic optoelectronic device comprising the organic random polymer of claim 1.

12. An organic optoelectronic device, comprising:
a first electrode;
an active layer which comprises the organic random polymer of claim 1; and
a second electrode, wherein the active layer is disposed between the first electrode and the second electrode, and at least one of the first electrode and the second electrode is a transparent or semi-transparent electrode.

13. An organic optoelectronic device, comprising:
a first electrode;
an active layer which comprises the organic composition of claim 10; and
a second electrode, wherein the active layer is disposed between the first electrode and the second electrode, and at least one of the first electrode and the second electrode is a transparent or semi-transparent electrode.
